(19) United States
(12) Patent Application Publication
(10) Pub. No.: US 2013/0260314 A1
(43) Pub. Date: Oct. 3, 2013

(54) RESIST COMPOSITION, METHOD OF FORMING RESIST PATTERN, COMPOUND AND POLYMERIC COMPOUND

(71) Applicant: TOKYO OHKA KOGYO CO., LTD., Kawasaki-shi (JP)

(72) Inventors: Akiya Kawaue, Kawasaki-shi (JP); Yoshiyuki Utsumi, Kawasaki-shi (JP); Jiro Yokoya, Kawasaki-shi (JP)

(73) Assignee: Tokyo Ohka Kogyo Co., Ltd., Kawasaki-shi (JP)

(21) Appl. No.: 13/850,685

(22) Filed: Mar. 26, 2013

(30) Foreign Application Priority Data
Mar. 30, 2012 (JP) 2012-079677

(51) Int. Cl. G03F 7/027

(52) U.S. Cl. CPC G03F 7/027
USPC 430/284.1; 526/263; 430/325; 546/226

(57) ABSTRACT

There is provided a resist composition including a polymeric compound (A1) containing a structural unit derived from a compound represented by general formula (a0-m), and a method of forming a resist pattern using the resist composition. In the formula, R¹ represents a polymerizable group; Y¹ represents a hydrocarbon group of 1 to 30 carbon atoms; L¹ represents a single bond or a carbonyl group; Y² represents a divalent linking group, and R² represents a hydrogen atom or a hydrocarbon group, provided that Y² and R² may be mutually bonded to form a ring with the nitrogen atom having Y² and R² bonded thereto; R³ represents a hydrogen atom or a hydrocarbon group; Y³ represents a group which forms an aromatic ring together with the two carbon atoms having Y³ bonded thereto, provided that the aromatic ring may have a nitro group or a substituent other than the nitro group bonded to the aromatic ring.

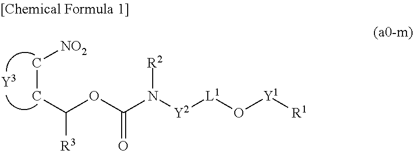

### TECHNICAL FIELD

The present invention relates to a resist composition capable of forming a resist pattern by developing with an alkali developing solution, a method of forming a resist pattern using the resist composition, a new compound, and a polymeric compound which is derived from the new compound and is useful for the resist composition.

Priority is claimed on Japanese Patent Application No. 2012-079677, filed on Mar. 30, 2012, the content of which is incorporated herein by reference.

### BACKGROUND ART

Techniques (pattern-forming techniques) in which a fine pattern is formed on top of a substrate, and a lower layer beneath that pattern is then fabricated by conducting etching with this pattern as a mask are widely used in the production of semiconductor device and liquid display device. These types of fine patterns are usually formed from an organic material, and are formed, for example, using a lithography method or a nanoimprint method or the like. In lithography techniques, for example, a resist film composed of a resist material containing a base component such as a resin is formed on a support such as a substrate, and the resist film is subjected to selective exposure of radial rays such as light or electron beam, followed by development, thereby forming a resist pattern having a predetermined shape on the resist film. Using this resist pattern as a mask, a semiconductor or the like is produced by conducting a step in which the substrate is processed by etching.

The aforementioned resist material can be classified into positive types and negative types. Resist materials in which the exposed portions exhibit increased solubility in a developing solution is called a positive type, and a resist material in which the exposed portions exhibit decreased solubility in a developing solution is called a negative type.

In general, an aqueous alkali solution (alkali developing solution) such as an aqueous solution of tetramethylammonium hydroxide (TMAH) is used as the developing solution. Alternatively, organic solvents such as aromatic solvents, aliphatic hydrocarbon solvents, ether solvents, ketone solvents, ester solvents, amide solvents and alcohol solvents are used as the developing solution (for example, see Patent Documents 1 and 2).

In recent years, advances in lithography techniques have lead to rapid progress in the field of pattern miniaturization.

Typically, these miniaturization techniques involve shortening the wavelength (increasing the energy) of the exposure light source. Conventionally, ultraviolet radiation typified by g-line and i-line radiation has been used, but nowadays KrF excimer lasers and ArF excimer lasers are starting to be introduced in mass production of semiconductor devices. Furthermore, research is also being conducted into lithography techniques that use an exposure light source having a wavelength shorter (energy higher) than these excimer lasers, such as electron beam (EB), extreme ultraviolet radiation (EUV), and X ray.

As shortening the wavelength of the exposure light source progresses, it is required to improve various lithography properties of the resist material, such as the sensitivity to the exposure light source and a resolution capable of reproducing patterns of minute dimensions. As resist materials which satisfy such requirements, chemically amplified resists are known.

As a chemically amplified composition, a composition including a base material component that exhibits a changed solubility in a developing solution under the action of acid and an acid generator component that generates acid upon exposure is generally used. For example, in the case where an alkali developing solution is used as a developing solution (alkali developing process), a base component which exhibits increased solubility in an alkali developing solution under action of acid is used.

Conventionally, a resin (base resin) is typically used as the base component of a chemically amplified resist composition. Resins that contain structural units derived from (meth)acrylate esters within the main chain (acrylic resins) are the mainstream as base resins for chemically amplified resist compositions that use ArF excimer laser lithography, as they exhibit excellent transparency in the vicinity of 193 nm.

Here, the term “(meth)acrylic acid” is a generic term that includes either or both of acrylic acid having a hydrogen atom bonded to the α-position and methacrylic acid having a methyl group bonded to the α-position. The term “(meth)acrylate ester” is a generic term that includes either or both of the acrylate ester having a hydrogen atom bonded to the α-position and the methacrylate ester having a methyl group bonded to the α-position. The term “(meth)acrylate” is a generic term that includes either or both of the acrylate having a hydrogen atom bonded to the α-position and the methacrylate having a methyl group bonded to the α-position.

In general, the base resin contains a plurality of structural units for improving lithography properties and the like. For example, a structural unit having a lactone structure and a structural unit having a polar group such as a hydroxy group are used, as well as a structural unit having an acid decomposable group which is decomposed by the action of an acid generated from the acid generator to form an alkali soluble group (for example, see Patent Document 3). When the base resin is an acrylic resin, as the acid decomposable group, in general, resins in which the carboxy group of (meth)acrylic acid or the like is protected with an acid dissociable group such as a tertiary alkyl group or an acetal group are used.

As a technique for further improving the resolution, a lithography method called liquid immersion lithography (hereafter, frequently referred to as “immersion exposure”) is known in which exposure (immersion exposure) is conducted in a state where the region between the lens of an exposure apparatus and the resist layer formed on a wafer is filled with a solvent (a immersion medium) that has a larger refractive index than the refractive index of air (see for example, Non-Patent Document 1).

According to this type of immersion exposure, it is considered that higher resolutions equivalent to those obtained using a shorter wavelength light source or a larger NA lens can be obtained, even when a light source with the same wavelength is used, with no lowering of the depth of focus. Furthermore, immersion exposure can be conducted by applying a conventional exposure apparatus. As a result, it is expected that immersion exposure will enable the formation of resist patterns of higher resolution and superior depth of focus at lower costs. Accordingly, in the production of semiconductor devices, which requires enormous capital investment, immersion exposure is attracting considerable attention as a method that offers significant potential to the semiconductor industry, both in terms of cost and in terms of lithography properties such as resolution.

Immersion lithography is effective in forming patterns having various shapes. Further, immersion exposure is expected to be capable of being used in combination with currently studied super-resolution techniques, such as phase shift method and modified illumination method. Currently, as the immersion exposure technique, technique using an ArF excimer laser as an exposure source is being actively studied. Further, water is mainly used as the immersion medium.

As a lithography technique which has been recently proposed, a double patterning method is known in which patterning is conducted two or more times to form a resist pattern (for example, see Non-Patent Documents 2 and 3). There are several different types of double patterning process, for example, (1) a method in which a lithography step (from application of resist compositions to exposure and developing) and an etching step are performed twice or more to form a pattern and (2) a method in which the lithography step is successively performed twice or more. According to the double patterning method, a resist pattern with a higher level of resolution can be formed, as compared to the case where a resist pattern is formed by a single lithography step (namely, a single patterning process), even when a light source with the same exposure wavelength is used, or even when the same resist composition is used. Furthermore, double patterning process can be conducted using a conventional exposure apparatus.

Moreover, a double exposure process has also been proposed in which a resist film is formed, and the resist film is subjected to exposure twice or more, followed by development to form a resist pattern (for example, see Patent Document 4). Like the double patterning process described above, this type of double exposure process is also capable of forming a resist pattern with a high level of resolution, and also has an advantage in that fewer number of steps is required than the above-mentioned double patterning process.

In a positive tone development process using a positive type, chemically amplified resist composition (i.e., a chemically amplified resist composition which exhibits increased solubility in an alkali developing solution upon exposure) in combination with an alkali developing solution, as described above, the exposed portions of the resist film are dissolved and removed by an alkali developing solution to form a resist pattern. The positive tone process using a combination of a positive chemically amplified resist composition and an alkali developing solution is advantageous over a negative tone development process in which a negative type, chemically amplified resist composition is used in combination with an alkali developing solution in that the structure of the photomask can be simplified, a satisfactory contrast for forming an image can be reliably obtained, and the characteristics of the formed resist pattern are excellent. For these reasons, currently, positive-tone development process using a combination of a positive chemically amplified resist composition and an alkali developing solution is mainly employed in the formation of an extremely fine resist pattern.

### DOCUMENTS OF RELATED ART

### Patent Document

[Patent Document 1] Japanese Unexamined Patent Application, First Publication No. Hei 6-194847
[Patent Document 2] Japanese Unexamined Patent Application, First Publication No. 2009-025723
[Patent Document 3] Japanese Unexamined Patent Application, First Publication No. 2003-241385
[Patent Document 4] Japanese Unexamined Patent Application, First Publication No. 2010-040849

### Non-Patent Documents

[Non-Patent Document 1] Proceedings of SPIE (U.S.), vol. 5754, pp. 119-128 (2005)
[Non-Patent Document 2] Proceedings of SPIE (U.S.), vol. 5256, pp. 985-994 (2003)
[Non-Patent Document 3] Proceedings of SPIE (U.S.), vol. 6153, pp. 615301-1-19 (2006)

### SUMMARY OF THE INVENTION

However, as further progress is made in lithography techniques and the application field for lithography techniques expand, further improvement in various lithography properties is demanded in a positive-tone developing process using a combination of a positive chemically amplified resist composition and an alkali developing solution.

For example, in the formation of an extremely small pattern (such as an isolated trench pattern, an extremely small, dense contact hole pattern, or the like), a region where the optical strength becomes weak is likely to be generated especially in the film thickness direction, thereby deteriorating the dimension uniformity of the resist pattern and the shape of the pattern.

In the formation of the aforementioned extremely small pattern, a method of forming a resist pattern (negative pattern) in which regions where the optical strength becomes weak are selectively dissolved and removed is useful. For forming a negative pattern with a chemically amplified resist composition used in a positive-tone developing process which is the mainstream, a method in which a developing solution containing an organic solvent (organic developing solution) is used in combination with a chemically amplified resist composition is known. However, negative-tone developing process is inferior to a positive-tone developing process using an alkali developing solution in combination with a chemically amplified resist composition in terms of environment, apparatus and cost. Thus, a novel method of forming a resist pattern has been demanded which is capable of forming a negative-tone resist pattern with excellent lithography properties.

The present invention takes the above circumstances into consideration, with an object of providing a resist composition exhibiting excellent lithography properties, a method of forming a resist pattern using the resist composition, and a novel compound useful for the resist composition.

As a result of intensive studies, the present inventors have invented a method of forming a negative pattern in which a resist film formed by a resist composition containing a base component that exhibits increased solubility in an alkali developing solution by the action of an acid and a photobase generator component that generates base upon exposure has the exposed portions remaining and the unexposed portions dissolved and removed by an “alkali developing solution” (Japanese Unexamined Patent Application, First Publication No. 2011-106577). As a result of further studies of the present inventors, it has been found that, by controlling the diffusion of the base generated at exposed portions of the resist film, a resist pattern with an excellent dimension uniformity can be formed. The present invention has been completed based on this finding.

Specifically, a first aspect of the present invention is a resist composition including a base component (A) which generates base upon exposure and exhibits changed solubility in a developing solution under action of acid, the base component (A) contains a polymeric compound (A1) having a structural unit derived from a compound represented by general formula (a0-m) shown below.

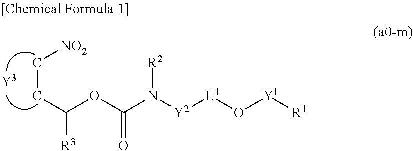

In the formula, R¹ represents a polymerizable group; Y¹ represents a hydrocarbon group of 1 to 30 carbon atoms which may have a substituent; L¹ represents a single bond or a carbonyl group; Y² represents a divalent linking group, and R² represents a hydrogen atom or a hydrocarbon group which may have a substituent, provided that Y² and R² may be mutually bonded to form a ring with the nitrogen atom having Y² and R² bonded thereto; R³ represents a hydrogen atom or a hydrocarbon group which may have a substituent; and Y³ represents a group which forms an aromatic ring together with the two carbon atoms having Y³ bonded thereto, provided that the aromatic ring may have a nitro group or a substituent other than the nitro group bonded to the aromatic ring.

A second aspect of the present invention is a method of forming a resist pattern, including: forming a resist film on a substrate using a resist composition according to the first aspect, subjecting the resist film to exposure, and subjecting the resist film to developing to form a resist pattern.

A third aspect of the present invention is a compound represented by general formula (a0-m) shown below.

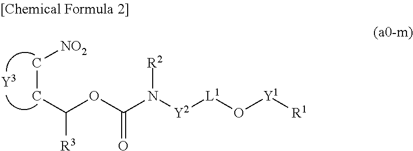

In the formula, R¹ represents a polymerizable group; Y¹ represents a hydrocarbon group of 1 to 30 carbon atoms which may have a substituent; L¹ represents a single bond or a carbonyl group; Y² represents a divalent linking group, and R² represents a hydrogen atom or a hydrocarbon group which may have a substituent, provided that Y² and R² may be mutually bonded to form a ring with the nitrogen atom having Y² and R² bonded thereto; R³ represents a hydrogen atom or a hydrocarbon group which may have a substituent; and Y³ represents a group which forms an aromatic ring together with the two carbon atoms having Y³ bonded thereto, provided that the aromatic ring may have a nitro group or a substituent other than the nitro group bonded to the aromatic ring.

A fourth aspect of the present invention is a polymeric compound having a structural unit derived from the compound of the third aspect.

According to the present invention, there are provided a resist composition exhibiting excellent lithography properties, a method of forming a resist pattern using the resist composition, and a novel compound useful for the resist composition.

### BRIEF DESCRIPTION OF THE DRAWINGS

FIG. 1 is a schematic diagram showing an example of one embodiment of the method of forming a resist pattern according to the present invention.

### MODE FOR CARRYING OUT THE INVENTION

In the present description and claims, the term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified.

The term “alkylene group” includes linear, branched or cyclic, divalent saturated hydrocarbon, unless otherwise specified. The same applies for the alkyl group within an alkoxy group.

A “halogenated alkyl group” is a group in which part or all of the hydrogen atoms of an alkyl group is substituted with a halogen atom. Examples of the halogen atom include a fluorine atom, a chlorine atom, a bromine atom and an iodine atom.

A “fluorinated alkyl group” or a “fluorinated alkylene group” is a group in which part or all of the hydrogen atoms of an alkyl group or an alkylene group have been substituted with fluorine atom(s).

The term “structural unit” refers to a monomer unit that contributes to the formation of a polymeric compound (resin, polymer, copolymer).

A “structural unit derived from an acrylate ester” refers to a structural unit that is formed by the cleavage of the ethylenic double bond of an acrylate ester.

An “acrylate ester” refers to a compound in which the terminal hydrogen atom of the carboxy group of acrylic acid (CH₂═CH—COOH) has been substituted with an organic group.

The acrylate ester may have the hydrogen atom bonded to the carbon atom on the α-position substituted with a substituent. The substituent that substitutes the hydrogen atom bonded to the carbon atom on the α-position is atom other than hydrogen or a group, and examples thereof include an alkyl group of 1 to 5 carbon atoms, a halogenated alkyl group of 1 to 5 carbon atoms and a hydroxyalkyl group. A carbon atom on the α-position of an acrylate ester refers to the carbon atom bonded to the carbonyl group, unless specified otherwise.

Hereafter, an acrylate ester having the hydrogen atom bonded to the carbon atom on the α-position substituted with a substituent is sometimes referred to as “α-substituted acrylate ester”. Further, acrylate esters and α-substituted acrylate esters are collectively referred to as “(α-substituted) acrylate ester”.

A “structural unit derived from hydroxystyrene or a hydroxystyrene derivative” refers to a structural unit that is formed by the cleavage of the ethylenic double bond of hydroxystyrene or a hydroxystyrene derivative.

The term “hydroxystyrene derivative” includes compounds in which the hydrogen atom at the α-position of hydroxystyrene has been substituted with another substituent such as an alkyl group or a halogenated alkyl group; and derivatives thereof. Examples of the derivatives thereof include hydroxystyrene in which the hydrogen atom of the hydroxy group has been substituted with an organic group and which may have the hydrogen atom on the α-position substituted with a substituent; and hydroxystyrene which has a substituent other than a hydroxy group bonded to the benzene ring and which may have the hydrogen atom on the α-position substituted with a substituent. Here, the α-position (carbon atom on the α-position) refers to the carbon atom having the benzene ring bonded thereto, unless specified otherwise.

As the substituent which substitutes the hydrogen atom on the α-position of hydroxystyrene, the same substituents as those described above for the substituent on the α-position of the aforementioned α-substituted acrylate ester can be mentioned.

A “structural unit derived from vinylbenzoic acid or a vinylbenzoic acid derivative” refers to a structural unit that is formed by the cleavage of the ethylenic double bond of vinylbenzoic acid or a vinylbenzoic acid derivative.

The term “vinylbenzoic acid derivative” includes compounds in which the hydrogen atom at the α-position of vinylbenzoic acid has been substituted with another substituent such as an alkyl group or a halogenated alkyl group; and derivatives thereof. Examples of the derivatives thereof include benzoic acid in which the hydrogen atom of the carboxy group has been substituted with an organic group and which may have the hydrogen atom on the α-position substituted with a substituent; and benzoic acid which has a substituent other than a hydroxy group and a carboxy group bonded to the benzene ring and which may have the hydrogen atom on the α-position substituted with a substituent. Here, the α-position (carbon atom on the α-position) refers to the carbon atom having the benzene ring bonded thereto, unless specified otherwise.

The term “styrene” includes styrene and compounds in which the hydrogen atom at the α-position of styrene has been substituted with another substituent such as an alkyl group or a halogenated alkyl group.

A “structural unit derived from styrene” and a “structural unit derived from styrene derivative” refer to a structural unit that is formed by the cleavage of the ethylenic double bond of styrene or a styrene derivative.

As the alkyl group as the substituent on the α-position, a linear or branched alkyl group is preferable, and specific examples include an alkyl group of 1 to 5 carbon atoms such as a methyl group, an ethyl group, a propyl group, an isopropyl group, an n-butyl group, an isobutyl group, a tert-butyl group, a pentyl group, an isopentyl group and a neopentyl group.

Specific examples of the halogenated alkyl group as the substituent on the α-position include groups in which part or all of the hydrogen atoms of the aforementioned “alkyl group as the substituent on the α-position” are substituted with halogen atoms. Examples of the halogen atom include a fluorine atom, a chlorine atom, a bromine atom and an iodine atom, and a fluorine atom is particularly desirable.

Specific examples of the hydroxyalkyl group as the substituent on the α-position include groups in which part or all of the hydrogen atoms of the aforementioned “alkyl group as the substituent on the α-position” are substituted with a hydroxy group. The number of hydroxy groups within the hydroxyalkyl group is preferably 1 to 5, and most preferably 1.

A group “may have a substituent” means a group in which a hydrogen atom (—H) in the structure thereof has been substituted with a monovalent group, or a group in which a methylene group (—CH₂—) in the structure thereof has been substituted with a divalent group.

The term “exposure” is used as a general concept that includes irradiation with any form of radiation.

An “organic group” refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

<<Resist Composition>>

The resist composition according to a first aspect of the present invention includes a base component (A) which generates base upon exposure and exhibits changed solubility in a developing solution under action of acid (hereafter, frequently referred to as “component (A)”).

<Base Component (A)>

In the present invention, the term “base component” refers to an organic compound capable of forming a film.

As the base component, an organic compound having a molecular weight of 500 or more is used. When the organic compound has a molecular weight of 500 or more, the organic compound exhibits a satisfactory film-forming ability, and a resist pattern of nano level can be easily formed.

The “organic compound having a molecular weight of 500 or more” is broadly classified into non-polymers and polymers.

In general, as a non-polymer, any of those which have a molecular weight in the range of 500 to less than 4,000 is used. Hereafter, a “low molecular weight compound” refers to a non-polymer having a molecular weight in the range of 500 to less than 4,000.

As a polymer, any of those which have a molecular weight of 1,000 or more is generally used. In the present description and claims, the term “polymeric compound” refers to a polymer having a molecular weight of 1,000 or more.

With respect to a polymeric compound, the “molecular weight” is the weight average molecular weight in terms of the polystyrene equivalent value determined by gel permeation chromatography (GPC).

The component (A) includes a polymeric compound (A1) (hereafter, frequently referred to as “component (A1)”) containing a structural unit derived from a compound represented by general formula (a0-m) (hereafter, referred to as “structural unit (a0)”).

As the component (A), only the component (A1) may be used, or the component (A1) and a low molecular compound or a polymeric compound other than the component (A 1) may be used in combination.

When the component (A) which exhibits changed solubility in a developing solution by the action of acid includes the component (A1), at unexposed portions of a resist film, the solubility of the component (A) in an alkali developing solution is increased by the action of acid. On the other hand, at exposed portions of a resist film, base is generated from a structural unit (a0) upon exposure, and by the interaction between the base and acid, the solubility of the component (A) in an alkali developing solution is either unchanged or only slightly changed.

[Polymeric Compound (A1)]

The component (A1) includes a structural unit (a0).

As the component (A1), it is preferable to include, in addition to the structural unit (a0), a structural unit containing an acid decomposable group that exhibits increased polarity by the action of acid (hereafter, referred to as “structural unit (a1)”).

(Structural Unit (a0))

The structural unit (a0) is a structural unit derived from a compound represented by general formula (a0-m) shown below.

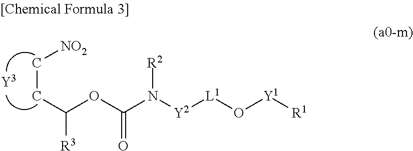

In the formula, R¹ represents a polymerizable group; Y¹ represents a hydrocarbon group of 1 to 30 carbon atoms which may have a substituent; L¹ represents a single bond or a carbonyl group; Y² represents a divalent linking group, and R² represents a hydrogen atom or a hydrocarbon group which may have a substituent, provided that Y² and R² may be mutually bonded to form a ring with the nitrogen atom having Y² and R² bonded thereto; R³ represents a hydrogen atom or a hydrocarbon group which may have a substituent; and Y³ represents a group which forms an aromatic ring together with the two carbon atoms having Y³ bonded thereto, provided that the aromatic ring may have a nitro group or a substituent other than the nitro group bonded to the aromatic ring.

In the formula (a0-m), R¹ represents a polymerizable group.

A “polymerizable group” refers to a group that renders a compound containing the group polymerizable by a radical polymerization or the like, for example, a group having a carbon-carbon multiple bond, such as an ethylenic double bond.

Examples of the polymerizable group for R¹ include a vinyl group, an allyl group, an acryloyl group, a methacryloyl group, a fluorovinyl group, a difluorovinyl group, a trifluorovinyl group, a difluorotrifluoromethylvinyl group, a trifluoroallyl group, a perfluoroallyl group, a trifluoromethylacryloyl group, a nonylfluorobutylacryloyl group, a vinyl ether group, a fluorinated vinyl ether group, an allyl ether group, a fluorinated allyl ether group, a styryl group, a fluorinated styryl group, a norbornyl group, a fluorinated norbornyl group and a silyl group.

In general formula (a0-m), Y¹ represents a hydrocarbon group of 1 to 30 carbon atoms which may have a substituent. Here, the number of carbon atoms within a substituent(s) is not included in the number of carbon atoms of the hydrocarbon group.

The hydrocarbon group for Y¹ may be either an aliphatic hydrocarbon group, or an aromatic hydrocarbon group.

The aliphatic hydrocarbon group for Y¹ refers to a hydrocarbon group that has no aromaticity. The aliphatic hydrocarbon group may be saturated or unsaturated. In general, the aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 12 carbon atoms, more preferably 1 to 10, still more preferably 1 to 8, and particularly preferably 1 to 5.

As the linear aliphatic hydrocarbon group, a linear alkylene group is preferable, and specific examples include a methylene group [—CH₂—], an ethylene group [—(CH₂)₂-], a trimethylene group [—(CH₂)₃-], a tetramethylene group [—(CH₂)₄-] and a pentamethylene group [—(CH₂)₅-].

As the branched aliphatic hydrocarbon group, a branched alkylene group is preferable, and specific examples include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —C(CH₃)₂C(CH₃)₂—, —CH(CH₂CH₃)CH₂—, —C(CH₂CH₃)₂—CH₂—, —CH₂—CH(C₂H₅)—, —CH₂—CH(C₃H₇)—, and —CH₂—CH(C₄H₉)—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—.

As the alkyl group within the alkylalkylene group, a linear alkyl group of 1 to 5 carbon atoms is preferable.

The linear or branched aliphatic hydrocarbon group may have a substituent (a group or an atom other than a hydrogen atom).

In the case where a hydrogen atom (—H) of the aliphatic hydrocarbon group is substituted with a monovalent group, examples of the monovalent group include an alkoxy group of 1 to 5 carbon atoms, a hydroxy group (—OH), an aromatic ring, a mercapto group (—SH), an amino group (—NH₂), a heterocycle, a fluorine atom and a fluorinated alkyl group of 1 to 5 carbon atoms. Examples of aromatic rings include groups in which one hydrogen atom has been removed from aromatic hydrocarbon rings, such as benzene, naphthalene, anthracene and phenanthrene. As the heterocycle, an aliphatic heterocycle in which part of the carbon atoms constituting a monovalent cyclic aliphatic hydrocarbon group has been substituted with a hetero atom (e.g., a five-membered ring containing a nitrogen atom or a six-membered ring containing a nitrogen atom) and an aromatic heterocycle in which part of the carbon atoms constituting the aforementioned aromatic hydrocarbon ring has been substituted with a hetero atom (e.g., a pyridine ring and a thiophene ring) can be mentioned.

When the methylene group (—CH₂—) within the aliphatic hydrocarbon group is substituted with a divalent group, examples of the divalent group include an oxygen atom (—O—), a carbonyl group (—C(═O)—) and —NH—.

As examples of the aliphatic hydrocarbon group containing a ring in the structure thereof, a cyclic aliphatic hydrocarbon group which may have a substituent containing a hetero atom in the ring structure thereof (e.g., a group in which two hydrogen atoms have been removed from an aliphatic hydrocarbon ring), a group in which the cyclic aliphatic hydrocarbon group is bonded to the terminal of the aforementioned linear or branched aliphatic hydrocarbon group, and a group in which the cyclic aliphatic hydrocarbon group is interposed within the aforementioned linear or branched aliphatic hydrocarbon group, can be given. As the linear or branched aliphatic hydrocarbon group, the same groups as those described above can be used.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic aliphatic hydrocarbon group, a group in which two hydrogen atoms have been removed from a polycycloalkane is preferable, and the polycycloalkane preferably has 7 to 12 carbon atoms. Examples of the polycycloalkane include adamantane, norbornane, isobornane, tricyclodecane and tetracyclododecane.

The cyclic aliphatic hydrocarbon group may or may not have a substituent (a group or an atom other than a hydrogen atom) for substituting the hydrogen atom. Examples of substituents include an alkyl group, an alkoxy group, a halogen atom, a halogenated alkyl group, a hydroxyl group and an oxo group (═O).

The alkyl group which substitutes the hydrogen atom within the cyclic aliphatic hydrocarbon group is preferably an alkyl group having 1 to 5 carbon atoms, and most preferably a methyl group, an ethyl group, a propyl group, an n-butyl group, or a tert-butyl group.

The alkoxy group which substitutes the hydrogen atom within the cyclic aliphatic hydrocarbon group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom which substitutes the hydrogen atom within the cyclic aliphatic hydrocarbon group include a fluorine atom, a chlorine atom, a bromine atom and an iodine atom, and a fluorine atom is particularly desirable.

Example of the halogenated alkyl group which substitutes the hydrogen atom within the cyclic aliphatic hydrocarbon group includes a group in which part or all of the hydrogen atoms within the aforementioned alkyl group have been substituted with the aforementioned halogen atoms.

In the cyclic aliphatic hydrocarbon groups, part of the carbon atoms constituting the ring structure may be substituted with a hetero atom-containing substituent group. The hetero atom-containing substituent group is preferably —O—, —C(═O)—O—, —S—, —S(═O)₂— or —S(═O)₂—O—.

The aromatic hydrocarbon group for Y¹ is a divalent hydrocarbon group having at least one aromatic ring, and may have a substituent. The aromatic ring is not particularly limited, as long as it is a cyclic conjugated compound having 4n+2π electrons, and may be either monocyclic or polycyclic. The aromatic ring preferably has 5 to 20 carbon atoms, more preferably 6 to 15 carbon atoms, and particularly preferably 6 to 12 carbon atoms. Here, the number of carbon atoms within a substituent(s) is not included in the number of carbon atoms of the aromatic hydrocarbon group.

Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom. Specific examples of the aromatic hetero ring include a pyridine ring and a thiophene ring.

Specific examples of the aromatic hydrocarbon group for Y¹ include a group in which two hydrogen atoms have been removed from the aforementioned aromatic hydrocarbon ring or aromatic hetero ring (arylene group or heteroarylene group); a group in which two hydrogen atoms have been removed from an aromatic compound having two or more aromatic rings (biphenyl, fluorene or the like); and a group in which one hydrogen atom of an aryl group or heteroaryl group (i.e., a group in which one hydrogen atom has been removed from the aforementioned aromatic hydrocarbon ring or aromatic hetero ring) has been substituted with an alkylene group (a group in which one hydrogen atom has been removed from the aryl group within the aforementioned arylalkyl group such as a benzyl group, a phenethyl group, a 1-naphthylmethyl group, a 2-naphthylmethyl group, a 1-naphthylethyl group, or a 2-naphthylethyl group). The alkylene group which is bonded to the aforementioned aryl group or heteroaryl group preferably has 1 to 4 carbon atoms, more preferably 1 or 2 carbon atoms, and particularly preferably 1 carbon atom.

The aromatic hydrocarbon group for Y¹ may or may not have a substituent. For example, the hydrogen atom bonded to the aromatic ring within the aromatic hydrocarbon group may be substituted with a substituent. Examples of substituents include an alkyl group, an alkoxy group, a halogen atom, a halogenated alkyl group, a hydroxyl group and an oxo group (═O). As the alkyl group, the alkoxy group, the halogen atom and the halogenated alkyl group which substitute the hydrogen atom bonded to the aromatic ring, the same groups as those described above for the alkyl group, the alkoxy group, the halogen atom and the halogenated alkyl group as a substituent which substitutes the hydrogen atom bonded to the cyclic aliphatic hydrocarbon group, can be mentioned.

In formula (a0-m) above, L¹ represents a single bond or a carbonyl group, and is preferably a carbonyl group. Further, when Y¹ does not have a carbonyl group, L¹ is preferably a carbonyl group.

In formula (a0-m) above, Y² represents a divalent linking group.

The divalent linking group for Y² is not particularly limited, and preferable examples thereof include a divalent hydrocarbon group which may have a substituent and a divalent linking group containing a hetero atom.

Examples of divalent hydrocarbon groups for Y² which may have a substituent include the same groups as those described above for the divalent hydrocarbon group of 1 to 30 carbon atoms which may have a substituent usable as Y′.

With respect to a “divalent linking group containing a hetero atom” for Y², a hetero atom is an atom other than carbon atom and hydrogen atom, and examples thereof include an oxygen atom, a nitrogen atom, a sulfur atom and a halogen atom.

Examples of the divalent linking group containing a hetero atom include —O—, —C(═O)—O—, —C(═O)—, —O—C(═O)—O—, —C(═O)—NH—, —NH— (wherein H may be substituted with a substituent such as an alkyl group or an acyl group), —S—, —S(═O)₂—, —S(═O)₂—O—, —NH—C(═O)—, ═N—, and a group represented by general formula —Y²¹—O—Y²²—, —[Y²¹—C(═O)—O]_{m′}—Y²²—, (═O)—O—Y²²— or u) Y²²— [in the formulae, each of Y²¹ and Y²² independently represents a divalent hydrocarbon group which may have a substituent; 0 represents an oxygen atom; and m′ represents an integer of 0 to 3].

When Y² represents —NH—, H may be substituted with a substituent such as an alkyl group, an acyl group or the like. The substituent (an alkyl group, an acyl group or the like) preferably has 1 to 10 carbon atoms, more preferably 1 to 8, and particularly preferably 1 to 5.

Each of Y²¹ and Y²² independently represents a divalent hydrocarbon group which may have a substituent. As the divalent hydrocarbon group, the same groups as those described above for the “divalent hydrocarbon group which may have a substituent” for Y² can be mentioned.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]_{m′}—Y²²—, m′ represents an integer of 0 to 3, preferably an integer of 0 to 2, more preferably 0 or 1, and particularly preferably 1. Namely, it is particularly desirable that the group represented by the formula —[Y²¹—C(═O)—O]_{m′}—Y²²— is a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

As the divalent linking group containing a hetero atom, a linear group containing an oxygen atom as the hetero atom, for example, a group containing an ether bond or an ester bond is preferable, and a group represented by the aforementioned formula —Y²¹—O—Y²²—, —[Y²¹—C(═O)—O]_{m′}—Y²²— or —Y²¹—O—C(═O)—Y²²— is more preferable.

As Y², a divalent hydrocarbon group which may have a substituent is preferable, a linear or branched alkylene group or an aliphatic hydrocarbon group containing a ring in the structure thereof is more preferable, and a linear or branched alkylene group of 1 to 6 carbon atoms or a group in which two hydrogen atoms have been removed from a polycycloalkane is still more preferable.

In formula (a0-m), R² represents a hydrogen atom or a hydrocarbon group which may have a substituent.

The hydrocarbon group which may have a substituent may be either an aromatic hydrocarbon group or an aliphatic hydrocarbon group.

The aromatic hydrocarbon group as the hydrocarbon group for R² is a hydrocarbon group having an aromatic ring. The aromatic hydrocarbon group preferably has 5 to 30 carbon atoms, more preferably 5 to 20, still more preferably 6 to 15, and most preferably 6 to 12. Here, the number of carbon atoms within a substituent(s) is not included in the number of carbon atoms of the aromatic hydrocarbon group.

Specific examples of aromatic hydrocarbon groups include an aryl group which is an aromatic hydrocarbon ring having one hydrogen atom removed therefrom, such as a phenyl group, a biphenyl group, a fluorenyl group, a naphthyl group, an anthryl group or a phenanthryl group; and an alkylaryl group such as a benzyl group, a phenethyl group, a 1-naphthylmethyl group, a 2-naphthylmethyl group, a 1-naphthylethyl group, or a 2-naphthylethyl group. The alkyl chain within the arylalkyl group preferably has 1 to 4 carbon atom, more preferably 1 or 3, and particularly preferably 1 or 2.

The aromatic hydrocarbon group may have a substituent. For example, part of the carbon atoms constituting the aromatic ring within the aromatic hydrocarbon group may be substituted with a hetero atom, or a hydrogen atom bonded to the aromatic ring within the aromatic hydrocarbon group may be substituted with a substituent.

In the former example, a heteroaryl group in which part of the carbon atoms constituting the ring within the aforementioned aryl group has been substituted with a hetero atom such as an oxygen atom, a sulfur atom or a nitrogen atom, and a heteroarylalkyl group in which part of the carbon atoms constituting the aromatic hydrocarbon ring within the aforementioned arylalkyl group has been substituted with the aforementioned hetero atom can be used.

In the latter example, as the substituent for the aromatic hydrocarbon group, an alkyl group, an alkoxy group, a halogen atom, a halogenated alkyl group, a hydroxyl group, an oxygen atom (═O), a nitro group or the like can be used. These substituents (i.e., the alkyl group, the alkoxy group, the halogen atom and the halogenated alkyl group) are the same groups as those described above for the substituents (i.e., the alkyl group, the alkoxy group, the halogen atom and the halogenated alkyl group) as a substituent which substitutes the hydrogen atom bonded to the aromatic ring of the aromatic hydrocarbon group for Y¹.

The aliphatic hydrocarbon group as the hydrocarbon group for R² may be either a saturated aliphatic hydrocarbon group, or an unsaturated aliphatic hydrocarbon group. Further, the aliphatic hydrocarbon group may be linear, branched or cyclic.

As the aliphatic hydrocarbon group for the hydrocarbon group represented by R², a linear or branched saturated hydrocarbon group, a linear or branched monovalent unsaturated hydrocarbon group, or a cyclic aliphatic hydrocarbon group (aliphatic cyclic group) is preferable.

The linear saturated hydrocarbon group (alkyl group) preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched saturated hydrocarbon group (alkyl group) preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The unsaturated hydrocarbon group as the hydrocarbon group for R² preferably has 2 to 10 carbon atoms, more preferably 2 to 5, still more preferably 2 to 4, and particularly preferably 3. Examples of linear monovalent unsaturated hydrocarbon groups include a vinyl group, a propenyl group (an allyl group) and a butynyl group. Examples of branched monovalent unsaturated hydrocarbon groups include a 1-methylpropenyl group and a 2-methylpropenyl group.

Among the above-mentioned examples, as the unsaturated hydrocarbon group, a propenyl group is particularly desirable.

The cyclic aliphatic hydrocarbon group (aliphatic cyclic group) as the hydrocarbon group for R² is preferably an aliphatic cyclic group of 3 to 30 carbon atoms which may have a substituent.

The aliphatic cyclic group may be either a monocyclic group or a polycyclic group. The aliphatic cyclic group preferably has 5 to 30 carbon atoms, more preferably 5 to 20, still more preferably 6 to 15, and particularly preferably 6 to 12.

As the aliphatic cyclic group, a group in which one or more hydrogen atoms have been removed from a monocycloalkane or a polycycloalkane such as a bicycloalkane, tricycloalkane or tetracycloalkane can be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

When the aliphatic cyclic group does not contain a hetero atom-containing substituent group in the ring structure thereof, the aliphatic cyclic group is preferably a polycyclic group, more preferably a group in which one or more hydrogen atoms have been removed from a polycycloalkane, and a group in which one or more hydrogen atoms have been removed from adamantane is most desirable.

When the aliphatic cyclic group contains a hetero atom-containing substituent group in the ring structure thereof, the hetero atom-containing substituent group is preferably —O—, —C(═O)—O—, —S—, —S(═O)₂— or —S(═O)₂—O—. Specific examples of such aliphatic cyclic groups include groups represented by formulas (L1) to (L6) and (S1) to (S4) shown below.

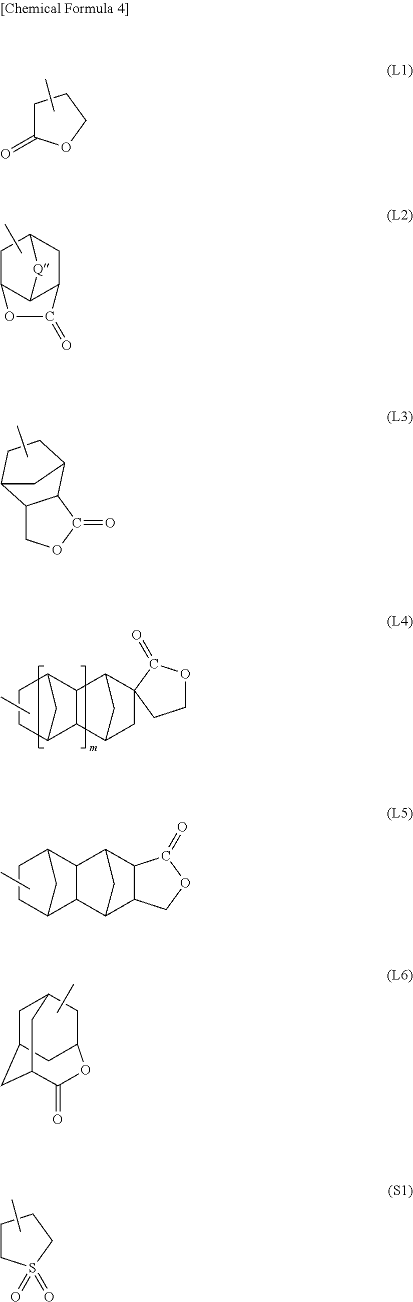

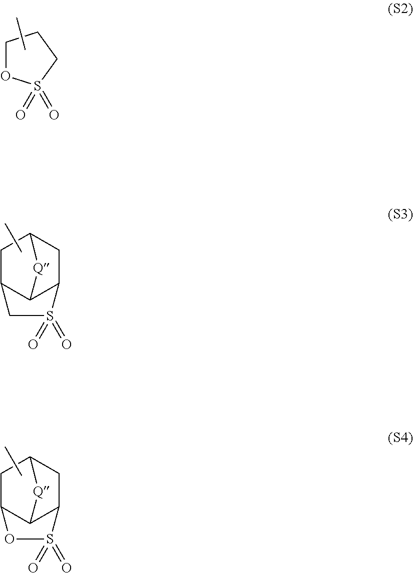

In the formulas, Q″ represents an alkylene group of 1 to 5 carbon atoms, —O—, —S—, —O—R⁹⁴— or —S—R⁹⁵— (wherein R⁹⁴ and R⁹⁵ each independently represent an alkylene group of 1 to 5 carbon atoms); and m represents an integer of 0 or 1.

In the formulas, the alkylene group for R⁹⁴ and R⁹⁵ is preferably a linear or branched alkylene group, and has 1 to 5 carbon atoms, preferably 1 to 3.

Specific examples of the alkylene group include a methylene group [—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group [—CH₂CH₂—]; alkylethylene groups such as —CH(CH₃)CH₂—, —CH(CH₃)CH(CH₃)—, —C(CH₃)₂CH₂— and —CH(CH₂CH₃)CH₂—; a trimethylene group (n-propylene group) [—CH₂CH₂CH₂—]; alkyltrimethylene groups such as —CH(CH₃)CH₂CH₂— and —CH₂CH(CH₃)CH₂—; a tetramethylene group [—CH₂CH₂CH₂CH₂—]; alkyltetramethylene groups such as —CH(CH₃)CH₂CH₂CH₂— and —CH₂CH(CH₃)CH₂CH₂—; and a pentamethylene group [—CH₂CH₂CH₂CH₂CH₂—].

In the aliphatic hydrocarbon group, part of the carbon atoms constituting the aliphatic hydrocarbon group may be substituted with a substituent group containing a hetero atom, or part or all of the hydrogen atoms constituting the aliphatic hydrocarbon group may be substituted with a substituent group containing a hetero atom. As the “hetero atom”, there is no particular limitation as long as it is an atom other than carbon atom and hydrogen, and examples thereof include a halogen atom, an oxygen atom, a sulfur atom and a nitrogen atom. Examples of the halogen atom include a fluorine atom, a chlorine atom, an iodine atom and a bromine atom.

The substituent group containing a hetero atom may consist of a hetero atom, or may be a group containing a group or atom other than a hetero atom.

Specific examples of the substituent group for substituting a part of the carbon atoms include —O—, —C(═O)—O—, —C(═O)—, —O—C(═O)—O—, —C(═O)—NH—, —NH— (the H may be substituted with a substituent such as an alkyl group or an acyl group), —S—, —S(═O)₂— and —S(═O)₂—O—. When the aliphatic hydrocarbon group is cyclic, the aliphatic hydrocarbon group may contain any of these substituent groups in the ring structure.

Examples of the substituent group for substituting part or all of the hydrogen atoms include an alkoxy group, a halogen atom, a halogenated alkyl group, a hydroxyl group, an oxygen atom (═O), a cyano group and a nitro group. The alkoxy group, the halogen atom and the halogenated alkyl group as the substituent are the same as defined for the alkoxy group, the halogen atom and the halogenated alkyl group as the substituent for the aromatic hydrocarbon group.

Among these, as R², a hydrogen atom or an aliphatic hydrocarbon group which may have a substituent is preferable, and a hydrogen atom or a linear or branched alkyl group is more preferable.

In formula (a0-m) above, Y² and R² may be mutually bonded to form a ring with the nitrogen atom having Y² and R² bonded thereto. As the ring to be formed, a ring having 2 to 8 carbon atoms is preferable, and a ring having 4 to 6 carbon atoms is particularly desirable. Specific examples of the ring include an ethyleneimine ring, a pyrrolidine ring and a piperidine ring.

In formula (a0-m) above, R³ represents a hydrogen atom or a hydrocarbon group which may have a substituent.

Examples of the hydrocarbon group which may have a substituent for R³ include the same hydrocarbon group which may have a substituent as those described above for R². Among these, a linear or branched aliphatic hydrocarbon group or an aromatic hydrocarbon group which may have a substituent is preferable, more preferably a linear or branched alkyl group of 1 to 6 carbon atoms or an aromatic hydrocarbon group which may have a nitro group, and most preferably a methyl group or a phenyl group substituted with a nitro group (particularly preferably a phenyl group substituted with a nitro group on the ortho position).

In formula (a0-m) above, Y³ represents a group which forms an aromatic ring together with the two carbon atoms having Y³ bonded thereto, provided that the aromatic ring may have a nitro group or a substituent other than the nitro group bonded to the aromatic ring.

The aromatic ring formed by Y³ and 2 carbon atoms having Y³ bonded thereto is not particularly limited as long as it is a cyclic conjugated compound having 4n+2π electrons (wherein n represents 0 or a natural number), and may be either monocyclic or polycyclic. The aromatic ring preferably has 5 to 30 carbon atoms, more preferably 5 to 20, still more preferably 6 to 15, and particularly preferably 6 to 12.

Examples of the aromatic ring include aromatic hydrocarbon rings, such as benzene, naphthalene, anthracene, phenanthrene, indene and fluorene; and aromatic hetero rings in which part of the carbon atoms constituting the aforementioned aromatic hydrocarbon rings has been substituted with a hetero atom. Further, the aromatic ring containing two or more aromatic hydrocarbon ring (e.g., biphenyl group and the like) can be mentioned. Examples of the hetero atom within the aromatic hetero rings include an oxygen atom, a sulfur atom and a nitrogen atom. Specific examples of the aromatic hetero ring include pyridine and thiophene. Among these, as the aromatic ring, the aromatic hydrocarbon ring is preferable, and benzene is particularly preferable.

Specific examples of Y³ include ═CH—, ═C<(quaternary carbon atom), —O—, —S—, ═N— and the like. The hydrogen atom within ═CH— may be substituted with a substituent.

Examples of the substituent group for the aromatic ring, in addition to the nitro group which has been already bonded to the aromatic ring, include a nitro group, an oxo group (═O), an alkyl group, an alkoxy group, a halogen atom, a halogenated alkyl group, a hydroxyalkyl group, a hydroxy group, —COOR″, —OC(═O)R″, a cyano group, —NR″₂, —R⁹′—N(R¹⁰′)—C(═O)—O—R⁵′, and a nitrogen-containing heterocyclic group.

Specific examples of aromatic hetero rings having an oxo group (═O) include anthraquinone, thioxanthone and xanthone.

The alkyl group as the substituent for the aromatic ring is preferably an alkyl group of 1 to 6 carbon atoms. Further, the alkyl group is preferably a linear alkyl group or a branched alkyl group.

Specific examples include a methyl group, an ethyl group, a propyl group, an isopropyl group, an n-butyl group, an isobutyl group, a tert-butyl group, a pentyl group, an isopentyl group, a neopentyl group and a hexyl group. Among these, a methyl group or an ethyl group is preferable, and a methyl group is particularly desirable.

The alkoxy group as the substituent for the aromatic ring is preferably an alkoxy group of 1 to 6 carbon atoms. Further, the alkoxy group is preferably a linear or branched alkoxy group. Specific examples of the alkoxy group include the aforementioned alkyl groups for the substituent having an oxygen atom (—O—) bonded thereto.

Examples of the halogen atom for the substituent include a fluorine atom, a chlorine atom, a bromine atom and an iodine atom, and a fluorine atom is preferable.

As examples of the halogenated alkyl group for the substituent, groups in which part or all of the hydrogen atoms of the aforementioned alkyl groups for the substituent have been substituted with the aforementioned halogen atoms can be given. As the halogenated alkyl group, a fluorinated alkyl group is preferable, and a perfluoroalkyl group is particularly desirable.

The hydroxyalkyl group for the substituent preferably has 1 to 6 carbon atoms, and specific examples thereof include a group in which at least one hydrogen atom of the aforementioned alkyl group for the substituent has been substituted with a hydroxy group.

In the —COOR″, —OC(═O)R″ and —NR″₂, R″ represents a hydrogen atom or a linear, branched or cyclic alkyl group of 1 to 15 carbon atoms.

When R″ represents a linear or branched alkyl group, it is preferably an alkyl group of 1 to 10 carbon atoms, more preferably an alkyl group of 1 to 5 carbon atoms, and particularly preferably a methyl group or an ethyl group.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The two R″ groups within the —NR″₂ group may be the same or different from each other.

In formula —R⁹′—N(R¹⁰′)—C(═O)—O—R⁵′, R⁹′ represents a divalent hydrocarbon group which may contain a hetero atom, R¹⁰′ represents a hydrogen atom or a monovalent hydrocarbon group which may contain a hetero atom, and R⁵′ represents a monovalent organic group which has an aliphatic ring or an aromatic ring.

The hydrocarbon group for R¹⁰′ may be an aromatic hydrocarbon group or an aliphatic hydrocarbon group.

The aromatic hydrocarbon group for R¹⁰′ is a hydrocarbon group having at least one aromatic ring. As the aromatic ring, the same aromatic rings as those described above for the aromatic ring formed by the aforementioned Y³ and 2 carbon atoms having Y³ bonded thereto can be mentioned. Specific examples of the aromatic hydrocarbon group for R¹⁰′ include a group in which one hydrogen atom has been removed from the aforementioned aromatic hydrocarbon ring or aromatic hetero ring (aryl group or heteroaryl group); a group in which one hydrogen atom has been removed from an aromatic compound having two or more aromatic rings (biphenyl, fluorene or the like); and a group in which one hydrogen atom of the aforementioned aromatic hydrocarbon ring or aromatic hetero ring has been substituted with an alkylene group (an arylalkyl group such as a benzyl group, a phenethyl group, a 1-naphthylmethyl group, a 2-naphthylmethyl group, a 1-naphthylethyl group, or a 2-naphthylethyl group, or a heteroarylalkyl group). The alkylene group which substitutes the hydrogen atom of the aforementioned aromatic hydrocarbon ring or the aromatic hetero ring preferably has 1 to 4 carbon atoms, more preferably 1 or 2 carbon atoms, and particularly preferably 1 carbon atom.

The aliphatic hydrocarbon group for R¹⁰′ refers to a hydrocarbon group that has no aromaticity.

The aliphatic hydrocarbon group for R¹⁰′ may be either saturated (an alkyl group) or unsaturated. In general, the aliphatic hydrocarbon group is preferably saturated. Further, the aliphatic hydrocarbon group may be linear, branched or cyclic, or a combination thereof. Examples of the combination include a group in which a cyclic aliphatic hydrocarbon group is bonded to a terminal of a linear or branched aliphatic hydrocarbon group, and a group in which a cyclic aliphatic hydrocarbon group is interposed within a linear or branched aliphatic hydrocarbon group.

The linear or branched alkyl group preferably has 1 to 20 carbon atoms, more preferably 1 to 15, and still more preferably 1 to 10.

Specific examples of linear alkyl groups include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

Specific examples of branched alkyl groups include a 1-methylethyl group (an isopropyl group), a 1-methylpropyl group, a 2-methylpropyl group, a 1-methylbutyl group, a 2-methylbutyl group, a 3-methylbutyl group, a 1-ethylbutyl group, a 2-ethylbutyl group, a tert-butyl group, a 1-methylpentyl group, a 2-methylpentyl group, a 3-methylpentyl group and a 4-methylpentyl group.

The cyclic alkyl group may be either a monocyclic group or a polycyclic group. The aliphatic cyclic group preferably has 3 to 30 carbon atoms, more preferably 5 to 30, still more preferably 5 to 20, particularly preferably 6 to 15, and most preferably 6 to 12. As the cyclic alkyl group, a group in which one hydrogen atom has been removed from a monocycloalkane or a polycycloalkane such as a bicycloalkane, tricycloalkane or tetracycloalkane can be used. Specific examples of the group in which one hydrogen atom has been removed from a monocycloalkane include a cyclopentyl group and a cyclohexyl group. Examples of the group in which one hydrogen atom has been removed from a polycycloalkane include an adamantyl group, a norbornyl group, an isobornyl group, a tricyclodecyl group and a tetracyclododecyl group.

The aromatic hydrocarbon group and the aliphatic hydrocarbon group for R¹⁰′ may have a substituent. As the substituent, the same substituents as those described above for substituting “the aromatic ring formed by the aforementioned Y³ and 2 carbon atoms having Y³ bonded thereto can be mentioned.

Examples of the hydrocarbon group for R⁹′ include groups in which one hydrogen atom has been removed from the hydrocarbon group (aromatic hydrocarbon group or aliphatic hydrocarbon group) for R¹⁰′.

The aliphatic ring or the aromatic ring for R⁵′ may be either a hydrocarbon ring or a hetero ring, and preferable examples thereof include groups explained above for R¹⁰′ which have a ring structure, and other aromatic rings. Specific examples of the above hydrocarbon ring and hetero ring include benzene, biphenyl, indene, naphthalene, fluorene, anthracene, phenanthrene, xanthone, thioxanthone and anthraquinone.

Further, these hydrocarbon rings and hetero rings may have a substituent. In terms of base generation efficiency, as the substituent, a nitro group is particularly desirable.

In formula —R⁹′—N(R¹⁰′)—C(═O)—O—R⁵′, R¹⁰′ may be bonded to R⁹′ to form a ring with the nitrogen atom.

The “nitrogen-containing heterocyclic group” as a substituent which the aforementioned aromatic ring may have is a group in which one or more hydrogen atoms have been removed from a nitrogen-containing heterocyclic compound which contains a nitrogen atom in the ring skeleton thereof. The nitrogen-containing heterocyclic compound may have a carbon atom or a hetero atom other than nitrogen (e.g., an oxygen atom, a sulfur atom or the like) within the ring skeleton thereof.

The nitrogen-containing heterocyclic compound may be either aromatic or aliphatic. When the nitrogen-containing heterocyclic compound is aliphatic, it may be either saturated or unsaturated. Further, the nitrogen-containing heterocyclic compound may be either monocyclic or polycyclic.

The nitrogen-containing heterocyclic compound preferably has 3 to 30 carbon atoms, more preferably 5 to 30, and still more preferably 5 to 20.

Specific examples of monocyclic nitrogen-containing heterocycle compound include pyrrole, pyridine, imidazole, pyrazole, 1,2,3-triazole, 1,2,4-triazole, pyrimidine, pyrazine, 1,3,5-triazine, tetrazole, piperidine, piperazine, pyrrolidine and morpholine.

Specific examples of polycyclic nitrogen-containing heterocycle compound include quinoline, isoquinoline, indole, pyrrolo[2,3-b]pyridine, indazole, benzimidazole, benzotriazole, carbazole, acridine, 1,5-diazabicyclo[4.3.0]-5-nonene, 1,8-diazabicyclo[5.4.0]-7-undecene, hexamethylenetetramine and 1,4-diazabicyclo[2.2.2]octane.

The nitrogen-containing heterocyclic compound may have a substituent. As the substituent, the same substituents as those described above for substituting “the aromatic ring formed by the aforementioned Y³ and 2 carbon atoms having Y³ bonded thereto can be mentioned.

Among these, as the substituent which the aromatic ring formed by the aforementioned Y³ and 2 carbon atoms having Y³ bonded thereto may have, an alkoxy group, an aryl group or a nitro group is preferable, and in terms of improvement in the decomposition efficiency during exposure, a nitro group is more preferable. It is preferable that the nitro group substitutes the hydrogen atom bonded to the carbon atom adjacent to the carbon atom having —CH(R³)— bonded thereto (i.e., the carbon atom of the ortho position with respect to —CH(R³)— in the case where the aromatic ring containing Y³ is a benzene ring).

The number of substituents which the aromatic ring formed by the aforementioned Y³ and 2 carbon atoms having Y³ bonded thereto may have is preferably 0 to 4, more preferably 0 to 2, still more preferably 0 or 1, and most preferably 0. If there are two or more substituents, the two or more substituents may be the same or different from each other.

As preferable examples of the structural unit (a0), structural units derived from compounds represented by general formulas (a0-m1) to (a0-m4) shown below can be mentioned. Among these, a structural unit derived from a compound represented by general formula (a0-m1) is preferable.

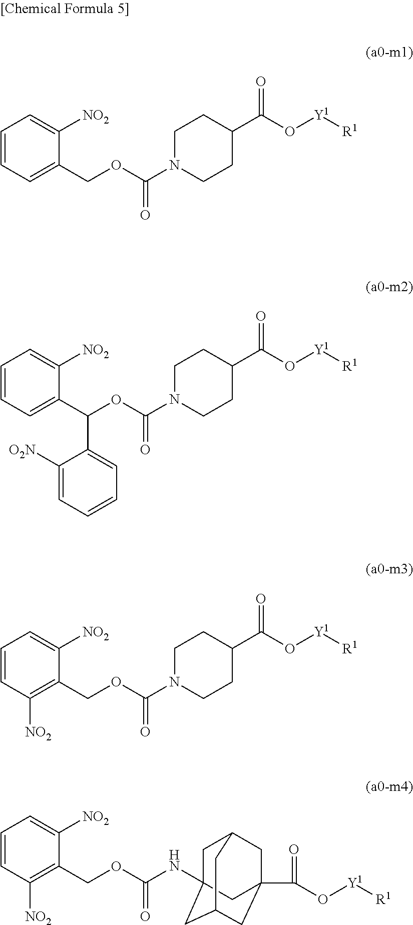

In the formula, R¹ represents a polymerizable group; and Y¹ represents a hydrocarbon group of 1 to 30 carbon atoms which may have a substituent.

In the aforementioned general formulas (a0-m1) to (a0-m4), R¹ and Y¹ are respectively the same as defined for R¹ and Y¹ in the aforementioned formula (a0-m).

Specific examples of structural units represented by the aforementioned general formulas (a0-1) to (a0-4) are shown below.

In the formulas shown below, R^{α} represents a hydrogen atom, a methyl group or a trifluoromethyl group.

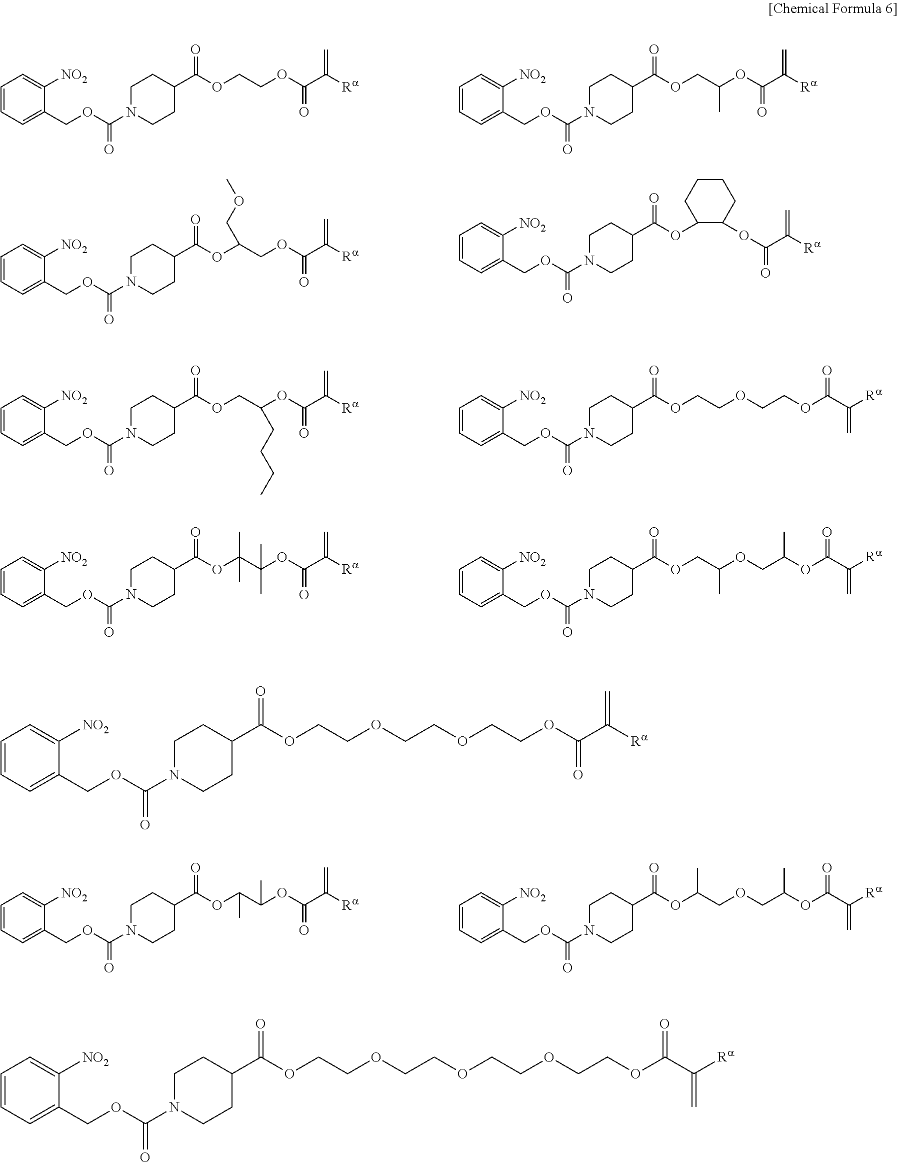

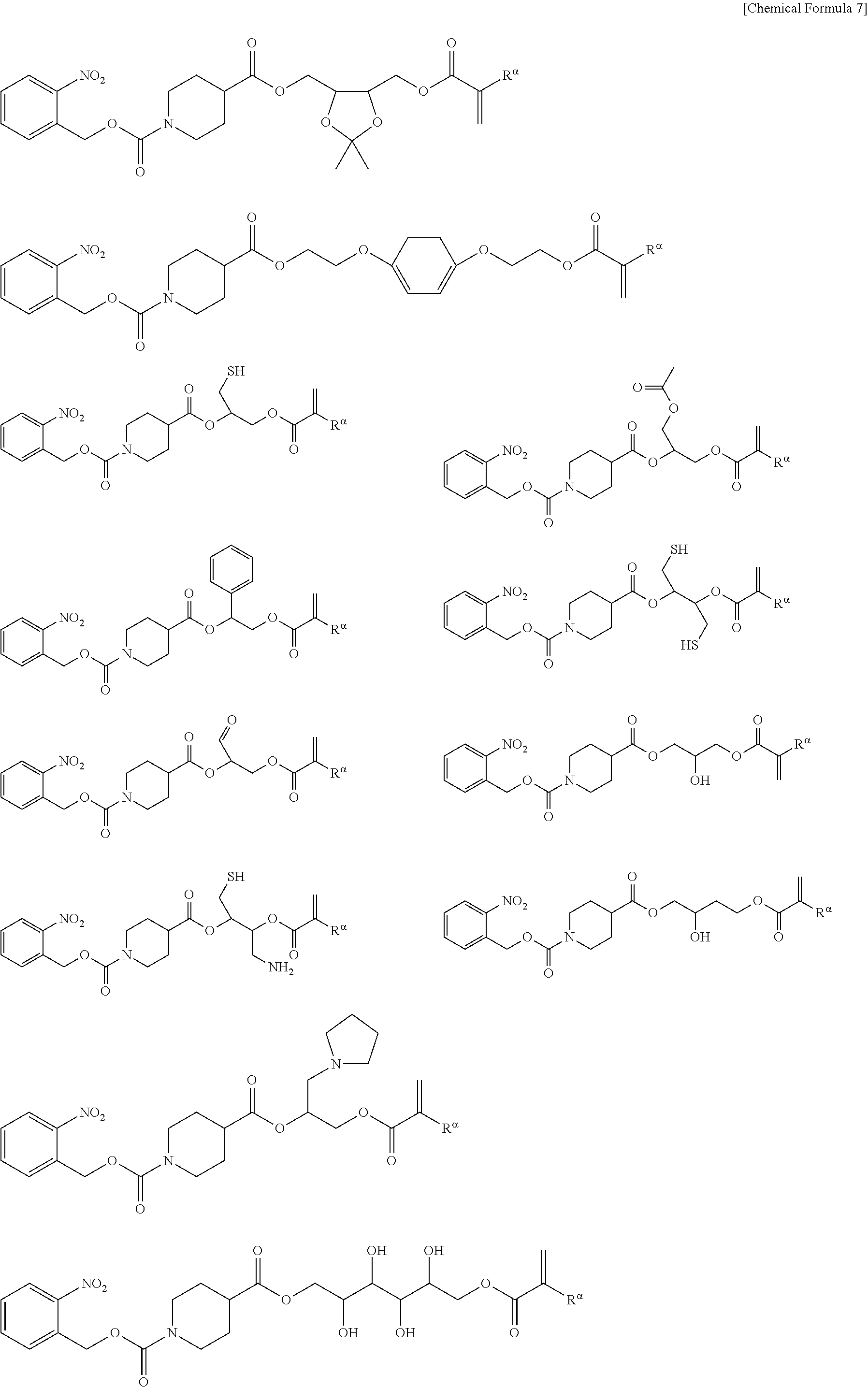

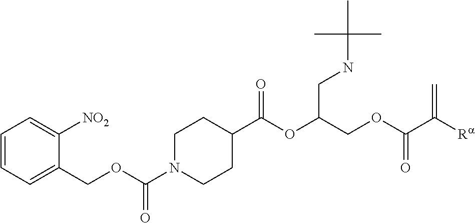

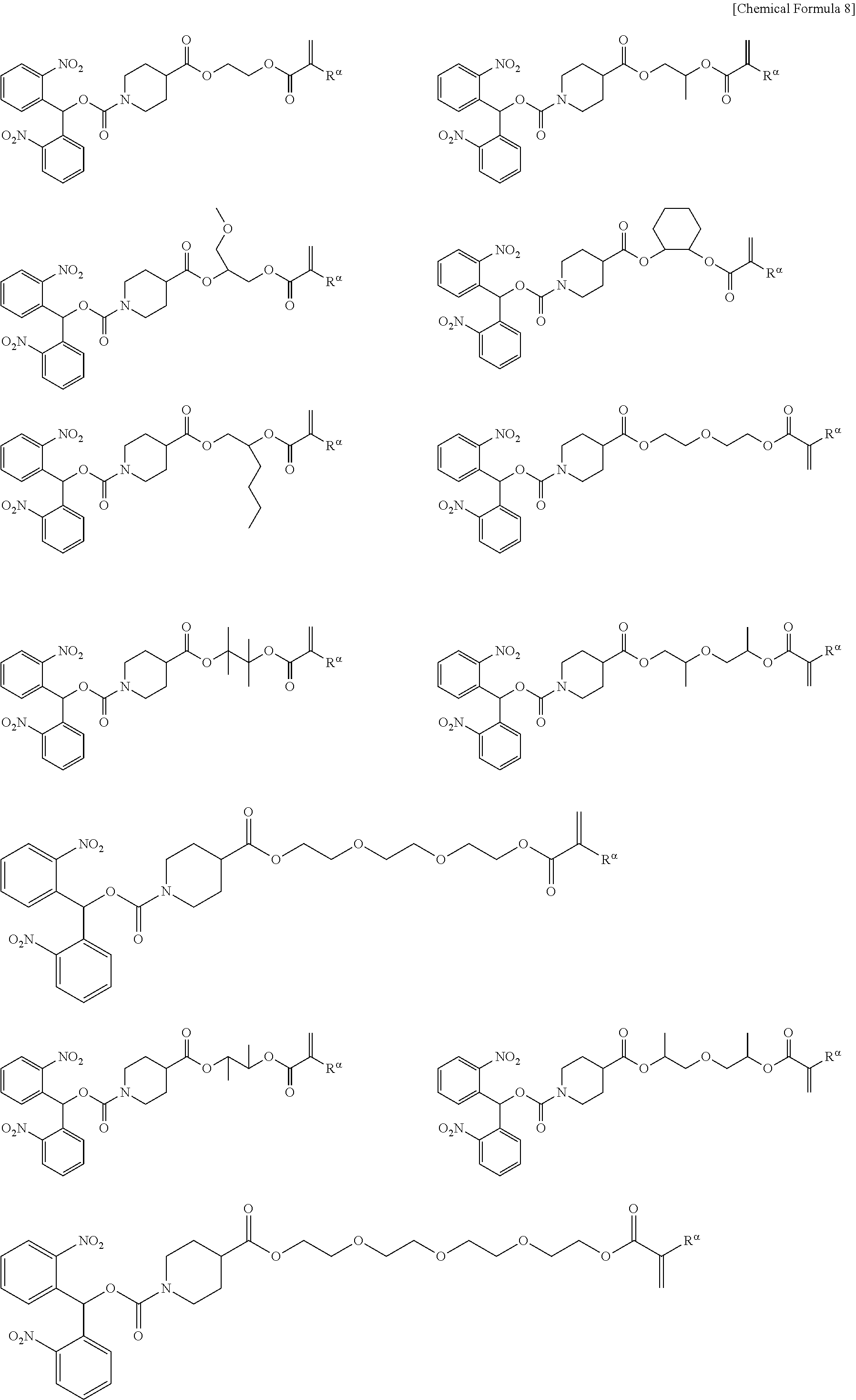

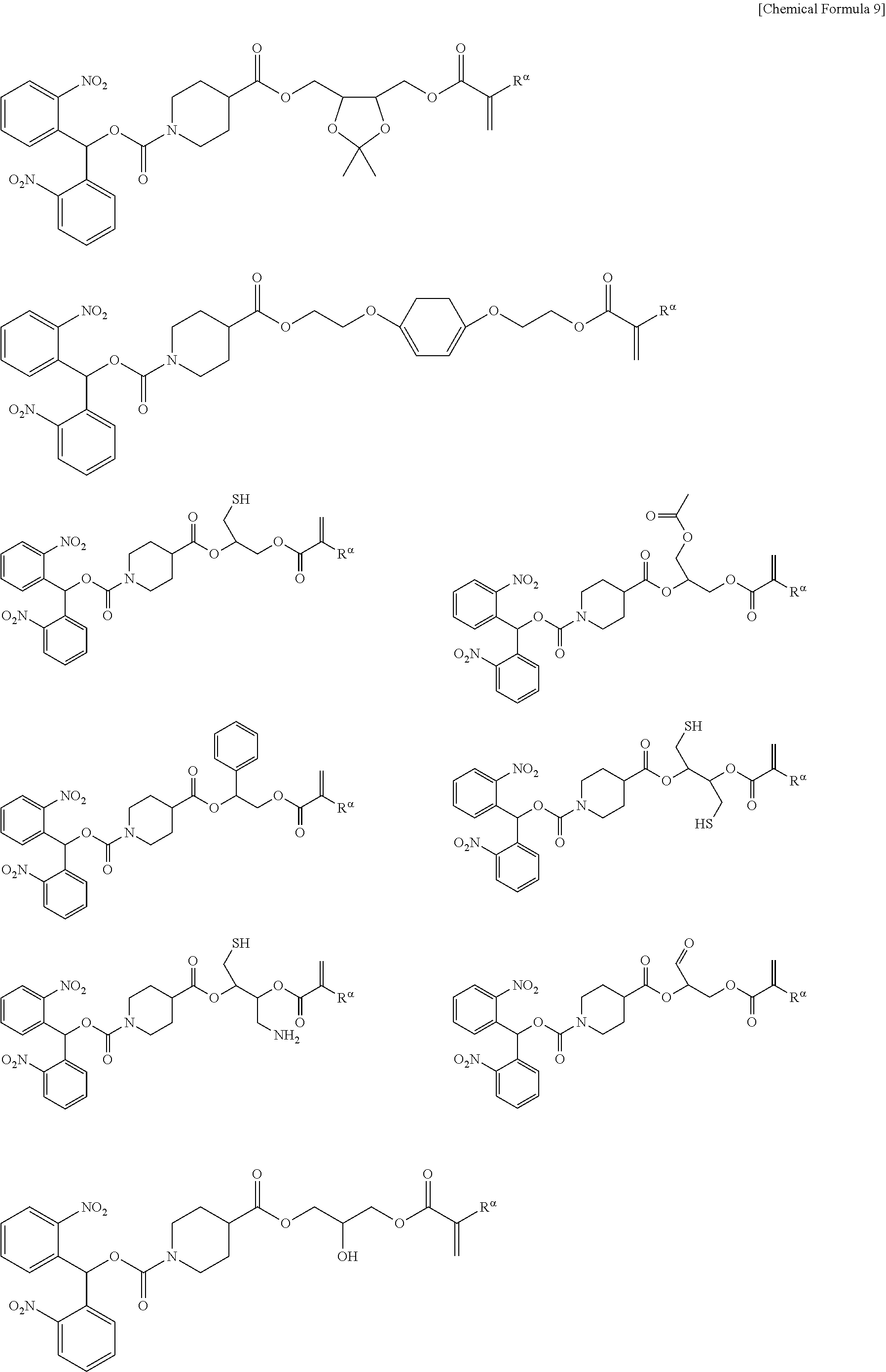

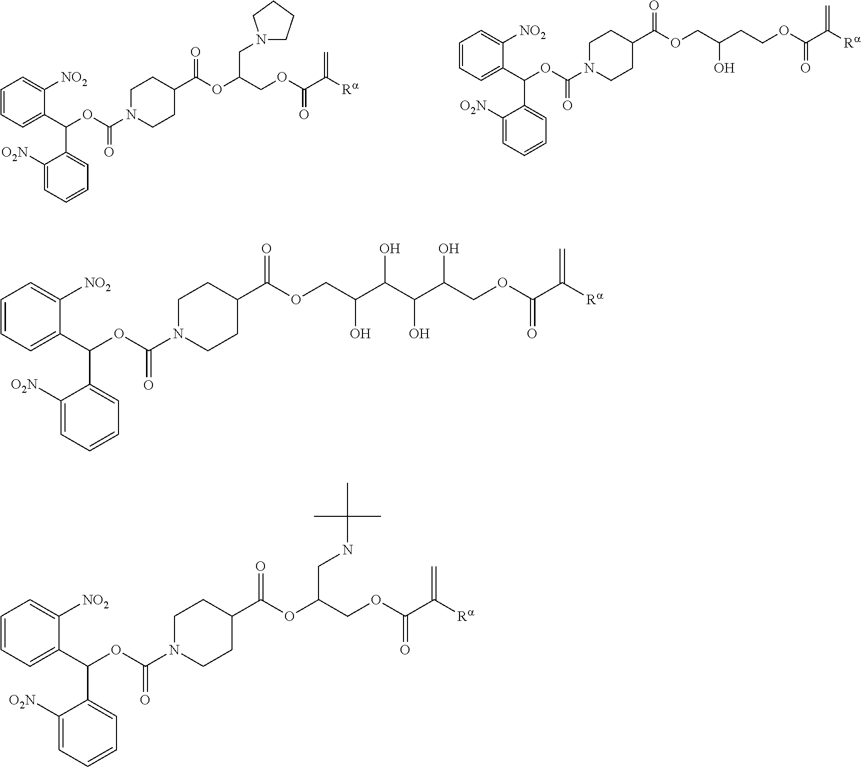

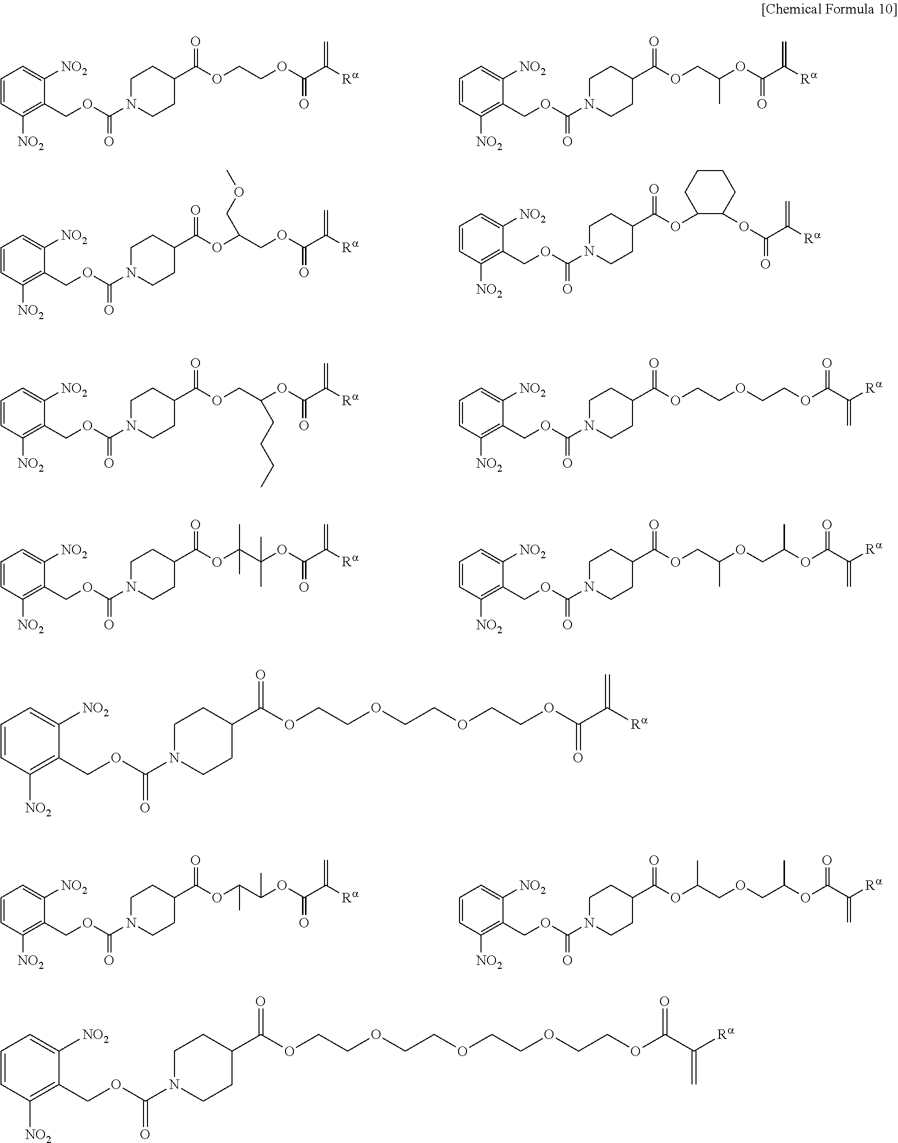

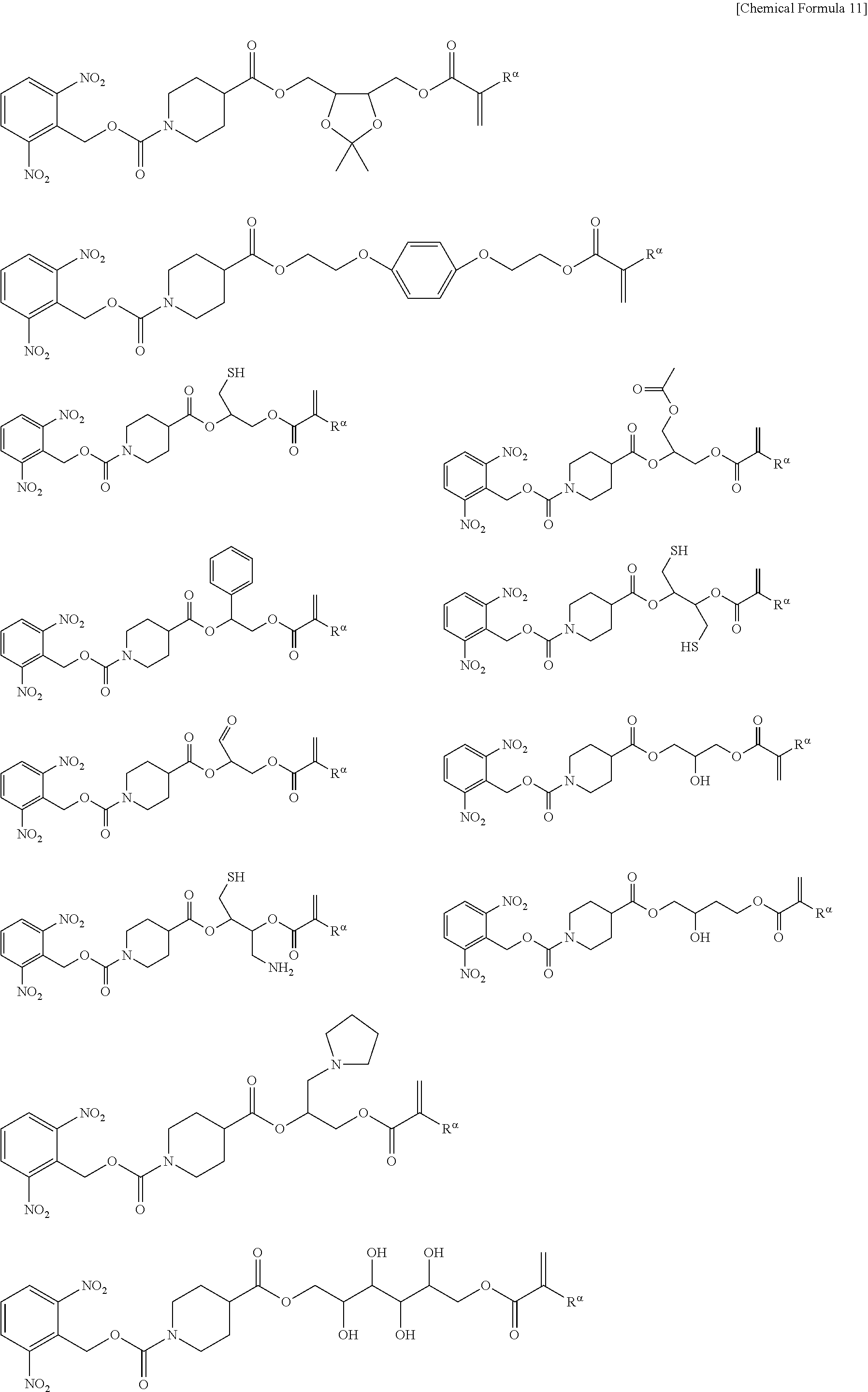

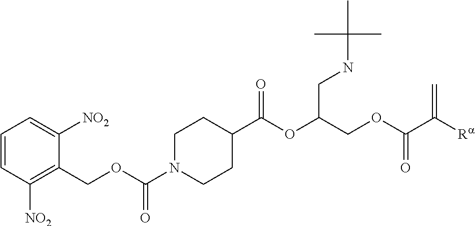

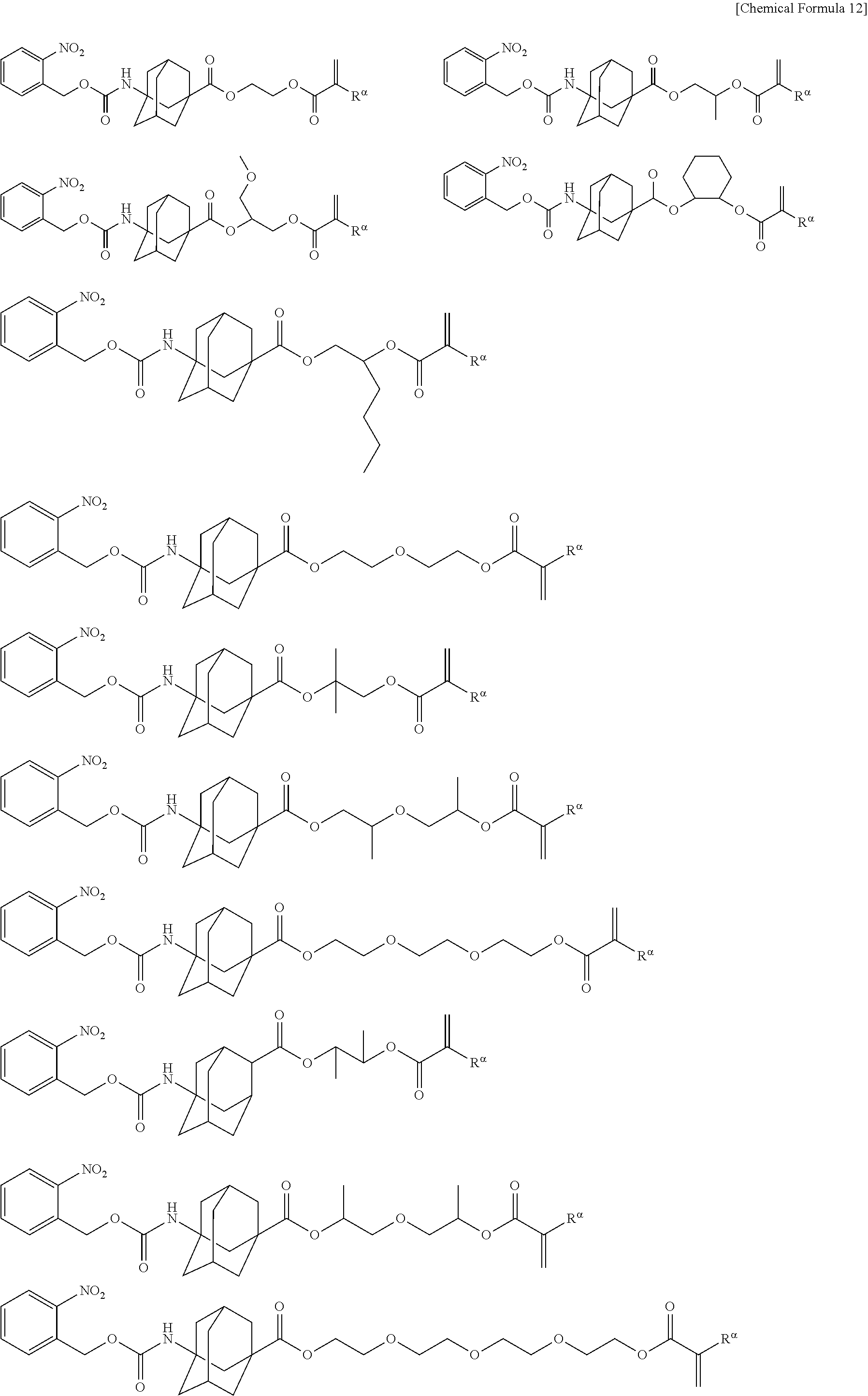

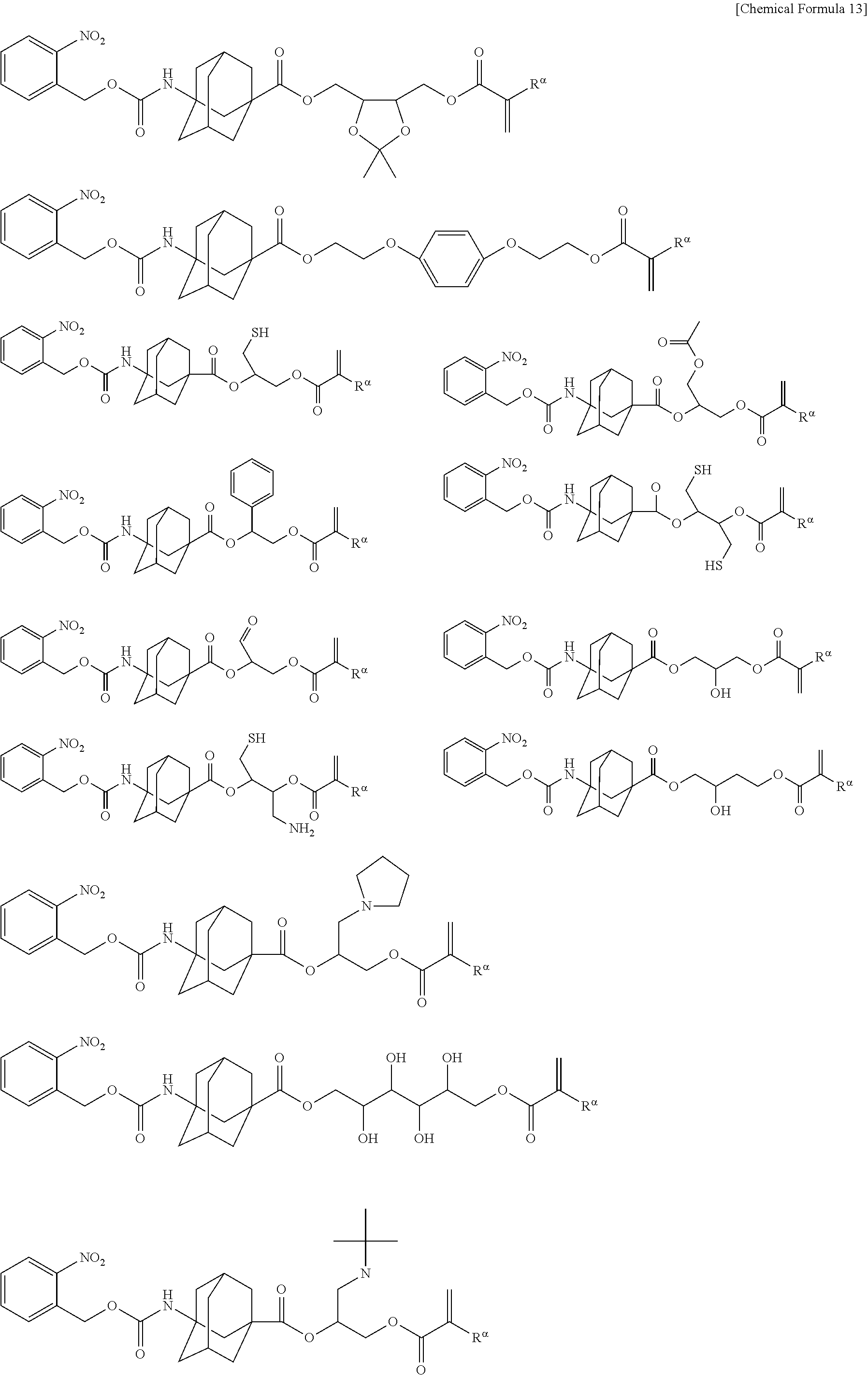

As the structural unit (a0) contained in the component (A 1), 1 type of structural unit may be used, or 2 or more types may be used.

In the component (A1), the amount of the structural unit (a0) based on the combined total of all structural units constituting the component (A1) is preferably 1 to 50 mol %, more preferably 1 to 30 mol %, and still more preferably 1 to 20 mol %.

When the amount of the structural unit (a0) is at least as large as the lower limit of the above-mentioned range, the film retentiveness of the resist film at exposed portions becomes excellent, and the dimension uniformity of the formed resist pattern is further improved. On the other hand, when the amount of the structural unit (a0) is no more than the upper limit of the above-mentioned range, a good balance can be reliably achieved with the other structural units. Also, the transparency of the formed resist film becomes excellent.

When the component (A) contains two or more polymeric compounds, in the component (A), the amount of the structural unit (a0) based on the combined total of all structural units constituting the component (A) is preferably 0.5 to 50 mol %, more preferably 0.5 to 30 mol %, and still more preferably 0.5 to 20 mol %. When the amount of the structural unit (a0) is within the above-mentioned range, the film retentiveness of the resist film at exposed portions becomes excellent, the dimension uniformity of the formed resist pattern are further improved, and the shape of the formed resist pattern becomes excellent.

(Structural Unit (a1))

The structural unit (a1) is a structural unit containing an acid decomposable group that exhibits increased polarity by the action of acid.

The term “acid decomposable group” refers to a group in which at least a part of the bond within the structure thereof is cleaved by the action of an acid.

Examples of acid decomposable groups which exhibit increased polarity by the action of an acid include groups which are decomposed by the action of an acid to form a polar group.

Examples of the polar group include a carboxy group, a hydroxy group, an amino group and a sulfo group (—SO₃H). Among these, a polar group containing —OH in the structure thereof (hereafter, frequently referred to as “OH-containing polar group”) is preferable, a carboxy group or a hydroxy group is more preferable, and a carboxy group is particularly desirable.

More specifically, as an example of an acid decomposable group, a group in which the aforementioned polar group has been protected with an acid dissociable group (such as a group in which the hydrogen atom of the OH-containing polar group has been protected with an acid dissociable group) can be given.

An “acid dissociable group” is (i) a group in which the bond between the acid dissociable group and the adjacent atom is cleaved by the action of acid; or

(ii) a group in which part of bonds is cleaved by the action of acid, and then the bond between the acid dissociable group and the adjacent atom is cleaved by decarboxylation reaction.

It is necessary that the acid dissociable group that constitutes the acid decomposable group is a group which exhibits a lower polarity than the polar group generated by the dissociation of the acid dissociable group. Thus, when the acid dissociable group is dissociated by the action of acid, a polar group exhibiting a higher polarity than that of the acid dissociable group is generated, thereby increasing the polarity. As a result, the polarity of the entire component (A1) is increased. By the increase in the polarity, the solubility in an alkali developing solution relatively changes and, the solubility in an alkali developing solution is relatively increased.

The acid dissociable group is not particularly limited, and any of the groups that have been conventionally proposed as acid dissociable groups for the base resins of chemically amplified resists can be used.

As the acid dissociable group for protecting a carboxy group or a hydroxy group as a polar group, for example, an acid dissociable group represented by general formula (a1-r-1) shown below (hereafter, frequently referred to as “acetal-type acid dissociable group”) can be mentioned.

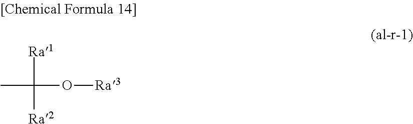

In the formula, Ra′¹ and Ra′² represent a hydrogen atom or an alkyl group; Ra′³ represents a hydrocarbon group, and Ra′³ may be bonded to Ra′¹ or Ra′² to form a ring.

In the formula (a1-r-1), as the alkyl group for Ra′¹ and Ra′², the same alkyl groups as those described above for the substituent which may be bonded to the carbon atom on the α-position of the aforementioned α-substituted alkylester can be mentioned, and an alkyl group of 1 to 5 carbon atoms is preferable. Specific examples of the alkyl group include linear or branched alkyl groups such as a methyl group, an ethyl group, a propyl group, an isopropyl group, an n-butyl group, an isobutyl group, a tert-butyl group, a pentyl group, an isopentyl group and a neopentyl group. Of these, a methyl group or an ethyl group is preferable, and a methyl group is particularly preferable.

Examples of the hydrocarbon group for Ra′³ include a linear, branched or cyclic alkyl group. The linear alkyl group preferably has 1 to 5 carbon atoms, more preferably 1 to 4, and still more preferably 1 or 2. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 10 carbon atoms, and more preferably 3 to 5. Specific examples of such branched alkyl groups include an isopropyl group, an isobutyl group, a tert-butyl group, an isopentyl group and a neopentyl group, and an isopropyl group is most desirable.

The cyclic alkyl group preferably has 3 to 20 carbon atoms, and more preferably 4 to 12. Examples of such groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane. In the cyclic alkyl groups, part of the carbon atoms constituting the ring may be replaced with an ethereal oxygen atom (—O—).

In the case where Ra′³ is bonded to Ra′¹ or Ra′² to form a ring, such a cyclic group is preferably a 4 to 7-membered ring, and more preferably a 4 to 6-membered ring. Specific examples of the cyclic group include tetrahydropyranyl group and tetrahydrofuranyl group.

As the acid dissociable group for protecting the carboxy group as a polar group, for example, an acid dissociable group represented by general formula (a1-r-2) shown below can be mentioned.

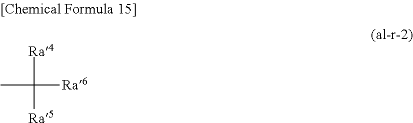

In the formula, Ra′⁴ to Ra′⁶ each represents a hydrocarbon group, and Ra′¹ and Ra′⁶ may be mutually bonded to form a ring.

In the formula (a1-r-2), the hydrocarbon group for Ra′⁴ to Ra′⁶ is preferably a linear, branched or cyclic alkyl group. As the alkyl group, the same groups as those described for a linear, branched or cyclic alkyl group for Ra′³ can be mentioned.

When the Ra′⁵ and Ra′⁶ are mutually bonded to form a ring, the cyclic group to be formed may be either a monocyclic group or a polycyclic group. Examples of the cyclic groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

In the acid dissociable group represented by formula (a1-r-2), a group constituted by an alkyl group is frequently referred to as a “tertiary alkyl ester-type acid dissociable group”.

As the acid dissociable group for protecting the hydroxy group as a polar group, for example, an acid dissociable group represented by general formula (a1-r-3) shown below (hereafter, frequently referred to as a “tertiary alkyl ester-type acid dissociable group”) can be mentioned.

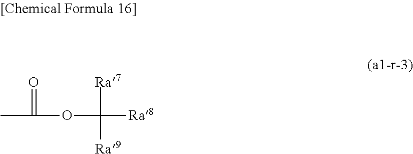

In the formula, Ra′⁷ to Ra′⁹ each represents an alkyl group, and Ra′⁸ and Ra′⁹ may be mutually bonded to form a ring.

In the formula (a1-r-3), the alkyl group for Ra′⁷ to Ra′⁹ may be any of linear, branched or cyclic. As the alkyl group, the same groups as those described for a linear, branched or cyclic alkyl group for Ra′³ can be mentioned.

Ra′¹ to Ra′⁹ preferably have 3 to 7 carbon atoms, more preferably 3 to 5 carbon atoms, and most preferably 3 or 4 carbon atoms.

The ring formed by Ra′⁸ and Ra′⁹ bonded to each other is the same ring as those described above for the ring formed by Ra′¹ and Ra′⁶ bonded to each other.

Examples of the structural unit (a1) include a structural unit derived from an acrylate ester which may have the hydrogen atom bonded to the carbon atom on the α-position substituted with a substituent and contains an acid decomposable group which exhibits increased polarity by the action of acid; a structural unit derived from hydroxystyrene or a hydroxystyrene derivative in which at least a part of the hydrogen atom of the hydroxy group is protected with a substituent containing an acid decomposable group; and a structural unit derived from vinylbenzoic acid or a vinylbenzoic acid derivative in which at least a part of the hydrogen atom within —C(═O)—OH is protected with a substituent containing an acid decomposable group.

As the structural unit (a1), a structural unit derived from an acrylate ester which may have the hydrogen atom bonded to the carbon atom on the α-position substituted with a substituent is preferable.

Specific examples of preferable structural units for the structural unit (a1) include structural units represented by general formula (a1-1) shown below.

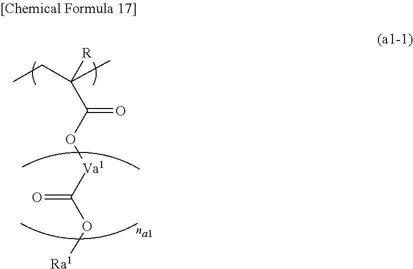

In the formula, R represents a hydrogen atom, an alkyl group of 1 to 5 carbon atoms or a halogenated alkyl group of 1 to 5 carbon atoms; Va¹ represents a divalent hydrocarbon group; nₐ₁ represents an integer of 0 to 2; and Ra¹ represents an acid dissociable group represented by the aforementioned formula (a1-r-1) or (a1-r-2).

In general formula (a1-1), R represents a hydrogen atom, an alkyl group of 1 to 5 carbon atoms or a halogenated alkyl group of 1 to 5 carbon atoms.

The alkyl group and the halogenated alkyl group for R are respectively the same as defined for the alkyl group and the halogenated alkyl group for the substituent on the α-position of the aforementioned substituted acrylate ester. R is preferably a hydrogen atom, an alkyl group of 1 to 5 carbon atoms or a fluorinated alkyl group of 1 to 5 carbon atoms, and most preferably a hydrogen atom or a methyl group.

Va¹ represents a divalent hydrocarbon group, and examples thereof include the same groups as those described above for the hydrocarbon group of 1 to 30 carbon atoms which may have a substituent for Y¹ in the aforementioned formula (a0-m).

nₐ₁ represents an integer of 0 to 2, and preferably 0 or 1.

Ra¹ represents an acid dissociable group represented by the aforementioned formula (a1-r-1) or (a1-r-2).

Specific examples of the formula (a1-1) include the formulas described below. In the formulas shown below, R^{α} represents a hydrogen atom, a methyl group or a trifluoromethyl group.

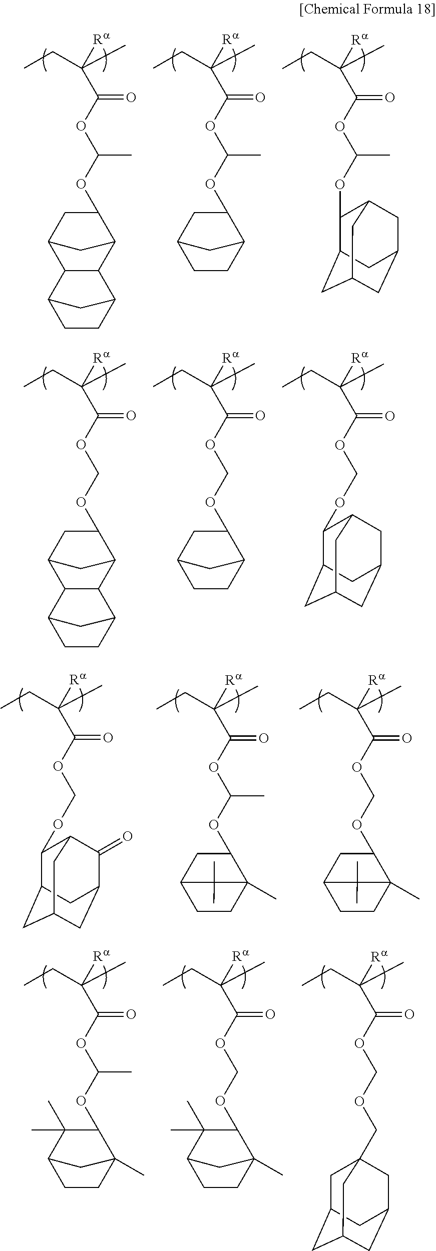

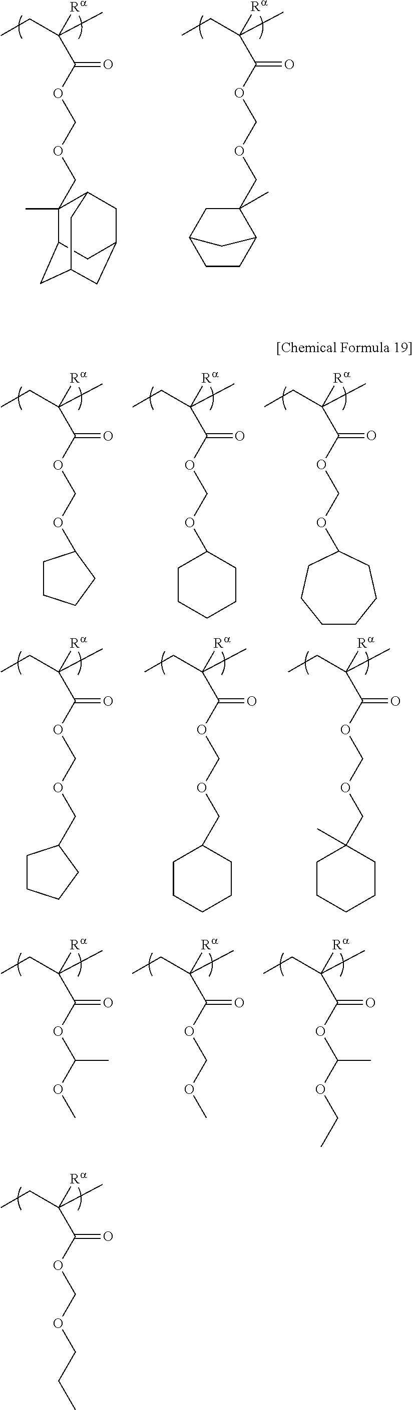

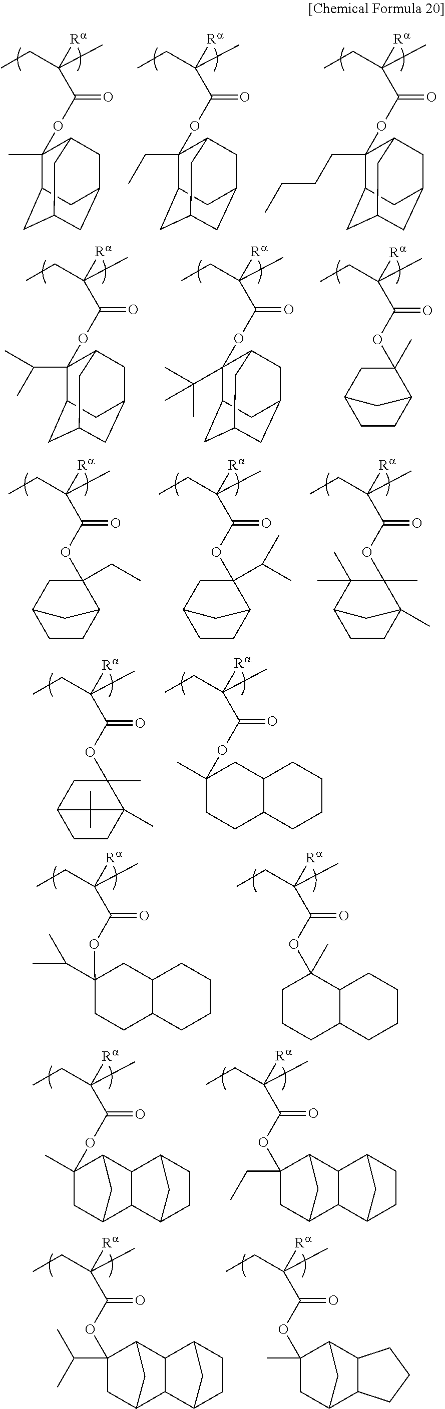

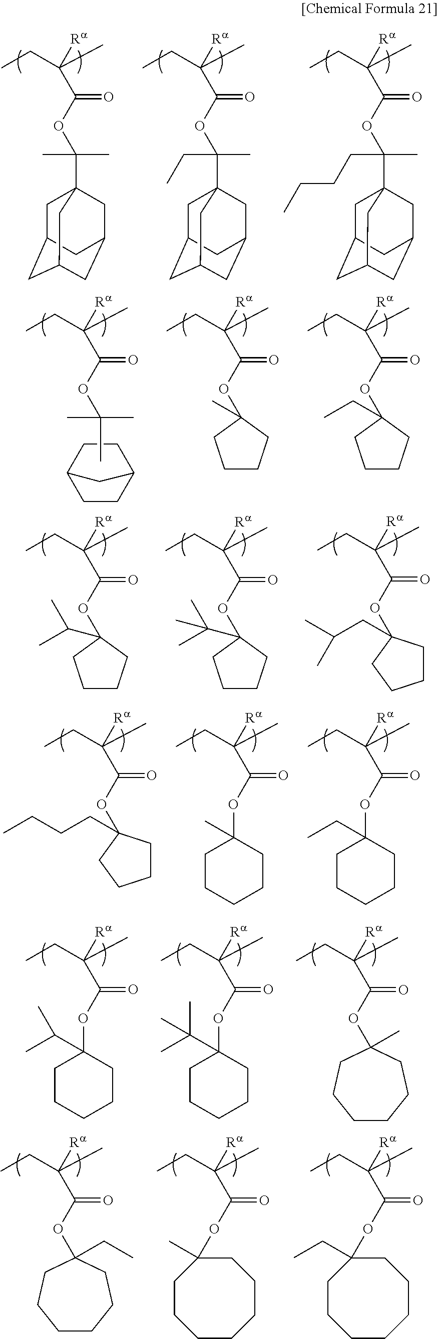

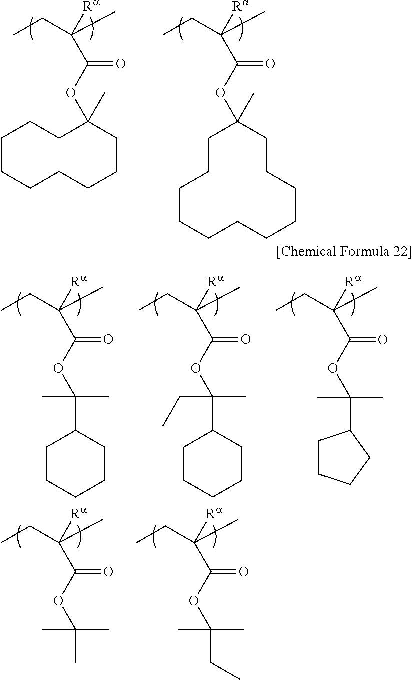

As the structural unit (a1) contained in the component (A1), 1 type of structural unit may be used, or 2 or more types may be used.

In the component (A1), the amount of the structural unit (a1) based on the combined total of all structural units constituting the component (A1) is preferably 20 to 80 mol %, more preferably 20 to 75 mol %, and still more preferably 25 to 70 mol %.

When the amount of the structural unit (a1) is at least as large as the lower limit of the above-mentioned range, a pattern can be easily formed using a resist composition prepared from the component (A1), and various lithography properties such as sensitivity, resolution, dimension uniformity and the like are improved. On the other hand, when the amount of the structural unit (a1) is no more than the upper limit of the above-mentioned range, a good balance can be achieved with the other structural units.

(Other Structural Units)

Structural Unit (a2):

The component (A1) preferably includes a structural unit containing a lactone-containing cyclic group (hereafter, referred to as “structural unit (a2)”), as well as the structural units (a0) and (a1).

When the component (A1) is used for forming a resist film, the lactone-containing cyclic group within the structural unit (a2) is effective in improving the adhesion between the resist film and the substrate.

The aforementioned structural unit (a0) or (a1) which contains a lactone-containing cyclic group falls under the definition of the structural unit (a2); however, such a structural unit is regarded as a structural unit (a0) or (a1), and does not fall under the definition of the structural unit (a2).

The term “lactone-containing cyclic group” refers to a cyclic group including a ring containing a —O—C(═O)— structure (lactone ring). The term “lactone ring” refers to a single ring containing a —O—C(O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

The lactone-containing cyclic group for the structural unit (a2) is not particularly limited, and an arbitrary structural unit may be used. Specific examples include lactone-containing cyclic groups represented by general formulas (a1-r-1) to (a2-r-7) shown below.

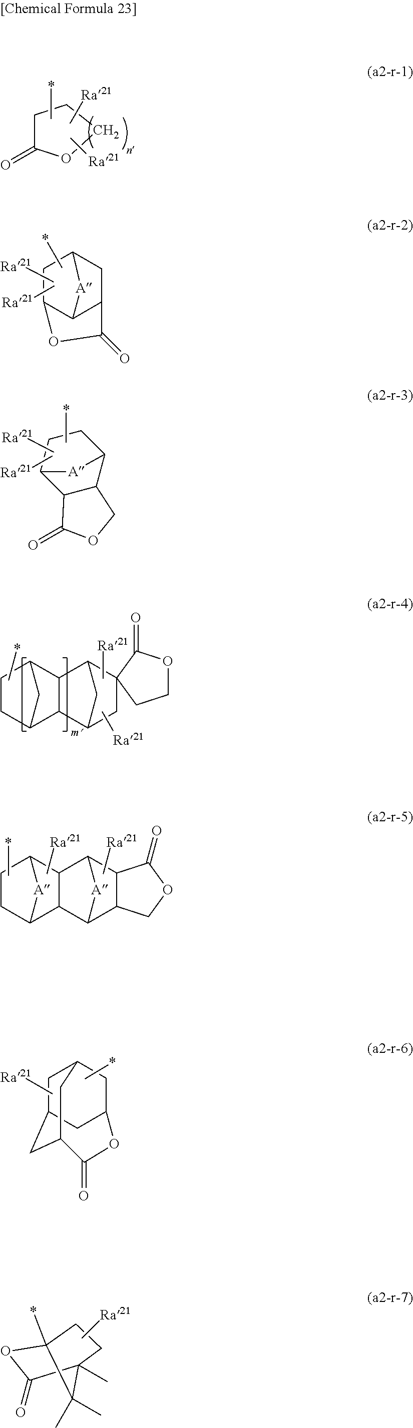

In the formulas, each Ra′²¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfonyl group or an alkylene group of 1 to 5 carbon atoms which may contain an oxygen atom or a sulfur atom; n′ represents an integer of 0 to 2; and m′ represents 0 or 1. In the formula, ★ represents a valence bond.

In the formulas (a2-r-1) to (a2-r-7), the alkyl group for Ra′²¹ is preferably an alkyl group of 1 to 6 carbon atoms. Further, the alkyl group is preferably a linear alkyl group or a branched alkyl group. Specific examples include a methyl group, an ethyl group, a propyl group, an isopropyl group, an n-butyl group, an isobutyl group, a tert-butyl group, a pentyl group, an isopentyl group, a neopentyl group and a hexyl group. Among these, a methyl group or an ethyl group is preferable, and a methyl group is particularly desirable.

As the alkoxy group for Ra′²¹, an alkoxy group of 1 to 6 carbon atoms is preferable. Further, the alkoxy group is preferably a linear or branched alkoxy group. Specific examples of the alkoxy groups include the aforementioned alkyl groups for the substituent having an oxygen atom (—O—) bonded thereto.

Examples of the halogen atom for Ra′²¹ include a fluorine atom, a chlorine atom, a bromine atom and an iodine atom, and a fluorine atom is preferable.

Examples of the halogenated alkyl group for Ra′²¹ include groups in which part or all of the hydrogen atoms within the aforementioned alkyl groups for Ra′²¹ has been substituted with the aforementioned halogen atoms. As the halogenated alkyl group, a fluorinated alkyl group is preferable, and a perfluoroalkyl group is particularly desirable.

In the —COOR″ group and the —OC(═O)R″ group for Ra′²¹, R″ preferably represents a hydrogen atom or a linear, branched or cyclic alkyl group of 1 to 15 carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The hydroxyalkyl group for Ra′²¹ preferably has 1 to 6 carbon atoms, and specific examples thereof include a group in which at least one hydrogen atom of the aforementioned alkyl groups for the substituent has been substituted with a hydroxy group.

In the formulas, A″ represents an oxygen atom (—O—), a sulfur atom or an alkylene group of 1 to 5 carbon atoms which may contain an oxygen atom (—O—) or a sulfur atom. As A′, an alkylene group of 1 to 5 carbon atoms or an oxygen atom (—O—) is preferable, more preferably an alkylene group of 1 to 5 carbon atoms, and most preferably a methylene group.

In formula (a2-r-1), n′ represents an integer of 0 to 2, preferably 1 or 2.

Specific examples of the lactone-containing cyclic groups represented by general formulas (a1-r-1) to (a2-r-7) are shown below. In the formula, the wavy line represents a valence bond.

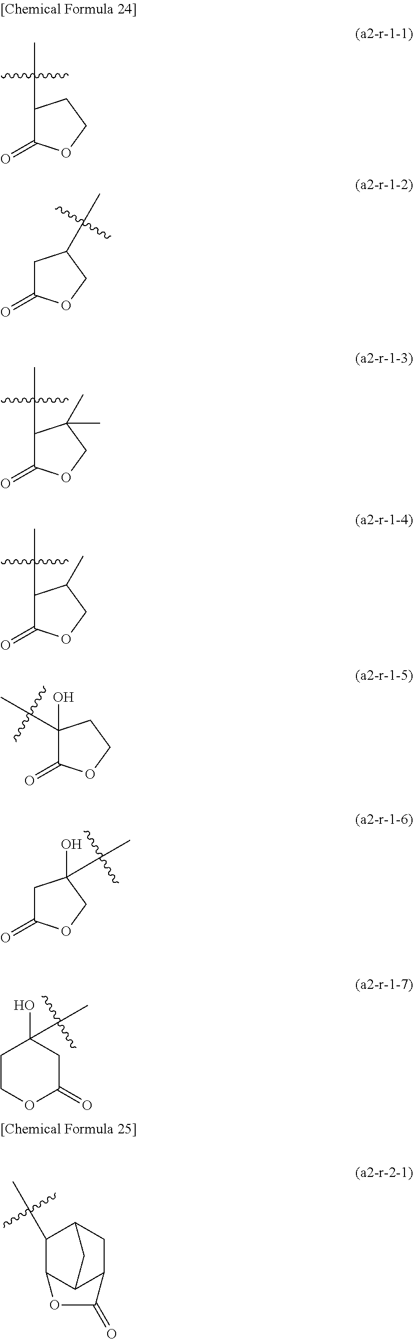

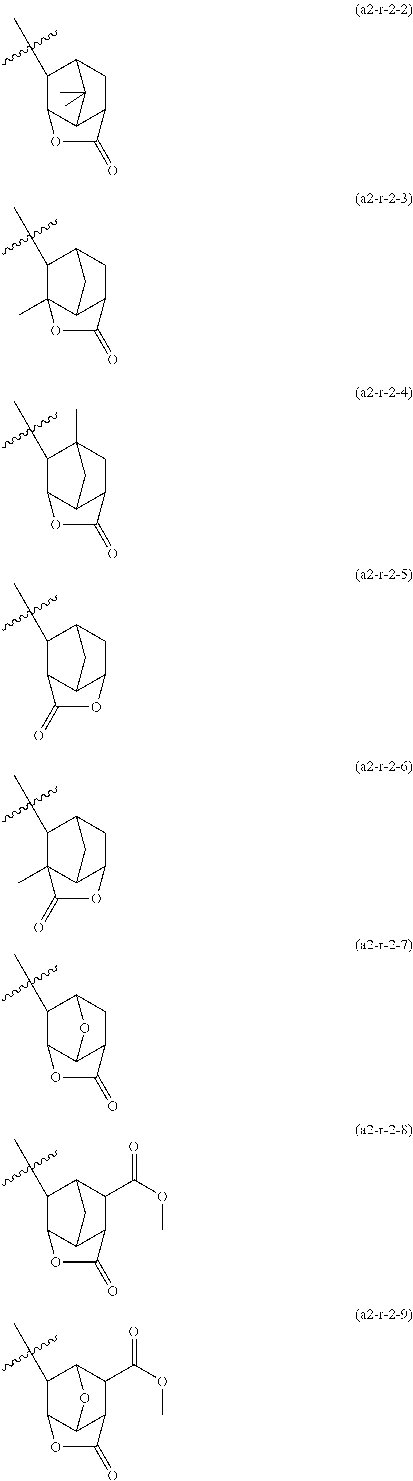

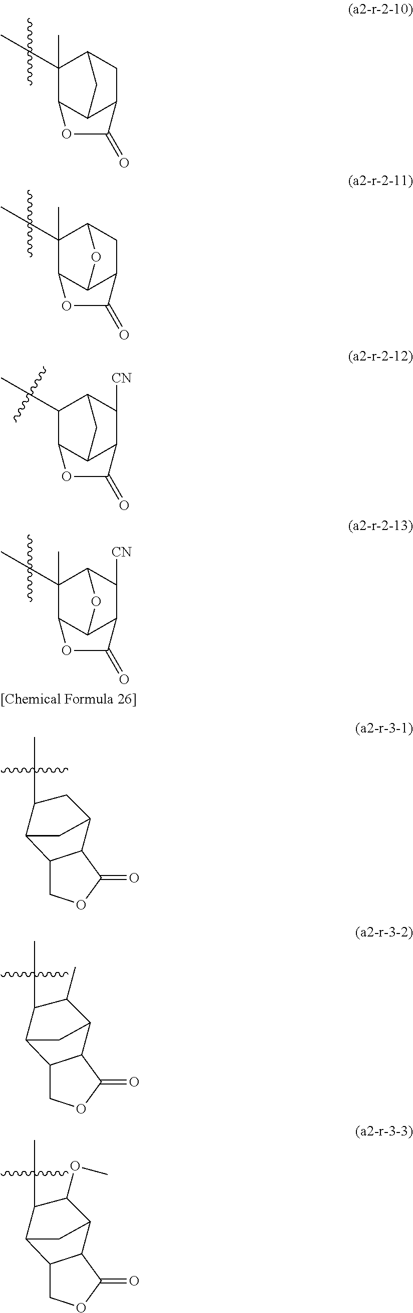

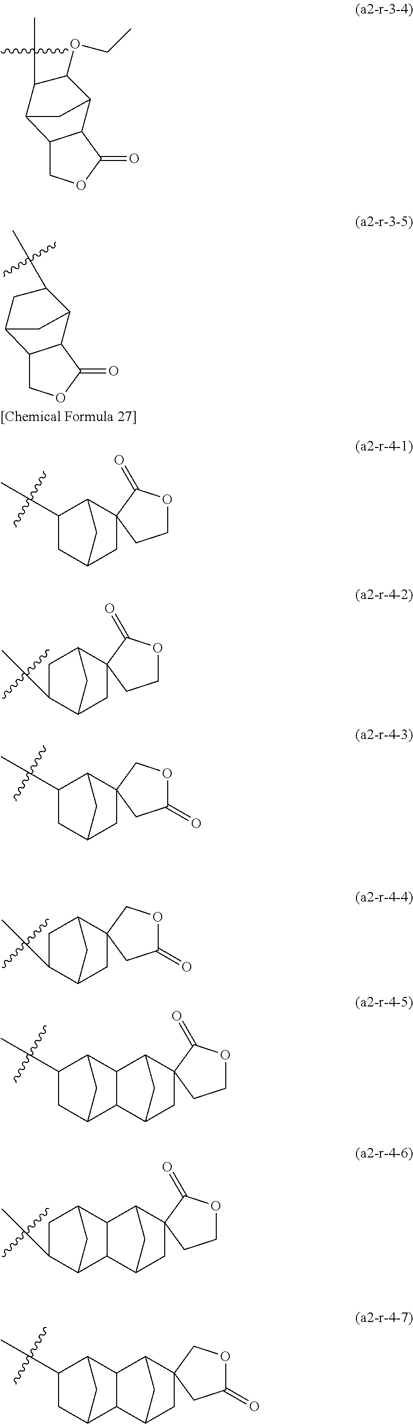

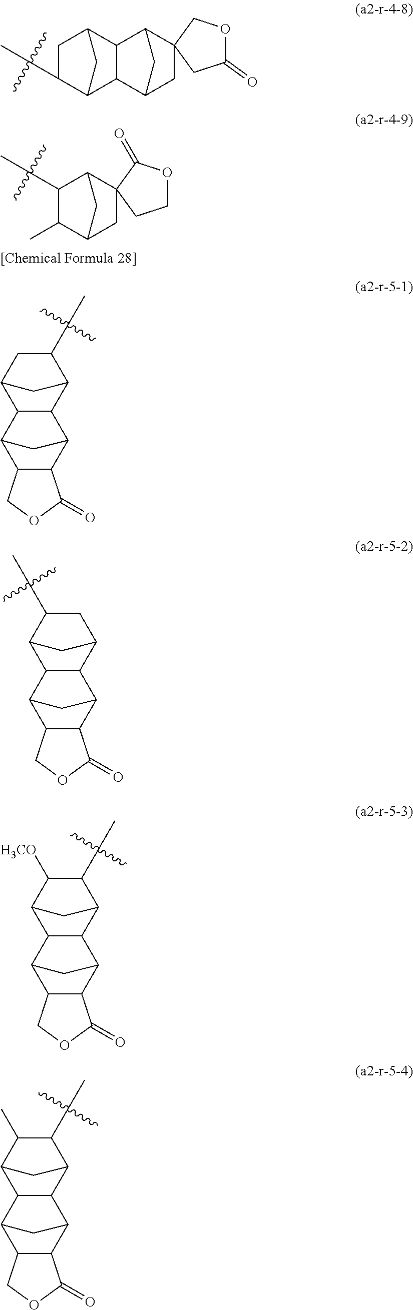

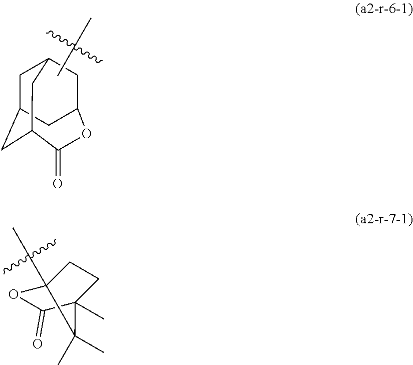

As the structural unit (a2), the structure of the other part is not particularly limited, as long as it contains a lactone-containing cyclic group, and as a preferable structural units, structural units represented by general formulas (a2-1) to (a2-4) shown below can be mentioned.

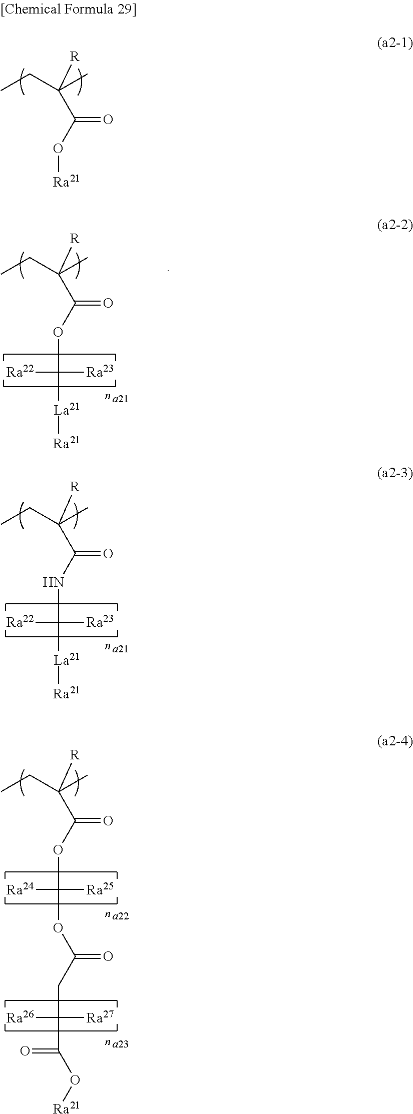

In the formulas, R is the same as defined above, Ra²¹ represents a lactone-containing cyclic group. La²¹ represents —O—C(═O)— or —C(═O)—O—. Ra²² to Ra²⁷ represent a hydrogen atom or an alkyl group; Ra²² and Ra²³, Ra²⁴ and Ra²⁵, and Ra²⁶ and Ra²⁷ may be mutually bonded to form a ring. na₂₁ to na₂₃ represents an integer of 1 to 5.

In the formulas (a2-1) to (a2-4), the alkyl group for Ra²² to Ra²⁷ preferably has 1 to 5 carbon atoms, and may be linear, branched or cyclic. In particular, a linear or branched alkyl group of 1 to 5 carbon atoms is preferable.

na₂₁ to na₂₃ represent an integer of 1 to 5, and preferably 1 or 2.

Specific examples of structural units represented by general formulas (a2-1) to (a2-4) are shown below. In the formulas shown below, R^{α} represents a hydrogen atom, a methyl group or a trifluoromethyl group.

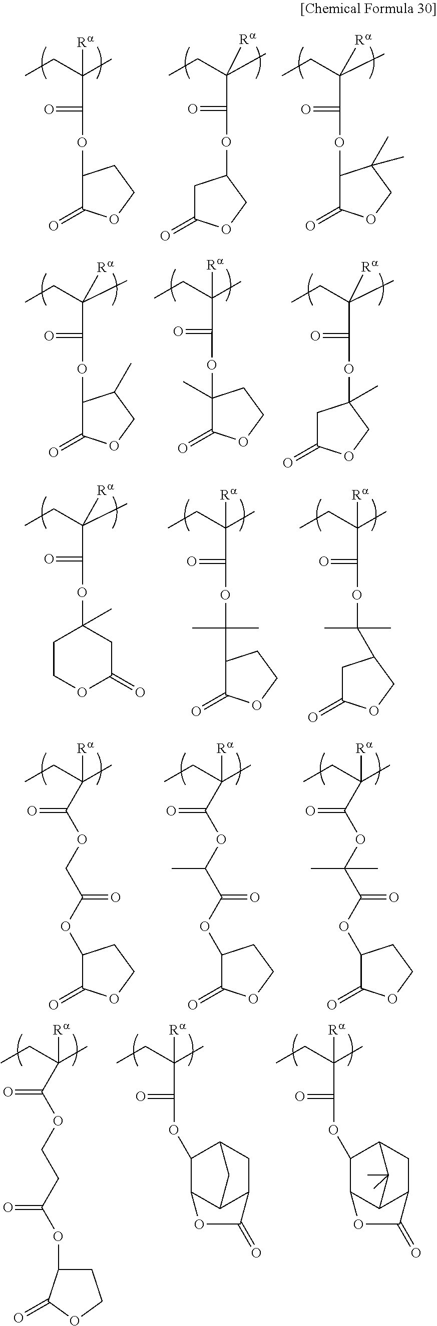

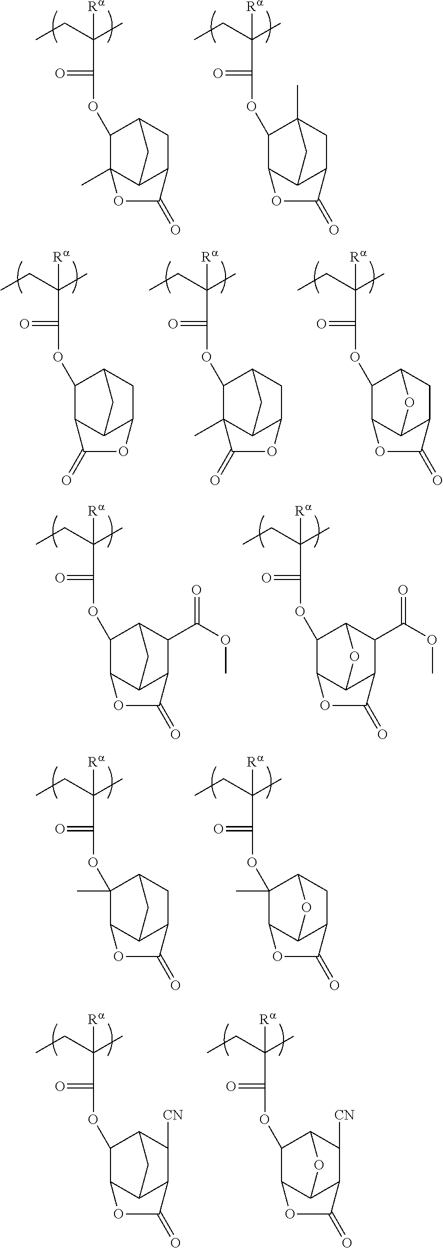

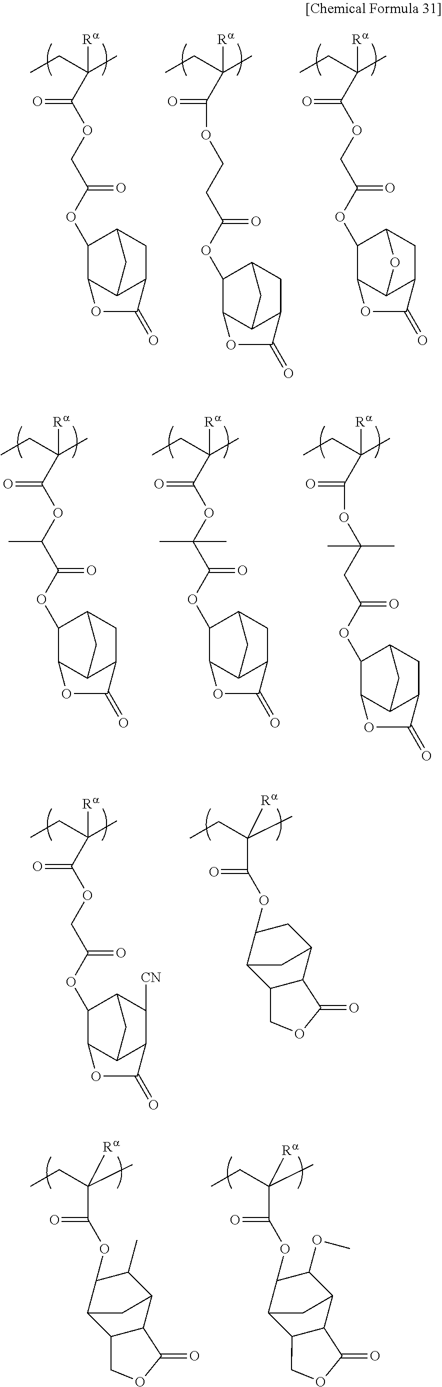

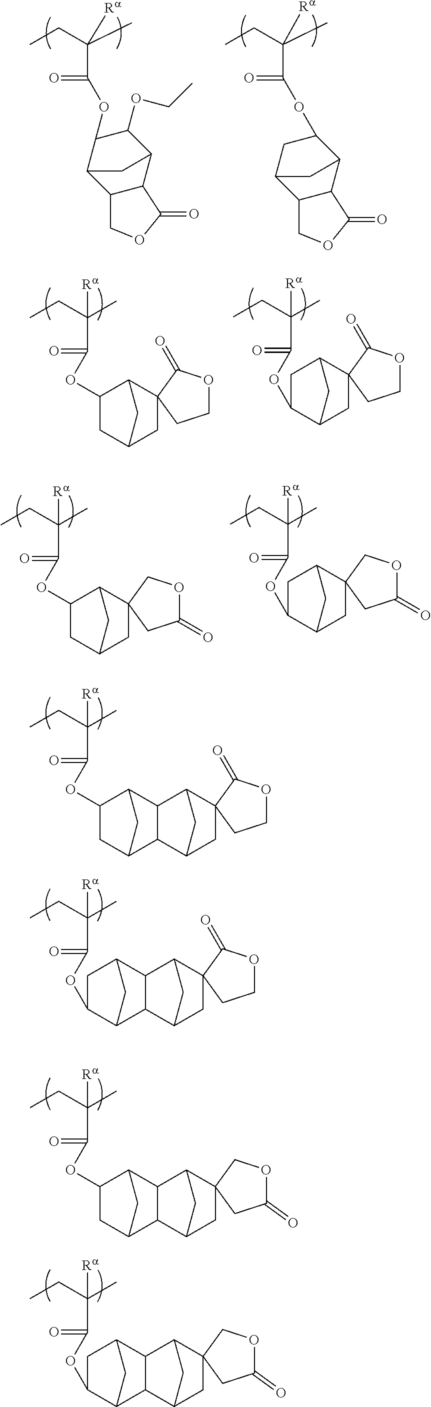

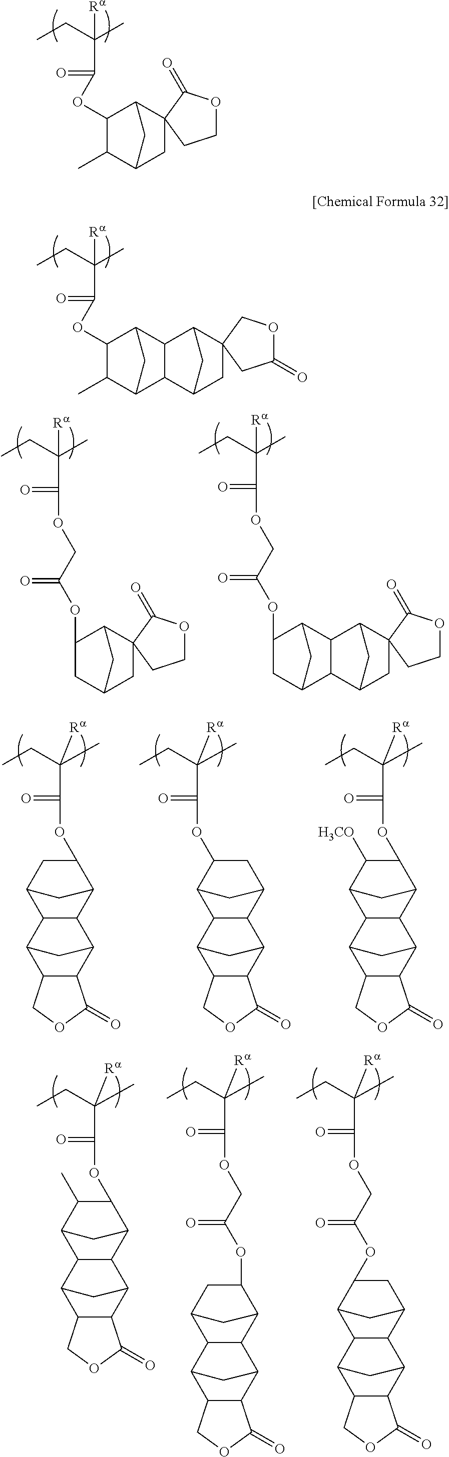

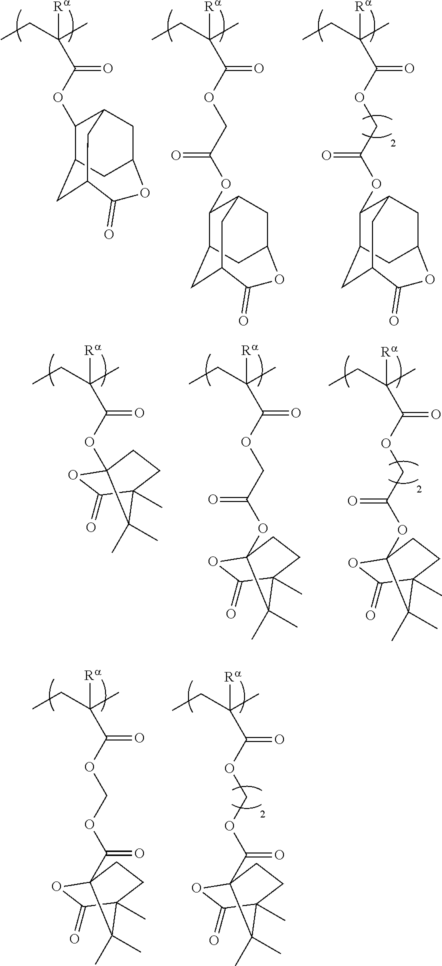

As the structural unit (a2) contained in the component (A1), 1 type of structural unit may be used, or 2 or more types may be used.

Among these, as the structural unit (a2), a structural unit represented by the aforementioned general formula (a2-1) is preferable.

When the component (A1) contains the structural unit (a2), the amount of the structural unit (a2) based on the combined total of all structural units constituting the component (A1) is preferably 1 to 80 mol %, more preferably 10 to 70 mol %, still more preferably 10 to 65 mol %, and particularly preferably 10 to 60 mol %.

When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units, and various lithography properties such as dimension uniformity, and pattern shape can be improved.

The component (A1) may also have a structural unit other than the above-mentioned structural units (a0), (a1) and (a2), as long as the effects of the present invention are not impaired.

As such a structural unit, any other structural unit which cannot be classified as the aforementioned structural units can be used without any particular limitation, and any of the multitude of conventional structural units used within resist resins for ArF excimer lasers or KrF excimer lasers (and particularly for ArF excimer lasers) can be used.

Structural Unit (a3):

The component (A1) may include a structural unit containing a polar group-containing aliphatic hydrocarbon group (hereafter, referred to as “structural unit (a3)”), provided that, the structural units that fall under the definition of structural units (a0), (a1) and (a2) are excluded from the definition of the structural unit (a3).

When the component (A1) includes the structural unit (a3), the hydrophilicity of the component (A) is enhanced, thereby contributing to improvement in resolution.

Examples of the polar group include a hydroxyl group, a cyano group, a carboxyl group, or a hydroxyalkyl group in which part of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and cyclic aliphatic hydrocarbon groups (cyclic groups). These cyclic groups can be selected appropriately from the multitude of groups that have been proposed for the resins of resist compositions designed for use with ArF excimer lasers. The cyclic group is preferably a polycyclic group, more preferably a polycyclic group of 7 to 30 carbon atoms.

Of the various possibilities, structural units derived from an acrylate ester that include an aliphatic polycyclic group that contains a hydroxyl group, a cyano group, a carboxyl group or a hydroxyalkyl group in which part of the hydrogen atoms of the alkyl group have been substituted with fluorine atoms are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

As the structural unit (a3), there is no particular limitation as long as it is a structural unit containing a polar group-containing aliphatic hydrocarbon group, and an arbitrary structural unit may be used.

The structural unit (a3) is preferably a structural unit derived from an acrylate ester which may have the hydrogen atom bonded to the carbon atom on the α-position substituted with a substituent and contains a polar group-containing aliphatic hydrocarbon group.

When the hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid. On the other hand, when the hydrocarbon group is a polycyclic group, structural units represented by formulas (a3-1), (a3-2) and (a3-3) shown below are preferable.

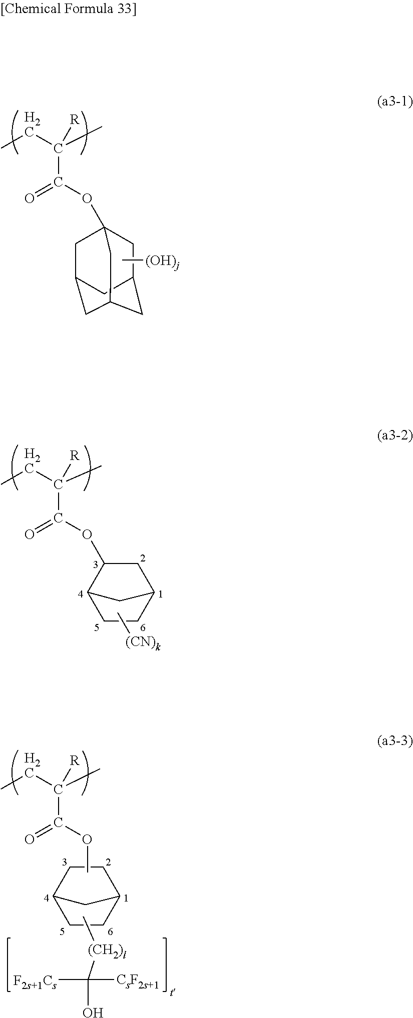

In the formulas, R is the same as defined above; j is an integer of 1 to 3; k is an integer of 1 to 3; t′ is an integer of 1 to 3; l is an integer of 1 to 5; and s is an integer of 1 to 3.

In formula (a3-1), j is preferably 1 or 2, and more preferably 1. When j is 2, it is preferable that the hydroxyl groups be bonded to the 3rd and 5th positions of the adamantyl group. When j is 1, it is preferable that the hydroxyl group be bonded to the 3rd position of the adamantyl group.

j is preferably 1, and it is particularly desirable that the hydroxyl group be bonded to the 3rd position of the adamantyl group.

In formula (a3-2), k is preferably 1. The cyano group is preferably bonded to the 5th or 6th position of the norbornyl group.

In formula (a3-3), t′ is preferably 1. l is preferably 1. s is preferably 1. Further, in formula (a3-3), it is preferable that a 2-norbonyl group or 3-norbonyl group be bonded to the terminal of the carboxy group of the acrylic acid. The fluorinated alkyl alcohol is preferably bonded to the 5th or 6th position of the norbornyl group.

As the structural unit (a3) contained in the component (A1), 1 type of structural unit may be used, or 2 or more types may be used.

When the component (A1) contains the structural unit (a3), the amount of the structural unit (a3) based on the combined total of all structural units constituting the component (A1) is preferably 5 to 50 mol %, more preferably 5 to 40 mol %, and still more preferably 5 to 25 mol %.

When the amount of the structural unit (a3) is at least as large as the lower limit of the above-mentioned range, the effect of using the structural unit (a3) can be satisfactorily achieved. On the other hand, when the amount of the structural unit (a3) is no more than the upper limit of the above-mentioned range, a good balance can be achieved with the other structural units.

Structural Unit (a4):

The component (A1) may include a structural unit containing an acid non-dissociable, aliphatic cyclic group (hereafter, referred to as “structural unit (a4)”).

In the structural unit (a4), examples of the aliphatic cyclic group include the same groups as those described above in relation to the aforementioned structural unit (a0), and any of the multitude of conventional polycyclic groups used within the resin component of resist compositions for ArF excimer lasers or KrF excimer lasers (and particularly for ArF excimer lasers) can be used.

In consideration of industrial availability and the like, at least one polycyclic group selected from amongst a tricyclodecyl group, an adamantyl group, a tetracyclododecyl group, an isobornyl group, and a norbornyl group is particularly desirable. These polycyclic groups may be substituted with a linear or branched alkyl group of 1 to 5 carbon atoms.

Specific examples of the structural unit (a4) include units with structures represented by general formulas (a4-1) to (a4-7) shown below.

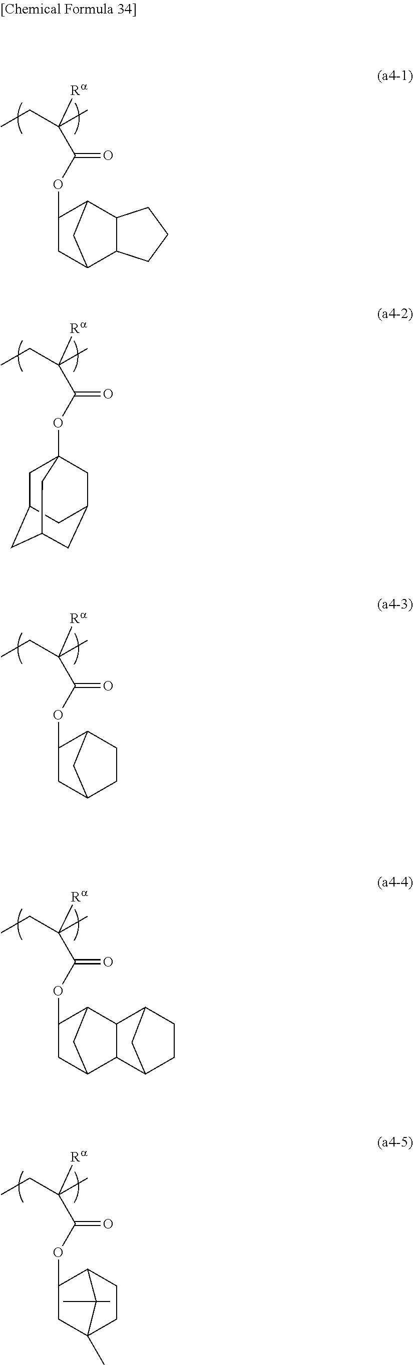

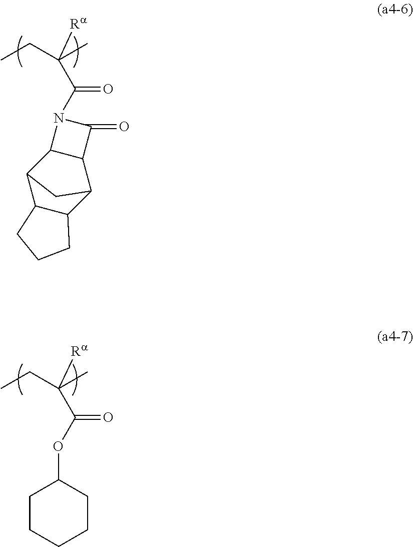

In the formulas, R^{α} is the same as defined above.

As the structural unit (a4) contained in the component (A1), 1 type of structural unit may be used, or 2 or more types may be used.

When the component (A1) contains the structural unit (a4), the amount of the structural unit (a4) based on the combined total of all structural units constituting the component (A1) is preferably 1 to 30 mol %, and more preferably 10 to 20 mol %.

When the amount of the structural unit (a4) is at least as large as the lower limit of the above-mentioned range, various lithography properties are improved. On the other hand, when the amount of the structural unit (a4) is no more than the upper limit of the above-mentioned range, a good balance can be achieved with the other structural units.

Structural Unit (a5):

The component (A1) may include a structural unit containing an —SO₂— containing cyclic group (hereafter, referred to as “structural unit (a5)”).

When the component (A1) is used for forming a resist film, the —SO₂— containing cyclic group within the structural unit (a5) is effective in improving the adhesion between the resist film and the substrate.

The aforementioned structural unit (a0) or (a1) which contains an —SO₂-containing cyclic group falls under the definition of the structural unit (a5); however, such a structural unit is regarded as a structural unit (a0) or (a1), and does not fall under the definition of the structural unit (a5).

Here, an “—SO₂— containing cyclic group” refers to a cyclic group having a ring containing —SO₂— within the ring structure thereof, i.e., a cyclic group in which the sulfur atom (S) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂-containing cyclic group may be either a monocyclic group or a polycyclic group.

As the —SO₂— containing cyclic group, a cyclic group containing —O—SO₂— within the ring skeleton thereof, i.e., a cyclic group containing a sultone ring in which —O—S— within the —O—SO₂— group forms part of the ring skeleton thereof is particularly desirable.

More specific examples of the —SO₂— containing cyclic group include groups represented by general formulas (a1-r-1) to (a5-r-4) shown below.

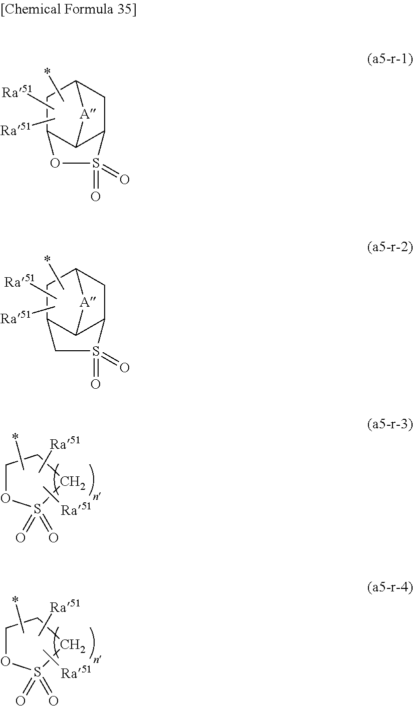

In the formulas, each Ra′⁵¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom or an alkyl group; A″ represents an oxygen atom, a sulfonyl group or an alkylene group of 1 to 5 carbon atoms which may contain an oxygen atom or a sulfur atom; and n′ represents an integer of 0 to 2.

In the aforementioned general formulas (a1-r-1) to (a5-r-4), Ra′⁵¹ is the same as defined for Ra′²¹ in the aforementioned formulas (a1-r-1) to (a2-r-7).

A″ is the same as defined for A″ in the aforementioned formulas (a1-r-2), (a2-r-3) and (a2-r-5).

n′ is the same as defined for n′ in the aforementioned formula (a1-r-1).

Specific examples of the cyclic groups represented by general formulas (a1-r-1) to (a5-r-4) are shown below. In the formulas shown below, “Ac” represents an acetyl group.

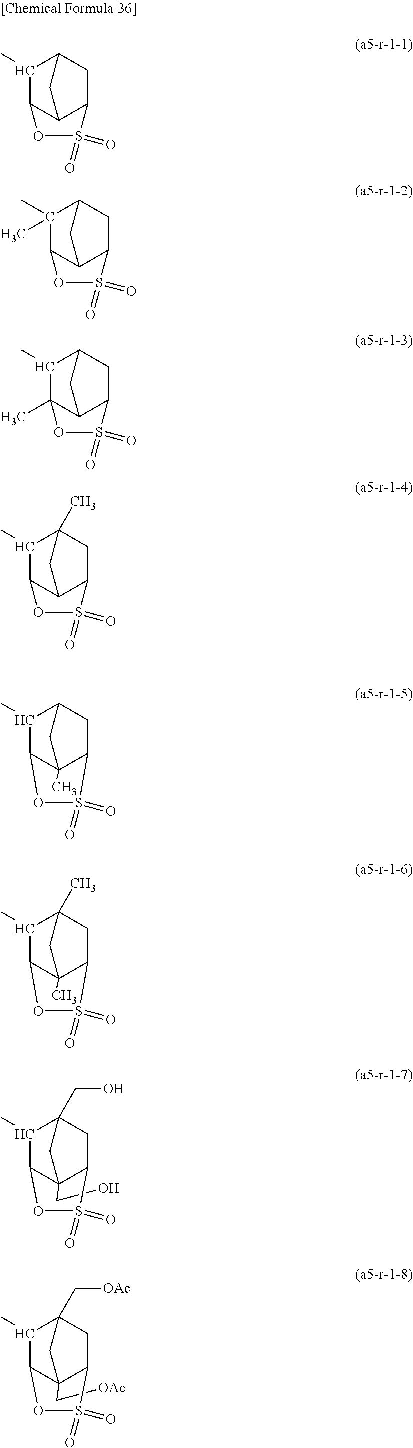

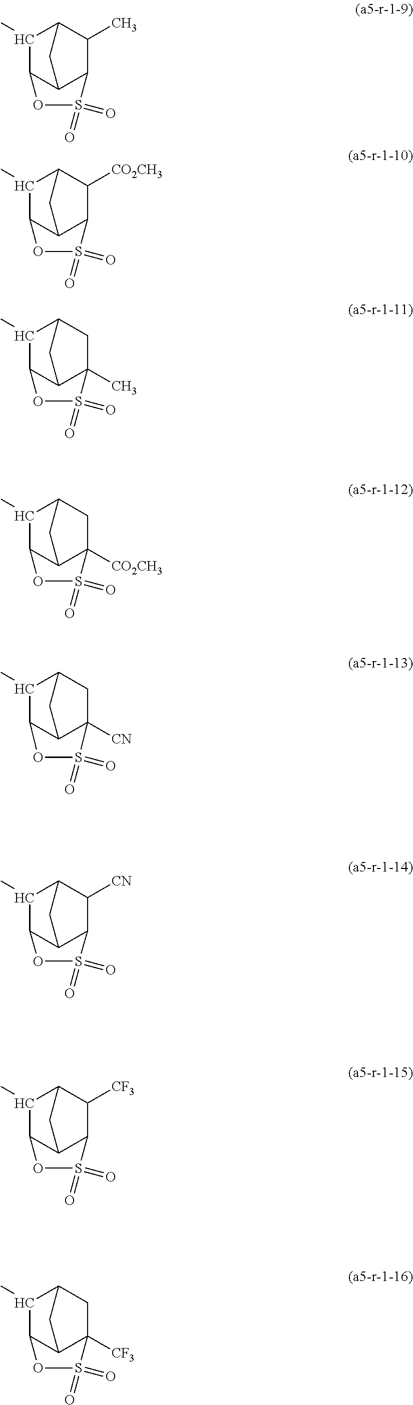

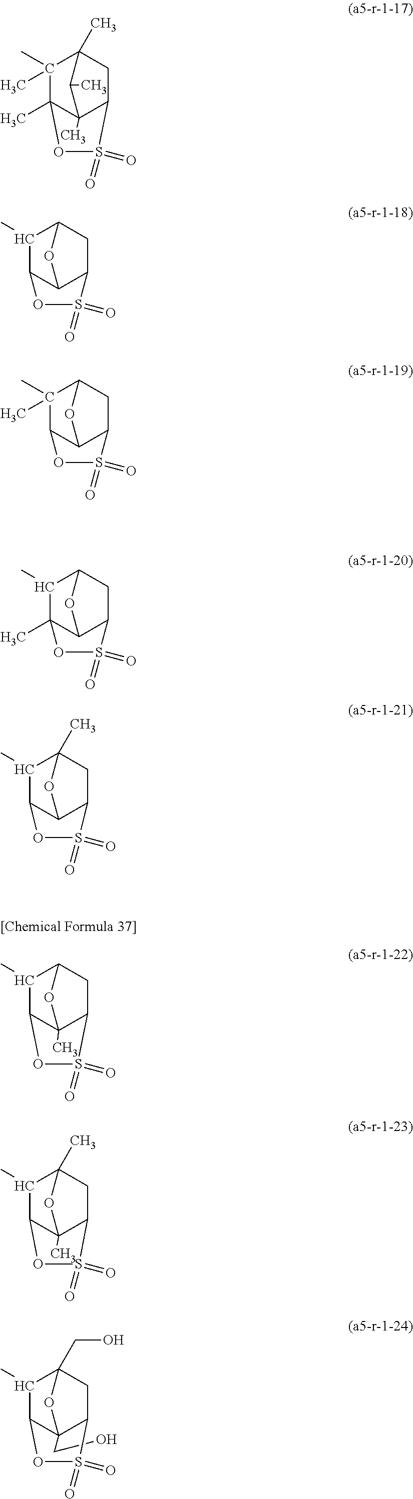

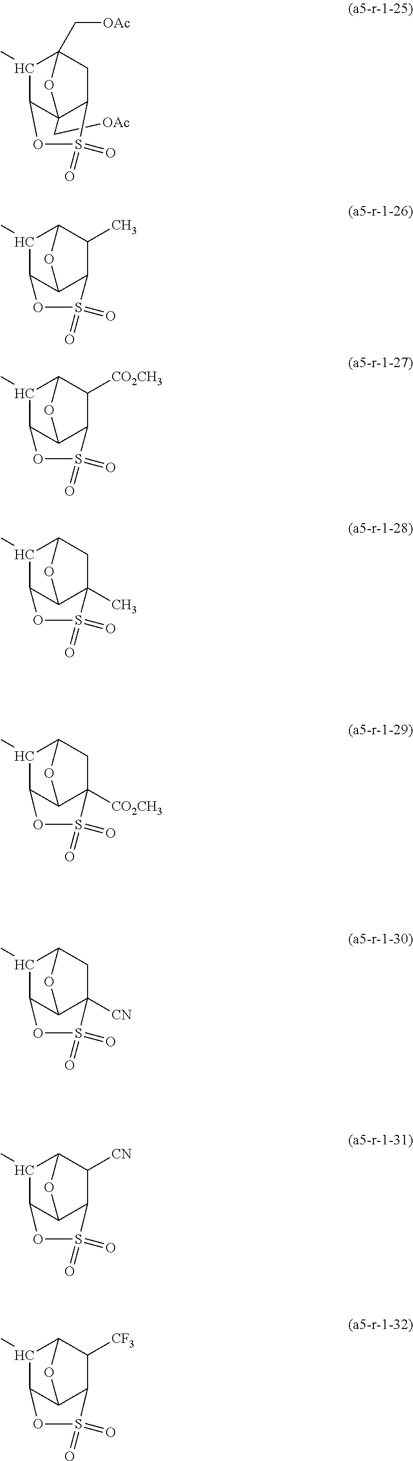

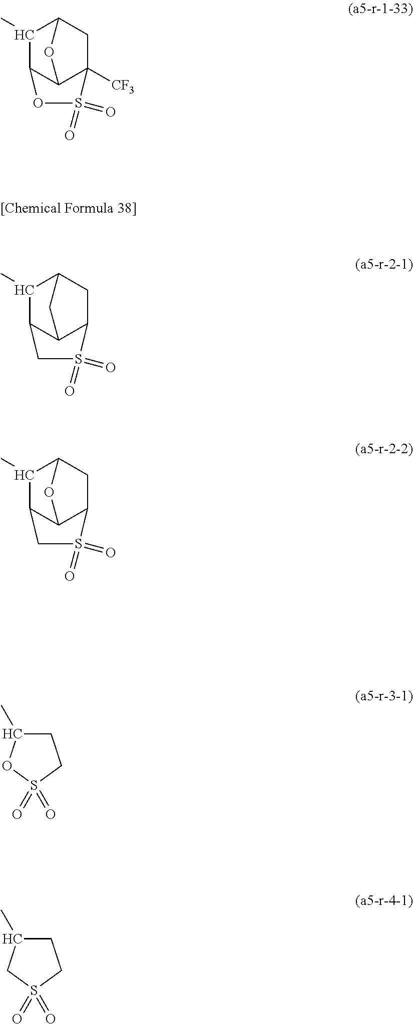

As the —SO₂— containing cyclic group, a group represented by the aforementioned general formula (a1-r-1) is preferable, at least one member selected from the group consisting of groups represented by the aforementioned chemical formulas (a1-r-1-1), (a5-r-1-18), (a5-r-3-1) and (a5-r-4-1) is more preferable, and a group represented by chemical formula (a1-r-1-1) is most preferable.

As the structural unit (a5), the structure of the other part is not particularly limited, as long as it contains an —SO₂— containing cyclic group, and a structural unit represented by general formula (a5-1) shown below is preferable.

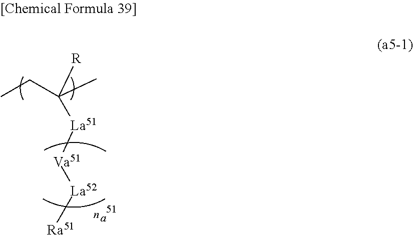

In the formula, R is the same as defined above; Va⁵¹ is a divalent hydrocarbon group; La⁵¹ represents —COO— or —CON(R^{C}′)—; La⁵² represents —O—, —COO—, —CON(R^{C}′)—, —OCO—, —CONHCO— or —CONHCS; R^{C}′ represents a hydrogen atom or a methyl group; na⁵¹ represents an integer of 0 to 3, when na⁵¹ is 1 or more, Va⁵¹ and La⁵² may be the same or different from each other; and Ra⁵¹ represents —SO₂— containing cyclic group.

In formula (a5-1), Va⁵¹ represents a divalent hydrocarbon group, and examples thereof include the same divalent hydrocarbon group as those described above for Va¹ in formula (a1-1).

na⁵¹ represents an integer of 0 to 3, and preferably 1 or 2.

Ra′¹ represents —SO₂— containing cyclic group, and examples thereof include groups represented by the aforementioned formula (a1-r-1) to (a5-r-4).

Specific examples of the structural unit (a5) include a structural unit represented by any one of the aforementioned general formula (a2-1) to (a2-4) in which Ra²¹ (lactone-containing cyclic group) has been replaced by Ra⁵¹ (—SO₂— containing cyclic group).

As the structural unit (a5) contained in the component (A1), 1 type of structural unit may be used, or 2 or more types may be used.

When the component (A1) contains the structural unit (a5), the amount of the structural unit (a5) based on the combined total of all structural units constituting the component (A1) is preferably 1 to 60 mol %, more preferably 5 to 55 mol %, still more preferably 10 to 50 mol %, and most preferably 15 to 45 mol %.

When the amount of the structural unit (a5) is at least as large as the lower limit of the above-mentioned range, a resist pattern having an excellent shape can be formed, and the lithography properties such as dimension uniformity are improved. On the other hand, when the amount of the structural unit (a5) is no more than the upper limit of the above-mentioned range, a good balance can be achieved with the other structural units.

Structural Unit (a6):

When the component (A1) is used for a resist composition used in the aforementioned dual-tone development process, the component (A1) may further contain a structural unit that is decomposed by exposure to generate acid (hereafter, referred to as “structural unit (a6)”). By virtue of including a structural unit containing an anion group that generates acid upon exposure as a structural unit (a6), it is preferable because the diffusion of generated acid can be suppressed and the contrast of the boundary between a positive region and a negative region can be improved.

As the anion group, the same groups as those described later for anion moieties of the component (G1) can be mentioned.

Structural Unit (a10):

The component (A1) may include a structural unit represented by general formula (a10-1) shown below (hereafter, referred to as “structural unit (a10)”). By virtue of including a structural unit (a10), the solubility in an organic solvent becomes excellent, the solubility in an alkali developing solution is improved, and the etching resistance becomes excellent.

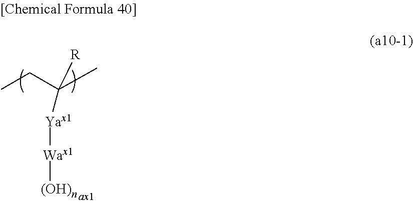

In the formula, R is as defined above; Ya^{x1} represents a single bond or a divalent linking group; Wa^{x1} represents an aromatic hydrocarbon group having a valency of (naₓ₁+1); and naₓ₁ represents an integer of 1 to 3.

In the formula (a10-1), examples of the divalent linking group for Ya^{x1} include the same divalent linking groups as those described above for Y² in formula (a0-m).

The aromatic hydrocarbon group for Wa^{x1} is a hydrocarbon group containing an aromatic ring, and the aromatic ring preferably has 5 to 30 carbon atoms, more preferably 5 to 20, still more preferably 6 to 15, and particularly preferably 6 to 12. Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom. Specific examples of the aromatic hetero ring include a pyridine ring and a thiophene ring. Specific examples for Wa^{x1} include a group in which (naₓ₁+1) hydrogen atoms have been removed from the aromatic hydrocarbon group or aromatic hetero ring.

naₓ₁ represent an integer of 1 to 3, and preferably 1 or 2.

Specific examples of structural units represented by general formula (a10-1) are shown below. In the formulas shown below, R^{α} represents a hydrogen atom, a methyl group or a trifluoromethyl group.

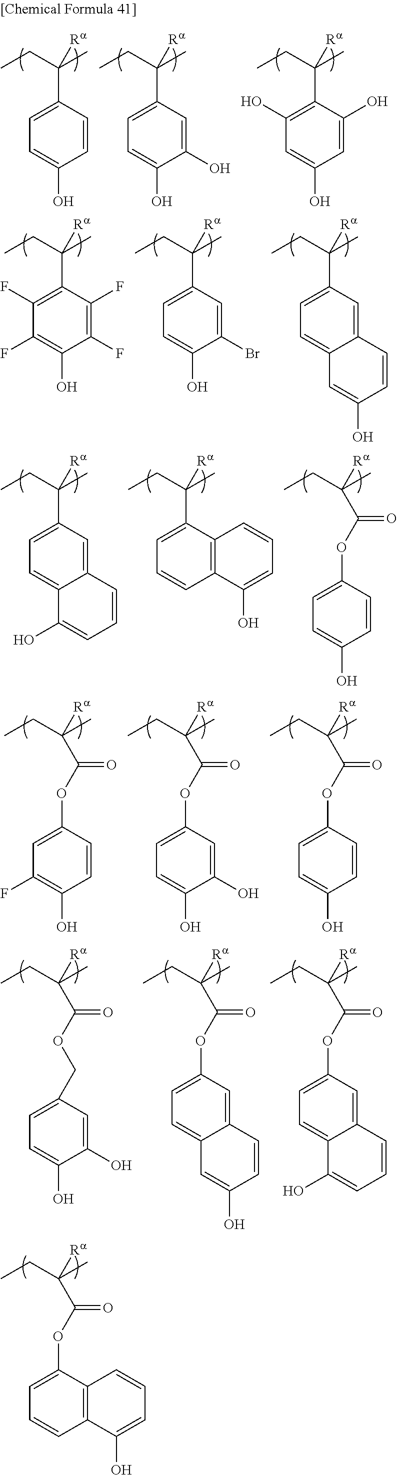

As the structural unit (a10) contained in the component (A1), 1 type of structural unit may be used, or 2 or more types may be used.

When the component (A1) contains the structural unit (a10), the amount of the structural unit (a10) based on the combined total of all structural units constituting the component (A1) is preferably 50 to 90 mol %, more preferably 55 to 85 mol %, and still more preferably 60 to 80 mol %.

Structural Unit (a12):

The component (A1) may include a structural unit represented by general formula (a12-1) shown below (hereafter, referred to as “structural unit (a12)”). By virtue of the structural unit (a12), the solubility in an alkali developing solution can be adjusted, and heat resistance and dry etching resistance are improved.

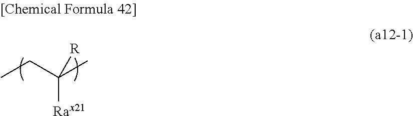

In the formula, R is the same as defined above; and Ra^{x21} represents an aromatic hydrocarbon group which may have a substituent.

In formula (a12-1), Ra^{x21} represents an aromatic hydrocarbon group which may have a substituent, and examples thereof include the same groups as those described above for aromatic hydrocarbon groups for Wa^{x1} in the aforementioned formula (a10-1).

As the substituent which the aromatic hydrocarbon group may have, the same groups as those described above for substituents for substituting the aromatic hydrocarbon group for R² in the aforementioned formula (a0-m) can be mentioned.

Specific examples of structural units represented by general formula (a12-1) are shown below. In the formulas shown below, R^{α} represents a hydrogen atom, a methyl group or a trifluoromethyl group.

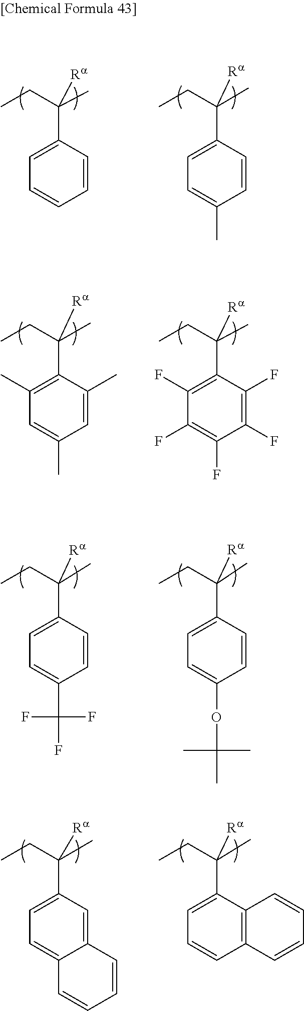

As the structural unit (a12) contained in the component (A1), 1 type of structural unit may be used, or 2 or more types may be used.

When the component (A1) contains the structural unit (a12), the amount of the structural unit (a12) based on the combined total of all structural units constituting the component (A1) is preferably 10 to 50 mol %, more preferably 15 to 45 mol %, and still more preferably 20 to 40 mol %.

In the resist composition of the present invention, the component (A) preferably contains a polymeric compound (A1) having a structural unit (a0).

Specific examples of the component (A1) include a polymeric compound consisting of a repeating structure of the structural unit (a0) and the structural unit (a1); and a polymeric compound consisting of a repeating structure of the structural unit (a0), the structural unit (a1) and the structural unit (a2).

More specific examples of the component (A1) include a polymeric compound consisting of a repeating structure of a structural unit derived from a compound represented by general formula (a0-m1), a structural unit represented by general formula (a1-1) and a structural unit represented by general formula (a2-1).

The weight average molecular weight (Mw) (the polystyrene equivalent value determined by gel permeation chromatography) of the component (A1) is not particularly limited, but is preferably 1,000 to 50,000, more preferably 1,500 to 30,000, and most preferably 2,000 to 20,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) is not particularly limited, but is preferably 1.0 to 5.0, more preferably 1.0 to 3.0, and most preferably 1.0 to 2.5. Here, Mn is the number average molecular weight.

The component (A1) can be obtained, for example, by a conventional radical polymerization or the like of the monomers corresponding with each of the structural units, using a radical polymerization initiator such as azobisisobutyronitrile (AIBN).

Furthermore, in the component (A1), by using a chain transfer agent such as HS—CH₂—CH₂—CH₂—C(CF₃)₂—OH, a —C(CF₃)₂—OH group can be introduced at the terminals of the component (A1). Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern).

As the monomers for deriving the corresponding structural units, commercially available monomers may be used, or the monomers may be synthesized by a conventional method.

In the component (A), as the component (A1), one type may be used alone, or two or more types may be used in combination.

In the component (A), the amount of the component (A1) based on the total weight of the component (A) is preferably 50% by weight or more, and more preferably 75 to 100% by weight.

When the amount of the component (A1) is at least as large as the lower limit of the above-mentioned range, the film retentiveness of the resist film at exposed portions becomes excellent, and the lithography properties and the shape of the formed resist pattern is further improved.

<Base Component (A′)>

The resist composition of the present invention may contain a base component which exhibits changed solubility in a developing solution under action of acid other than the component (A) (hereafter, referred to as “component (A′)”), as well as the component (A), as long as the effects of the present invention are not impaired.

As the component (A′), a resin component that exhibits increased solubility in an alkali developing solution under the action of acid is preferable, a polymeric compound that exhibits increased polarity by the action of acid is more preferable, and a polymeric compound including the aforementioned structural unit (a1) (hereafter, referred to as “component (A′1)”) is particularly desirable.

The component (A′1) preferably includes the structural unit (a2), as well as the structural unit (a1).

Furthermore, the component (A′1) may include the structural unit (a3), the structural unit (a4), the structural unit (a5), the structural unit (a10) or the structural unit (a12), as well as the structural unit (a1) or the structural units (a1) and (a2).

Specific examples of the component (A′1) include a polymeric compound consisting of a repeating structure of the structural unit (a1) and the structural unit (a2).

More specific examples of the component (A′1) include a polymeric compound consisting of a repeating structure of a structural unit represented by general formula (a1-1) and a structural unit represented by general formula (a2-1).

With respect to the component (A′ 1), the ratio of each structural unit, the weight average molecular weight (Mw) and the dispersity (Mw/Mn) are the same as defined above for the component (A1).

As the component (A′1), one type may be used, or two or more types may be used in combination.

In the resist composition of the present invention, the mixing ratio (weight ratio) of the component (A1) to the component (A′1) (i.e., (A1)/(A′1)) is preferably within a range from 100/0 to 1/99, more preferably from 90/10 to 10/90, and is still more preferably from 60/40 to 20/80.

When the amount of the component (A1) relative to the total amount of the components (A1) and (A′1) is within the above-mentioned range, the amount of the structural unit (a0) relative to the entire base component can be controlled, the film retentiveness of the resist film at exposed portions becomes excellent, and the dimension uniformity of the resist pattern is further improved. Further, a resist pattern having a fine dimension can be obtained. Further, the lithography properties and the shape of a resist pattern can be improved.

In the resist composition of the present invention, the amount of the component (A) can be appropriately adjusted depending on the thickness of the resist film to be formed, and the like.

<Other Components>

The resist composition of the present invention may include an acidic compound component, in addition to the component (A).

The resist composition of the present invention preferably includes a compound represented by general formula (J1) shown below as an acidic compound component (hereafter, frequently referred to as “component (J)”).

[Compound (J) Represented by General Formula (J1)]

The component (J) is an acidic compound component which is decomposed by exposure to exhibit decreased acidity. The component (J) prior to exposure has an acid strength sufficient for increasing the solubility of the component (A) in an alkali developing solution. After exposure, the component (J) is decomposed by the exposure energy to exhibit a decreased acidity. By the decrease in the acidity at exposed portions, the solubility of the component (A) in an alkali developing solution cannot be increased, or only slightly increases the solubility of the component (A) in an alkali developing solution. As a result, an excellent dissolution contrast can be obtained between the exposed portions and unexposed portions.

An acid “has an acid strength sufficient for increasing the solubility of the component (A) in an alkali developing solution” includes acid, for example, when a polymeric compound (A1) having a structural units (a0) and (a1)) is used, by conducting baking (PEB) after exposure (PEB; step (3) described later), the acid is capable of causing cleavage of at least part of the bond within the structure of the acid decomposable group in the structural unit (a1).

The component (J) is an ammonium salt having a fluorinated alkylsulfonate anion which is a strong acid. By virtue of the anion moiety being a strong acid, the compound (J) exhibits acidity (proton donor ability) prior to exposure, and increases the solubility of the component (A) in an alkali developing solution.

On the other hand, by subjecting the component (J) to exposure, a decomposition reaction involving decarboxylation proceeds, so that the bond between the nitrogen atom having Y⁴ and R⁴ bonded thereto and the carbon atom of the carbonyl group is cleaved. As a result, an ammonium salt derived from a decomposition product (H²N⁺(R⁴)—Y⁴-L²-O—Y⁵—C(R⁷)(R⁸)—SO₃⁻), carbon dioxide, a residual group derived from a decomposition product (a compound containing an aromatic ring which is formed by Y⁶ and two carbon atoms having Y⁶ bonded thereto, and which has —NO and —C(R⁵)═O bonded to the aromatic ring), and an amine (WH) derived from the counteraction are produced. With respect to the ammonium salt derived from the decomposition product, after the generation thereof, in the molecules thereof or between the molecules, the proton on acidic portion is trapped by basic portion newly generated by photoexcitation decomposition and exhibiting a pKa larger than WH. As a result, the acidity becomes smaller than the ammonium salt.

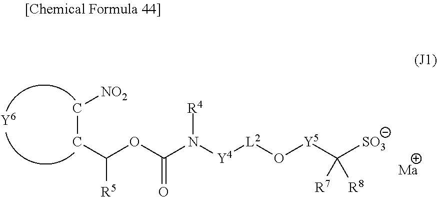

In the formula, Y⁴ represents a divalent linking group, R⁴ represents a hydrogen atom or a hydrocarbon group which may have a substituent, provided that Y⁴ and R⁴ may be mutually bonded to form a ring with the nitrogen atom having Y⁴ and R⁴ bonded thereto; R⁵ represents a hydrogen atom or a hydrocarbon group which may have a substituent; L² represents a single bond or a carbonyl group; Y⁵ represents an alkylene group of 1 to 6 carbon atoms, provided that part of the methylene group constituting the alkylene group may be replaced with an oxygen atom or a carbonyl group, part or all of the hydrogen atoms constituting the alkylene group may be substituted with an aliphatic hydrocarbon group of 1 to 6 carbon atoms which may have a fluorine atom, provided that -L²-O—Y⁵— does not represent —C(═O)—O—C(═O)—; Y⁶ represents a group which forms an aromatic ring together with the two carbon atoms having Y⁶ bonded thereto, provided that the aromatic ring may have a nitro group or a substituent other than the nitro group bonded to the aromatic ring; R⁷ and R⁸ each independently represents a fluorine atom or a linear or branched fluorinated alkyl group of 1 to 6 carbon atoms; and Ma⁺ represents a primary, secondary or tertiary ammonium coutercation which exhibits a pKa smaller than a pKa of H₂N⁺(R⁴)—Y⁴-L²-O—Y⁵—C(R⁷)(R⁸)—SO₃⁻ generated by decomposition upon exposure.

In the formula (J1), Y⁴ represents a divalent linking group.

The divalent linking group for Y⁴ is not particularly limited, and is preferably a divalent hydrocarbon group which may have a substituent, a divalent linking group containing a hetero atom, —Y⁴¹—CH[N(R⁴′)Y⁴′-L²′-O—Y⁵′—C(R⁷′)(R⁸′)—SO₃⁻]—Y⁴²— or —Y⁴¹—CH[O—Y′—C(R⁷′)(R⁸′)—SO₃⁻]—Y⁴²—.

The divalent hydrocarbon group which may have a substituent and the divalent linking group containing a hetero atom are the same as defined for those described above for Y² in the aforementioned formula (a0-m).

Y⁴¹ is a divalent hydrocarbon group which may have a substituent. As the divalent hydrocarbon group, the same groups as those described above for the “divalent hydrocarbon group which may have a substituent” for Y² in the aforementioned formula (a0-m) can be mentioned. Among these, as Y⁴¹, a linear aliphatic hydrocarbon group is preferable, more preferably a linear alkylene group, still more preferably a linear alkylene group of 1 to 5 carbon atoms, and a methylene group or an ethylene group is particularly desirable.

Y⁴² represents a single bond or a divalent hydrocarbon group which may have a substituent, and the divalent hydrocarbon group is the same as defined for the divalent hydrocarbon group represented by Y⁴¹. Among these, as Y⁴², a single bond is preferable.

Y⁴′, R⁴′, L²′, Y⁵′, R⁷′ and R⁸′ are the same as defined for Y⁴, R⁴, L², Y⁵, R⁷ and R⁸.

By virtue of Y⁴ having —Y⁴¹—CH[N(R⁴′)Y⁴′-L²′-O—Y⁵′—C(R⁷′)(R⁸′)—SO₃⁻]—Y⁴²— or —Y⁴¹—CH[O—Y⁵—C(R⁷′)(R⁸′)—SO₃⁻]—Y⁴²—, the acidity of the anion moiety of the component (J) can be increased.

Among these, as Y⁴, a linear or branched alkylene group, an aliphatic hydrocarbon group having a ring in the structure thereof, —Y⁴¹—CH[N(R⁴′)Y⁴′-L²′-O—Y⁵′—C(R⁷′)(R⁸′)—SO₃⁻]—Y⁴²— or —Y⁴′—CH[O—Y⁵′—C(R⁷′)(R⁸′)—SO₃⁻]—Y⁴²— is preferable; and a linear or branched alkylene group of 1 to 6 carbon atoms is more preferable.

In formula (J1), R⁴ is the same as defined for R² in general formula (a0-m).

Among these, as R⁴, a hydrogen atom or an aliphatic hydrocarbon group which may have a substituent is preferable, and a hydrogen atom or a linear or branched alkyl group is more preferable.

In formula (J1), Y⁴ and R⁴ may be mutually bonded to form a ring with the nitrogen atom having Y⁴ and R⁴ bonded thereto. As the ring to be formed, a ring having 3 to 8 carbon atoms is preferable, and a ring having 4 to 6 carbon atoms is particularly desirable. Specific examples of the ring include an ethyleneimine ring, a pyrrolidine ring and a piperidine ring.

In formula (J1), R¹ is the same as R³ in the aforementioned formula (a0-m), and among these, a linear or branched aliphatic hydrocarbon group or an aromatic hydrocarbon group which may have a substituent is preferable, more preferably a linear or branched alkyl group of 1 to 6 carbon atoms or an aromatic hydrocarbon group which may have a nitro group, and most preferably a methyl group or a phenyl group substituted with a nitro group (particularly preferably a phenyl group substituted with a nitro group on the ortho position).

In formula (J1), Y⁵ represents an alkylene group of 1 to 6 carbon atoms, provided that part of the methylene group constituting the alkylene group may be replaced with an oxygen atom or a carbonyl group, part or all of the hydrogen atoms constituting the alkylene group may be substituted with an aliphatic hydrocarbon group of 1 to 6 carbon atoms which may have a fluorine atom. As the alkylene group for Y⁵, the same linear or branched alkylene groups as those described above for the divalent linking group represented by Y² can be mentioned. Among these, as Y⁵, a methylene group or a carbonyl group is preferable.

In formula (J1), L² represents a single bond or a carbonyl group, provided that -L²-O—Y⁵— does not represent —C(═O)—O—C(═O)—. That is, when Y¹ has a carbonyl group on the terminal adjacent to the oxygen atom bonded to L², L² does not represent a carbonyl group.

Further, when Y⁵ does not have a carbonyl group, L² is preferably a carbonyl group.

In formula (J1), Y⁶ represents a group which forms an aromatic ring together with the two carbon atoms having Y⁶ bonded thereto, provided that the aromatic ring may have a nitro group or a substituent other than the nitro group bonded to the aromatic ring.

The aromatic ring formed by Y⁶ and 2 carbon atoms having Y⁶ bonded thereto is bonded is the same as defined for the aromatic ring formed by Y³ and 2 carbon atoms having Y³ bonded thereto in the formula (a0-m).

Examples of the aromatic ring include aromatic hydrocarbon rings, such as benzene, naphthalene, anthracene, phenanthrene, indene and fluorene; and aromatic hetero rings in which part of the carbon atoms constituting the aforementioned aromatic hydrocarbon rings has been substituted with a hetero atom. Further, the aromatic ring containing two or more aromatic hydrocarbon ring (e.g., biphenyl group and the like) can be mentioned. Examples of the hetero atom within the aromatic hetero rings include an oxygen atom, a sulfur atom and a nitrogen atom. Specific examples of the aromatic hetero ring include pyridine and thiophene. Among these, as the aromatic ring, the aromatic hydrocarbon ring is preferable, and benzene is particularly preferable.

Specific examples of Y⁶ include ═CH—, ═C<(quaternary carbon atom), —O—, —S—, ═N— and the like. The hydrogen atom within ═CH— may be substituted with a substituent.

As the substituent which the aromatic ring may have, the same substituents as those described above for substituting the aromatic ring formed by the aforementioned Y³ and 2 carbon atoms having Y³ bonded thereto in the formula (a0-m) can be mentioned.

Preferable examples of the aromatic ring formed by the aforementioned Y⁶ and 2 carbon atoms having Y⁶ bonded thereto are shown below.

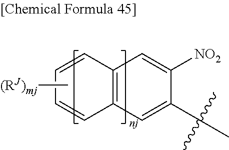

In the formula, R^{J} represents a hydrogen atom, a hydroxy group, a halogen atom, a linear or branched alkoxy group, a hydrocarbon group which may have a substituent, or a nitro group; mj represents an integer of 0 to 4; and nj represents an integer of 0 to 3. In the formula, the wavy line represents a valence bond.

In the formula, R^{J} represents a hydrogen atom, a hydroxy group, a halogen atom, a linear or branched alkoxy group, a hydrocarbon group which may have a substituent, or a nitro group.

Examples of the halogen atom for R^{J} include a fluorine atom, a chlorine atom, a bromine atom and an iodine atom, and a fluorine atom is preferable.

As the linear or branched alkoxy group for R^{J}, an alkoxy group of 1 to 6 carbon atoms is preferable. Specific examples include a group in which an oxygen atom (—O—) is bonded to an alkyl group such as a methyl group, an ethyl group, a propyl group, an isopropyl group, an n-butyl group, an isobutyl group, a tert-butyl group, a pentyl group, an isopentyl group, a neopentyl group or a hexyl group. Among these, a methoxy group or an ethoxy group is preferable.

The hydrocarbon group for R^{J} which may have a substituent may be either an aromatic hydrocarbon group or an aliphatic hydrocarbon group, and examples thereof include the same groups as those described above for the hydrocarbon group which may have a substituent for R² in the aforementioned formula (a0-m).

mj represents an integer of 0 to 4, preferably an integer of 0 to 2, more preferably 0 or 1, and most preferably 0. When mj is 2 or more, the plurality of R^{J} may be the same or different from each other.

nj represents an integer of 0 to 3. When nj represents 0, it means that the aromatic ring in the formula is a benzene ring. nj is preferably an integer of 0 to 2, more preferably 0 or 1, and most preferably 0.

In formula (J1), R⁷ and R⁸ each independently represents a fluorine atom or a linear or branched fluorinated alkyl group of 1 to 6 carbon atoms.

The fluorination ratio of the fluorinated alkyl group is preferably from 10 to 100%, more preferably from 50 to 100%, and it is most preferable that all hydrogen atoms are substituted with fluorine atoms because the acid strength increases. Specific examples of such fluorinated alkyl groups include a trifluoromethyl group, a heptafluoro-n-propyl group and a nonafluoro-n-butyl group.

Specific examples of preferable anion moieties for the component (J) are shown below.

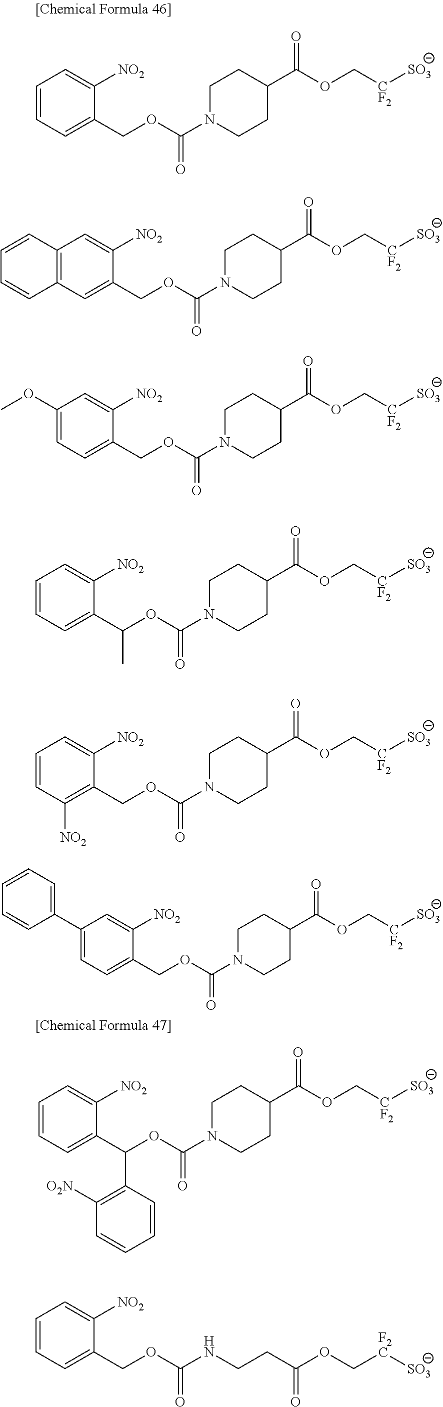

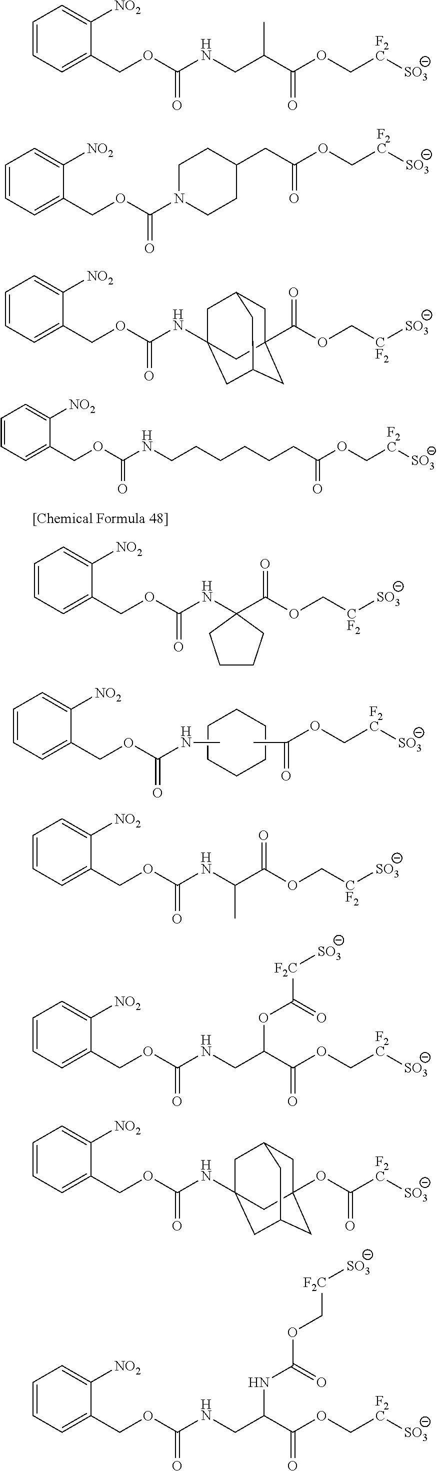

In formula (J1), Ma⁺ represents a primary, secondary or tertiary ammonium coutercation which exhibits a pKa smaller than a pKa of the ammonium salt (H₂N⁺(R⁴)—Y⁴-L²—O—Y⁵—C(R⁷)(R⁸)—SO₃⁻) derived from a decomposition product generated by decomposition upon exposure.

As Ma⁺ in formula (J1), there is not particular limitation as long as it satisfies the above pKa, and can be appropriately selected depending on the type and pKa of anion moiety in formula (J1), type and pKa of the ammonium salt derived from a decomposition product, and the like. Specifically, Ma⁺ preferably has a pKa of 1 to 6. When the pKa is no more than 6, the basicity of the cation can be rendered satisfactorily weak, and the component (J1) itself becomes an acidic compound prior to exposure. Further, the pKa can be rendered smaller than the pKa of the ammonium salt from a decomposition product. Further, when the pKa is at least 1, a salt can be more reliably formed with the counteranion prior to exposure, and it becomes possible to appropriately control the acidity of the component (J).

The structure of Ma⁺ is not particularly limited as long as it satisfies the above requirements and contains a nitrogen atom, and examples thereof include a cation represented by general formula (J1c-1) shown below.

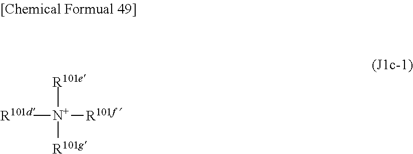

In the formula, R^{101d}′, R^{101e}′, R^{101f}, and R^{101g}′ each independently represents a hydrogen atom, a linear, branched or cyclic alkyl group, an alkenyl group, an oxoalkyl group or an oxoalkenyl group of 1 to 12 carbon atoms, an aryl group of 6 to 20 carbon atoms, an aralkyl group of 7 to 12 carbon atoms, an aryloxoalkyl group, or a combination thereof, and part or all of the hydrogen atoms of these groups may be substituted with a fluorine atom, an alkoxy group or an amino group, and one or more —CH₂— within the alkyl group may be replaced with —NH—. R^{101d}′ and R^{101e}′, or R^{101d}′, R^{101e}′ and R^{101f}′ may be mutually bonded with the nitrogen atom to form a ring, provided that, when a ring is formed, R^{101d}′ and R^{101e′}, or R^{101d}′, R^{101e}′ and R^{101f}′ forms an aliphatic hetero ring containing the nitrogen atom in the ring thereof or a hetero aromatic group containing the nitrogen atom in the ring thereof.

In formula (J1c-1), R^{101d}′, R^{101e}′, R^{101f}′ and R^{101g}′ independently represents a hydrogen atom, a linear, branched or cyclic alkyl group, an alkenyl group, an oxoalkyl group or an oxoalkenyl group of 1 to 12 carbon atoms, an aryl group of 6 to 20 carbon atoms, an aralkyl group of 7 to 12 carbon atoms or an aryloxoalkyl group.

As the alkyl group for R^{101d}′ to R^{101g}′, the same alkyl groups as those described above as a substituent which the aromatic ring formed by Y³ and two carbon atoms to which Y³ is bonded, may have in the formula (a0-m) can be mentioned, preferably has 1 to 10 carbon atoms, and a methyl group, an ethyl group, a propyl group or a butyl group is particularly desirable.

The alkenyl group for R^{101d}′ to R^{101g}′ preferably has 2 to 10 carbon atoms, more preferably 2 to 5, and still more preferably 2 to 4. Specific examples thereof include a vinyl group, a propenyl group (an allyl group), a butynyl group, a 1-methylpropenyl group and a 2-methylpropenyl group.

The oxoalkyl group for R^{101d}′ to R^{101g}′ preferably has 2 to 10 carbon atoms, and examples thereof include a 2-oxoethyl group, a 2-oxopropyl group, a 2-oxocyclopentyl group and a 2-oxocyclohexyl group.

Examples of the oxoalkenyl group for R^{101d}′ to R^{101g}′ include an oxo-4-cyclohexenyl group and a 2-oxo-4-propenyl group.

As the aryl group for R^{101d}′ to R^{101g}′, the same aromatic hydrocarbon groups as those described above as an aromatic ring which formed by Y³ and two carbon atoms to which Y³ is bonded in the formula (a0-m) can be mentioned, and a phenyl group or a naphthyl group is particularly desirable.

Examples of the aralkyl group and aryloxoalkyl group for R^{101d}′ to R^{101g}′ include a benzyl group, a phenylethyl group, a phenethyl group, a 2-phenyl-2-oxoethyl group, a 2-(1-naphthyl)-2-oxoethyl group and a 2-(2-naphthyl)-2-oxoethyl group.

R^{101d}′ to R^{101g}′ are constituted of only an alkyl group and/or a hydrogen atom, it is preferable that at least one of the hydrogen atoms or carbon atoms is substituted with a halogen atom such as a fluorine atom, an alkoxy group or a sulfur atom, and it is more preferable that a hydrogen atom within an alkyl group is substituted with a fluorine atom.

Further, R^{101d} and R^{101e}, or R^{101d}, R^{101e} and R^{101f} may be mutually bonded to form a ring with the nitrogen atom. Examples of the formed ring include an aliphatic hetero ring and a heteroaromatic ring, and specific examples thereof include a pyrrolidine ring, a piperidine ring, a hexamethyleneimine ring, an azole ring, a pyridine ring, a pyrimidine ring, an azepine ring, a pyrazine ring, a quinoline ring and a benzoquinoline ring.

Further, the ring may contain an oxygen atom in the ring skeleton thereof, and preferable examples of rings which contain an oxygen atom include an oxazole ring and an isooxazole ring.

As the cation moiety represented by general formula (J1c-1), cation moieties represented by general formulae (J1c-11) to (J1c-14) shown below are preferable.

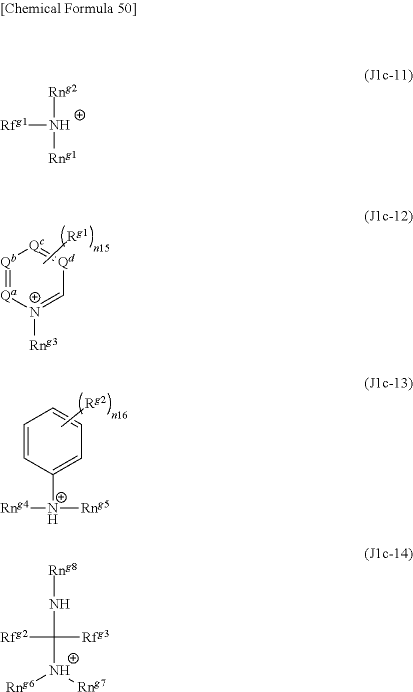

In the formulas, Rf^{g1}, Rf^{g2} and Rf^{g3} each independently represents a fluorinated alkyl group of 1 to 12 carbon atoms;

Rn^{g1} and Rn^{g2} each independently represents a hydrogen atom, an alkyl group of 1 to 5 carbon atoms or a fluorinated alkyl group of 1 to 5 carbon atoms, provided that Rn^{g1} and Rn^{g2} may be mutually bonded to form a ring; Q^{a} to Q^{d} each independently represents a carbon atom or a nitrogen atom; Rn^{g3} represents a hydrogen atom or a methyl group; Rn^{g4}, Rn^{g5}, Rn^{g6}, Rn^{g7} and Rn^{g8} each independently represents a hydrogen atom, an alkyl group of 1 to 5 carbon atoms or an aromatic hydrocarbon group; R^{g1} and R^{g2} each independently represents a hydrocarbon group; n15 and n16 each independently represents an integer of 0 to 4, provided that, when n15 and n16 is 2 or more, the plurality of R^{g1} and R^{g2} which substitute the hydrogen atoms of the adjacent carbon atom may be bonded to form a ring.

In formulae (J1c-11) and (J1c-14), Rf^{g1} to Rf^{g3} each independently represents a fluorinated alkyl group of 1 to 12 carbon atoms, and is preferably a fluorinated alkyl group of 1 to 5 carbon atoms in which 50% or more of the hydrogen atoms of the alkyl group have been fluorinated.

In formulae (J1c-13) and (J1c-14), Rn^{g4} to Rn^{g8} each independently represents an alkyl group of 1 to 5 carbon atoms or an aromatic hydrocarbon group, and is the same as defined for the alkyl group of 1 to 5 carbon atoms and aryl groups as those described above in the explanation of R^{101d}, R^{101e}, R^{101f} and R^{101g} in formula (J1c-1).

In formulae (J1c-12) and (J1c-13), n15 and n16 each independently represents an integer of 0 to 4, preferably an integer of 0 to 2, and more preferably 0. In formulae (J1c-12) and (J1c-13), R^{g1} and R^{g2} each independently represents a hydrocarbon group, and is preferably an alkyl group or alkenyl group of 1 to 12 carbon atoms. The alkyl group and the alkenyl group are the same as defined for those described in the explanation of formula (J1c-1).

When n15 and n16 are 2 or more, the plurality of R^{g1} and R^{g2} may be the same or different from each other. Further, when n15 and n16 is 2 or more, the plurality of R& and R^{g2} which substitute the hydrogen atoms bonded to the adjacent carbon atom may be bonded to form a ring. Examples of the formed ring include a benzene ring and a naphthalene ring. That is, the compound represented by formula (J1c-12) or (J1c-13) may be a condensed ring compound formed by condensation of 2 or more rings.

Specific examples of compounds represented by any one of the aforementioned formulae (J1c-11) to (J1c-14) are shown below.

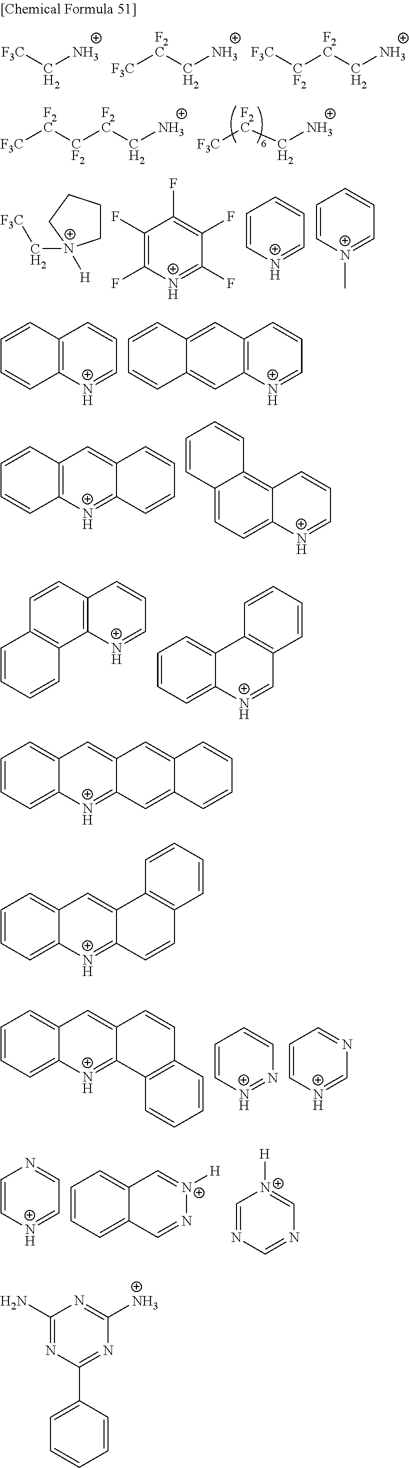

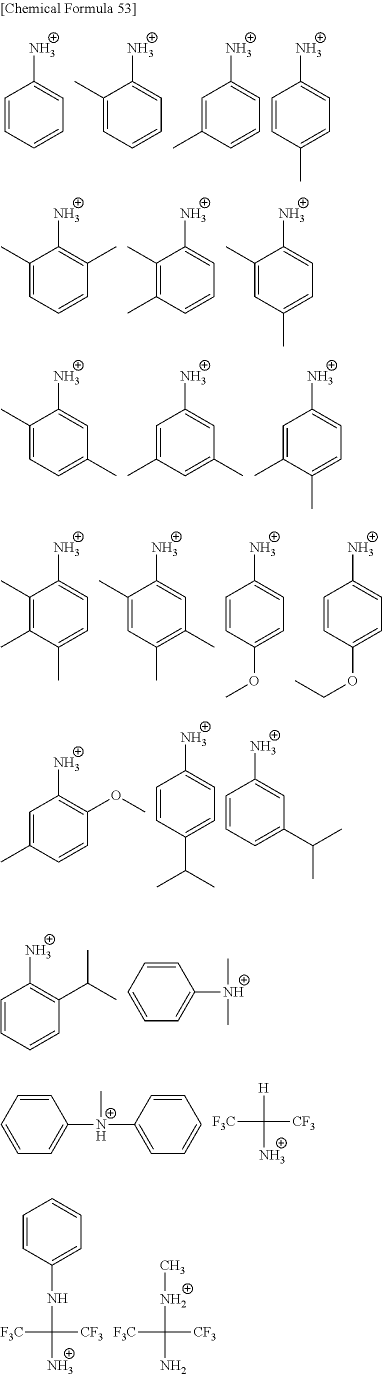

Further, Ma⁺ may be a divalent cation. In the case where Ma⁺ is a divalent cation, and only one SO₃⁻ is present in the component (J), the molar ratio of the anion moiety:the cation moiety in the component (J) becomes 2:1. Likewise, in the case where Ma⁺ is a monovalent cation as that represented by the aforementioned formula (J1c-1), and two SO₃⁻ are present in the component (J) (the case where Y⁴ has SO₃⁻), the molar ratio of the anion moiety:the cation moiety in the component (J) becomes 1:2.

Specific examples of the divalent ammonium cation include an ammonium cation represented by formula (J1c-2) shown below.

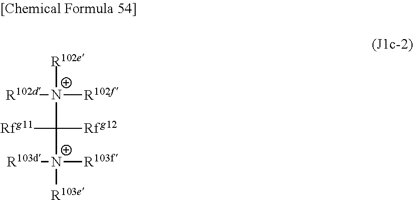

In the formula, Rf^{g11} and Rf^{g12} are the same as defined for R^{101d}′ to R^{101f}′; R^{102d} R^{102e}′, R^{102f}′, R^{103d}′, R^{103e}′ and R^{103f}′ are the same as defined for R^{101d}′ to R^{101f}′; R^{102d} and R^{102e}′, R^{102e}′ and R^{102f}′, R^{103d}′ and R^{103e}′, or R^{103e}′ and R^{103f}′ may be mutually bonded with the nitrogen atom to form a ring, provided that, when a ring is formed, R^{102d}′ and R^{102e}′, R^{102e}′ and R^{102f}′, R^{103d}′, and R^{103e}′, or R^{103e}′ and R^{103f}′ forms an aliphatic heteroring containing the nitrogen atom in the ring thereof or a heteroaromatic ring containing the nitrogen atom in the ring thereof.

A specific example of a cation moiety represented by the formula (J1c-2) is shown below.

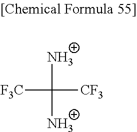 [SMILES: [NH3+]C([NH3+])(C(F)(F)F)C(F)(F)F]

As the component (J), one type of compound may be used alone, or two or more types may be used in combination.

When the resist composition of the present invention contains the component (J), the amount of the component (J) relative to 100 parts by weight of the component (A) is preferably within a range from 0.5 to 30 parts by weight, more preferably from 1 to 20 parts by weight, and still more preferably from 2 to 15 parts by weight.

When the amount of the component (J) is at least as large as the lower limit of the above-mentioned range, an excellent dissolution contrast can be obtained. On the other hand, when the amount of the component (J) is no more than the upper limit of the above-mentioned range, the storage stability and the lithography properties become excellent.

Acid Component (G)

The resist composition of the present invention may further include an acidic compound component other than the aforementioned component (J) (hereafter, referred to as “acid component or component (G)”), in addition to the component (A).

As the component (G), an acidic salt having an acid strength sufficient for increasing the solubility of the component (A) in an alkali developing solution (hereafter, referred to as “component (G1)”) or an acid other than acid salts (acids which do not form a salt, acids which are not ionic; hereafter, referred to as “component (G2)”) can be used.

An acid “has an acid strength sufficient for increasing the solubility of the component (A) in an alkali developing solution” includes acid, for example, when a polymeric compound (A1) having a structural unit (a0) and a structural unit (a1) is used, by conducting baking (PEB) in step (3) described above, the acid is capable of causing cleavage of at least part of the bond within the structure of the acid decomposable group in the structural unit (a1).

Component (G1)

Examples of the component (G1) include an ionic compound (salt compound) having a nitrogen-containing cation and a counteranion. The component (G1) itself exhibits acidity even in the form of a salt, and acts as a proton donor.

Hereafter, the cation moiety and the anion moiety of the component (G1) will be described.

(Cation Moiety of Component (G1))

The cation moiety of the component (G1) is not particularly limited as long as it contains a nitrogen atom. As a preferable example, a cation represented by the general formula (J1c-1) can be mentioned.

As the cation moiety represented by general formula (J1c-1), cation moieties represented by the general formulae (J1c-11) to (J1c-14) are preferable, and specific examples thereof include the same cation moieties as those exemplified above for specific examples of the cation moieties represented by the general formulae (J1c-11) to (J1c-14).

(Anion Moiety of Component (G1))

The anion moiety of the component (G1) is not particularly limited, and any of those generally used the anion moiety of a salt used in a resist composition may be appropriately selected for use.

Among these, as the anion moiety of the component (G1), those which forms a salt with the aforementioned cation moiety for the component (G1) to form a component (G1) that is capable of increasing the solubility of the component (A) in an alkali developing solution is preferable.

That is, the anion moiety of the component (G1) preferably has a strong acidity. Specifically, the pKa of the anion moiety is more preferably 0 or less, still more preferably −15 to −1, and particularly preferably −13 to −3. When the pKa of the anion moiety is no more than 0, the acidity of the anion can be rendered satisfactorily strong relative to a cation having a pKa of 7 or less, and the component (G1) itself becomes an acidic compound. On the other hand, when the pKa of the anion moiety is −15 or more, deterioration of the storage stability caused by the component (G1) being excessively acidic can be prevented.

As the anion moiety of the component (G1), an anion moiety having at least one anion group selected from a sulfonate anion, a carboxylate anion, a sulfonylimide anion, a bis(alkylsulfonyl)imide anion and a tris(alkylsulfonyl)methide anion is preferable.

Specific examples include anions represented by general formula: “R⁴″SO₃⁻ (R⁴″ represents a linear, branched or cyclic alkyl group which may have a substituent, a halogenated alkyl group, an aryl group or an alkenyl group)”.

In the aforementioned general formula “R⁴″SO₃⁻”, R⁴″ represents a linear, branched or cyclic alkyl group which may have a substituent, a halogenated alkyl group, an aryl group or an alkenyl group.

The linear or branched alkyl group for the aforementioned R⁴″ preferably has 1 to 10 carbon atoms, more preferably 1 to 8, and most preferably 1 to 4.

The cyclic alkyl group for the aforementioned R⁴″ preferably has 4 to 15 carbon atoms, more preferably 4 to 10 carbon atoms, and most preferably 6 to 10 carbon atoms.

When R⁴″ represents an alkyl group, examples of “R⁴″SO₃⁻” include alkylsulfonates, such as methanesulfonate, n-propanesulfonate, n-butanesulfonate, n-octanesulfonate, 1-adamantanesulfonate, 2-norbornanesulfonate and d-camphor-10-sulfonate.

The halogenated alkyl group for the aforementioned R⁴″ is an alkyl group in which part or all of the hydrogen atoms thereof have been substituted with a halogen atom. The alkyl group preferably has 1 to 5 carbon atoms, and is preferably a linear or branched alkyl group, and more preferably a methyl group, an ethyl group, a propyl group, an isopropyl group, an n-butyl group, a tert-butyl group, a tert-pentyl group or an isopentyl group. Examples of the halogen atom which substitutes the hydrogen atoms include a fluorine atom, a chlorine atom, an iodine atom and a bromine atom.

In the halogenated alkyl group, it is preferable that 50 to 100% of all hydrogen atoms within the alkyl group (prior to halogenation) have been substituted with a halogen atom, and it is preferable that all hydrogen atoms have been substituted with a halogen atom.

As the halogenated alkyl group, a fluorinated alkyl group is preferable. The fluorinated alkyl group preferably has 1 to 10 carbon atoms, more preferably 1 to 8 carbon atoms, and most preferably 1 to 4 carbon atoms.

Further, the fluorination ratio of the fluorinated alkyl group is preferably from 10 to 100%, more preferably from 50 to 100%, and it is particularly preferable that all hydrogen atoms are substituted with fluorine atoms because the acid strength increases.

Specific examples of such fluorinated alkyl groups include a trifluoromethyl group, a heptafluoro-n-propyl group and a nonafluoro-n-butyl group.

The aryl group for R⁴″ is preferably an aryl group of 6 to 20 carbon atoms.

The alkenyl group for R⁴″ is preferably an alkenyl group of 2 to 10 carbon atoms.

With respect to R⁴″, the expression “may have a substituent” means that part of or all of the hydrogen atoms within the aforementioned linear, branched or cyclic alkyl group, halogenated alkyl group, aryl group or alkenyl group may be substituted with substituents (atoms other than hydrogen atoms, or groups).

R⁴″ may have one substituent, or two or more substituents.

Examples of the substituent include a halogen atom, a hetero atom, an alkyl group, and a group represented by the formula X³-Q′- (in the formula, Q′ represents a divalent linking group containing an oxygen atom; and X³ represents a hydrocarbon group of 1 to 30 carbon atoms which may have a substituent).

Examples of halogen atoms and alkyl groups include the same halogen atoms and alkyl groups as those described above with respect to the halogenated alkyl group for R⁴″.

Examples of hetero atoms include an oxygen atom, a nitrogen atom, and a sulfur atom.

In the group represented by formula X³-Q′-, Q′ represents a divalent linking group containing an oxygen atom.

Q′ may contain an atom other than an oxygen atom. Examples of atoms other than oxygen include a carbon atom, a hydrogen atom, a sulfur atom and a nitrogen atom.

Examples of divalent linkage groups containing an oxygen atom include non-hydrocarbon, oxygen atom-containing linkage groups such as an oxygen atom (an ether bond; —O—), an ester bond (—C(═O)—O—), an amido bond (—C(═O)—NH—), a carbonyl group (—C(═O)—) and a carbonate group (—O—C(═O)—O—); and a combination of any of the aforementioned non-hydrocarbon, oxygen atom-containing linking groups with an alkylene group. Furthermore, the combinations may have a sulfonyl group (—SO₂—) bonded thereto.

Specific examples of the combinations of the aforementioned non-hydrocarbon, oxygen atom-containing linking groups with an alkylene group include —R⁹¹—O—, —R⁹²—O—C(═O)—, —C(═O)—O—R⁹³—O—C(═O)—, —SO₂—O—R⁹⁴—O—C(═O)—, —R⁹⁵—SO₂—O—R⁹⁴—O—C(═O)-(in the formulas, each of R⁹¹ to R⁹⁵ independently represents an alkylene group).

The alkylene group for R⁹¹ to R⁹⁵ is preferably a linear or branched alkylene group, and preferably has 1 to 12 carbon atoms, more preferably 1 to 5, and particularly preferably 1 to 3.

Specific examples of the alkylene group include a methylene group [—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group [—CH₂CH₂—]; alkylethylene groups such as —CH(CH₃)CH₂—, —CH(CH₃)CH(CH₃)—, —C(CH₃)₂CH₂— and —CH(CH₂CH₃)CH₂—; a trimethylene group (n-propylene group) [—CH₂CH₂CH₂—]; alkyltrimethylene groups such as —CH(CH₃)CH₂CH₂— and —CH₂CH(CH₃)CH₂—; a tetramethylene group [—CH₂CH₂CH₂CH₂—]; alkyltetramethylene groups such as —CH(CH₃)CH₂CH₂CH₂— and —CH₂CH(CH₃)CH₂CH₂—; and a pentamethylene group [—CH₂CH₂CH₂CH₂CH₂—].

As Q′, a divalent linking group containing an ester bond or an ether bond is preferable, and —R⁹¹—O—, —R⁹²—O—C(═O)— or —C(═O)—O—R⁹³—O—C(═O)— is more preferable.

In the group represented by the formula X³-Q′-, the hydrocarbon group for X³ may be either an aromatic hydrocarbon group or an aliphatic hydrocarbon group, and these hydrocarbon groups may have a substituent.

As the hydrocarbon group for X³, the same groups as those described above for the hydrocarbon group which may have a substituent for R² in the aforementioned formula (a0-m) can be mentioned.

Among these, as X³, a linear alkyl group which may have a substituent, or a cyclic group which may have a substituent is preferable. The cyclic group may be either an aromatic hydrocarbon group which may have a substituent, or an aliphatic cyclic group which may have a substituent, and an aliphatic cyclic group which may have a substituent is preferable.

As the aromatic hydrocarbon group, a naphthyl group which may have a substituent, or a phenyl group which may have a substituent is preferable.

As the aliphatic cyclic group which may have a substituent, an aliphatic polycyclic group which may have a substituent is preferable. As the aliphatic polycyclic group, the aforementioned group in which one or more hydrogen atoms have been removed from a polycycloalkane, or any one of groups represented by the aforementioned formulae (L2) to (L6), (S3) and (S4) are preferable.

Among these examples, as the aforementioned R⁴″, a halogenated alkyl group or a group having X³-Q′- as a substituent is preferable.

When the R⁴″ group has X³-Q′- as a substituent, as R⁴″, a group represented by the formula: X³-Q′-Y³— (in the formula, Q′ and X³ are the same as defined above, and Y³ represents an alkylene group of 1 to 4 carbon atoms which may have a substituent or a fluorinated alkylene group of 1 to 4 carbon atoms which may have a substituent is preferable.

In the group represented by the formula X³-Q′-Y³—, as the alkylene group for Y³, the same alkylene group as those described above for Q′ in which the number of carbon atoms is 1 to 4 can be used.

As the fluorinated alkylene group, the aforementioned alkylene group in which part or all of the hydrogen atoms has been substituted with fluorine atoms can be used.

Specific examples of Y³ include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—; —CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)—, —C(CF₃)₂CH₂—; —CH₂—, —CH₂CH₂—, —CH₂CH₂CH₂—, —CH(CH₃)CH₂—, —CH(CH₂CH₃)—, —C(CH₃)₂—, —CH₂CH₂CH₂CH₂—, —CH(CH₃)CH₂CH₂—, —CH₂CH(CH₃)CH₂—, —CH(CH₃)CH(CH₃)—, —C(CH₃)₂CH₂—, —CH(CH₂CH₃)CH₂—CH(CH₂CH₂CH₃)—, and —C(CH₃)(CH₂CH₃)—.

As Y³, a fluorinated alkylene group is preferable, and a fluorinated alkylene group in which the carbon atom bonded to the adjacent sulfur atom is fluorinated is particularly desirable. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—; —CH₂CF₂—, —CH₂CH₂CF₂—, —CH₂CF₂CF₂—; —CH₂CH₂CH₂CF₂—, —CH₂CH₂CF₂CF₂—, and —CH₂CF₂CF₂CF₂—.

Of these, —CF₂—, —CF₂CF₂—, —CF₂CF₂CF₂— or CH₂CF₂CF₂— is preferable, —CF₂—, —CF₂CF₂— or —CF₂CF₂CF₂— is more preferable, and —CF₂— is particularly desirable.

The alkylene group or fluorinated alkylene group may have a substituent. The alkylene group or fluorinated alkylene group “has a substituent” means that part or all of the hydrogen atoms or fluorine atoms in the alkylene group or fluorinated alkylene group has been substituted with groups other than hydrogen atoms and fluorine atoms.

Examples of substituents which the alkylene group or fluorinated alkylene group may have include an alkyl group of 1 to 4 carbon atoms, an alkoxy group of 1 to 4 carbon atoms, and a hydroxyl group.

Specific examples of groups represented by formula R⁴″SO₃⁻ in which R⁴″ represents X³-Q′-Y³— include anions represented by the following formulae (b1) to (b9).

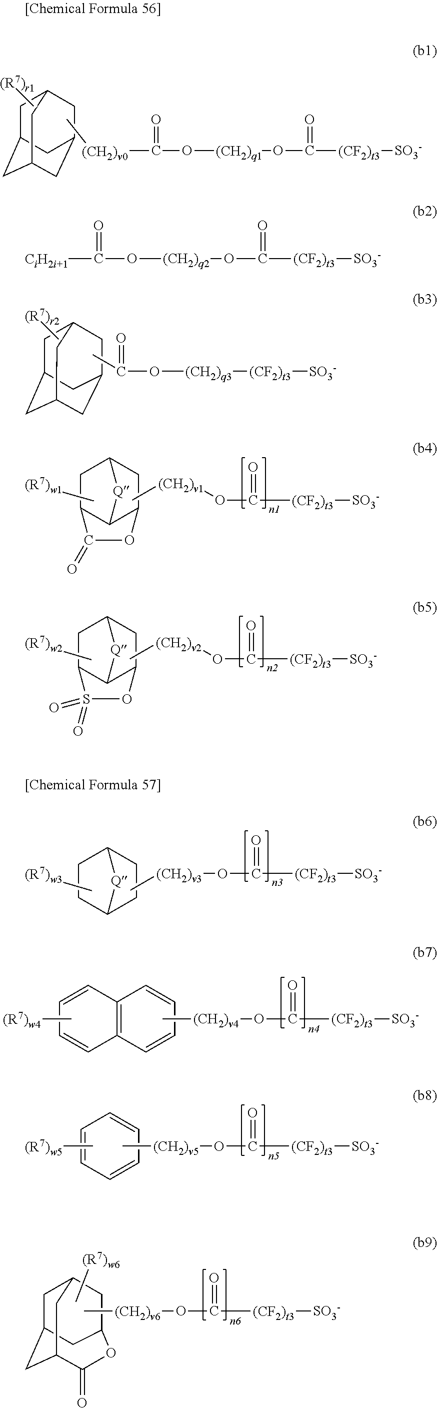

In the formulae, q1 and q2 each independently represents an integer of 1 to 5; q3 represents an integer of 1 to 12; t3 represents an integer of 1 to 3; r1 and r2 each independently represents an integer of 0 to 3; i represents an integer of 1 to 20; R⁷ represents a substituent; n1 to n6 each independently represents 0 or 1; v0 to v6 each independently represents an integer of 0 to 3; w1 to w6 each independently represents an integer of 0 to 3; and Q″ is the same as defined above.

As the substituent for R⁷, the same groups as those which the aforementioned aliphatic hydrocarbon group or aromatic hydrocarbon group may have as a substituent in the explanation or X³ can be used.

If there are two or more of the R⁷ group, as indicated by the values r1, r2, and w1 to w6, then the two or more of the R⁷ groups may be the same or different from each other.

Further, as preferable examples of the anion moiety of the component (01), an anion represented by general formula (G1a-3) shown below and an anion moiety represented by general formula (G1a-4) shown below can also be mentioned.

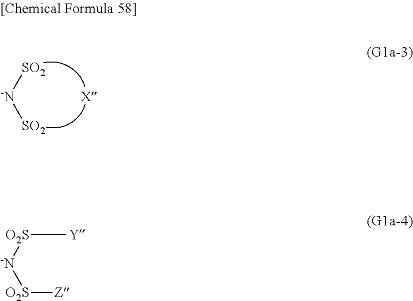

In the formulas, X″ represents an alkylene group of 2 to 6 carbon atoms in which at least one hydrogen atom has been substituted with a fluorine atom; and Y″ and Z″ each independently represents an alkyl group of 1 to 10 carbon atoms in which at least one hydrogen atom has been substituted with a fluorine atom.

In formula (G1a-3), X″ represents a linear or branched alkylene group in which at least one hydrogen atom has been substituted with a fluorine atom, and the alkylene group preferably has 2 to 6 carbon atoms, more preferably 3 to 5 carbon atoms, and most preferably 3 carbon atoms.

In formula (G1a-4), each of Y″ and Z″ independently represents a linear or branched alkyl group in which at least one hydrogen atom has been substituted with a fluorine atom, and the alkyl group preferably has 1 to 10 carbon atoms, more preferably 1 to 7 carbon atoms, and most preferably 1 to 3 carbon atoms.

The smaller the number of carbon atoms of the alkylene group for X″ or those of the alkyl group for Y″ and Z″ within the above-mentioned range of the number of carbon atoms, the more the solubility in a resist solvent is improved.

Further, in the alkylene group for X″ or the alkyl group for Y″ and Z″, it is preferable that the number of hydrogen atoms substituted with fluorine atoms is as large as possible because the acid strength increases and the transparency to high energy radiation of 200 nm or less or electron beam is improved.

The amount of fluorine atoms within the alkylene group or alkyl group, i.e., fluorination ratio, is preferably from 70 to 100%, more preferably from 90 to 100%, and it is most desirable that the alkylene group or alkyl group be a perfluoroalkylene or perfluoroalkyl group in which all hydrogen atoms are substituted with fluorine atoms.

As the anion moiety of the component (G1), an anion represented by the aforementioned formula “R⁴″SO₃⁻” (in particular, an anion in which R⁴″ is “X³-Q′-Y³—”, and specific examples thereof include any one of anions represented by the aforementioned formulae (b1) to (b9)) or an anion represented by the aforementioned formula (G1a-3) is particularly preferable.

As the component (G1), one type of compound may be used alone, or two or more types may be used in combination.

In the resist composition, the amount of the component (G1) within the component (G) is preferably 40% by weight or more, still more preferably 70% by weight or more, and may be even 100% by weight. When the amount of the component (G1) is at least as large as the lower limit of the above-mentioned range, the storage stability and the lithography properties become excellent.

When the resist composition of the present invention contains the component (G1), the amount of the component (G1) relative to 100 parts by weight of the component (A) is preferably within a range from 0.5 to 30 parts by weight, more preferably from 1 to 20 parts by weight, and still more preferably from 2 to 15 parts by weight. When the amount of the component (G1) is within the above-mentioned range, the lithography properties become excellent.

Component (G2)

The component (G2) is a component which does not fall under the definition of the component (G1), and the component (G2) itself exhibits acidity, so as to act as a proton donor. Examples of the component (G2) include a non-ionic acid which does not form a salt.

As the component (G2), there is no particular limitation as long as it is an acid exhibiting an acid strength sufficient for increasing the solubility of the base component (A) in an alkali developing solution. As the component (G2), in terms of the reactivity with the acid dissociable group of the base component and ease in increasing the solubility of the resist film in an alkali developing solution, an imine acid or a sulfonic acid compound is preferable, and examples thereof include sulfonylimide, bis(alkylsulfonyl)imide, tris(alkylsulfonyl)methide, and any of these compounds which have a fluorine atom.

In particular, a compound represented by any one of general formulae (G2-1) to (G2-3) shown below (preferably a compound represented by general formula (G2-2)), a compound in which an anion represented by any one of general formulae (b1) to (b9) described above has “—SO₃” replaced by “—SO₃H”, a compound in which an anion represented by general formula (G1a-3) or (G1a-4) described above has “N” replaced by “NH”, and camphorsulfonic acid are preferable. Other examples include acid components such as a fluorinated alkyl group-containing carboxylic acid, a higher fatty acid, a higher alkylsulfonic acid, and a higher alkylarylsulfonic acid.

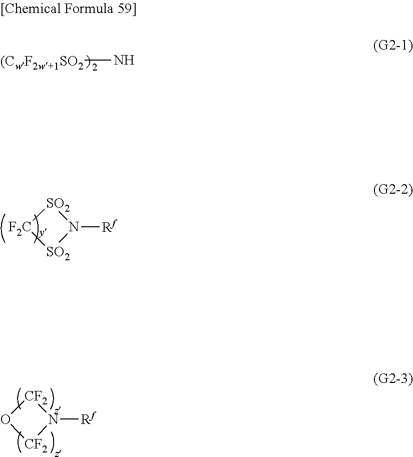

In formula (G2-1), w′ represents an integer of 1 to 5. In formula (G2-2), R^{f} represents a hydrogen atom or an alkyl group (provided that part or all of the hydrogen atoms within the alkyl group may be substituted with a fluorine atom, a hydroxy group, an alkoxy group, a carboxy group or an amino group); and y′ represents 2 or 3. In formula (G2-3), R^{f} is the same as defined above; and z′ represents 2 or 3.

Examples of compounds represented by the aforementioned formula (G2-1) include (C₄F₉SO₂)₂NH and (C₃F₇SO₂)₂NH.

In the aforementioned formula (G2-2), the alkyl group for R^{f} preferably has 1 or 2 carbon atoms, and more preferably 1.

Examples of the alkoxy group which may substitute the hydrogen atom(s) within the alkyl group include a methoxy group and an ethoxy group.

Examples of a compound represented by the aforementioned formula (G2-2) include a compound represented by a chemical formula (G2-21) shown below.

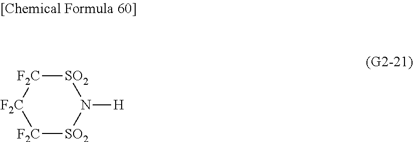 [SMILES: O=S1(=O)NS(=O)(=O)C(F)(F)C(F)(F)C1(F)F]

In the aforementioned formula (G2-3), R^{f} is the same as defined for R^{f} in formula (G2-2).

Examples of a compound represented by the aforementioned formula (G2-3) include a compound represented by a chemical formula (G2-31) shown below.

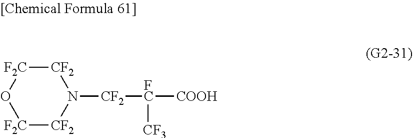

As the fluorinated alkyl group-containing carboxylic group, for example, C₁₀F₂₁COOH can be mentioned.

Examples of the higher fatty acid include higher fatty acids having an alkyl group of 8 to 20 carbon atoms, and specific examples thereof include dodecanoic acid, tetradecanoic acid, and stearic acid.

The alkyl group of 8 to 20 carbon atoms may be either linear or branched. Further, the alkyl group of 8 to 20 carbon atoms may have a phenylene group, an oxygen atom or the like interposed within the chain thereof. Furthermore, the alkyl group of 8 to 20 carbon atoms may have part of the hydrogen atoms substituted with a hydroxy group or a carboxy group.

Examples of the higher alkylsulfonic acid include sulfonic acids having an alkyl group preferably with an average of 9 to 21 carbon atoms, more preferably 12 to 18 carbon atoms, and specific examples thereof include decanesulfonic acid, dodecanesulfonic acid, tetradecanesulfonic acid, pentadecanesulfonic acid and octadecanesulfonic acid.

Examples of the higher alkylarylsulfonic acid include alkylbenzenesulfonic acids and alkylnaphthalenesulfonic acids having an alkyl group preferably with an average of 6 to 18 carbon atoms, more preferably 9 to 15 carbon atoms, and specific examples thereof include dodecylbenzenesulfonic acid and decylnaphthalenesulfonic acid.

Examples of the acid components include alkyldiphenyletherdisulfonic acids preferably with an average of 6 to 18 carbon atoms, more preferably 9 to 15, and preferable examples thereof include dodecyldiphenyletherdisulfonic acid.

Examples of the component (G2) other than those described above include organic carboxylic acid, a phosphorus oxo acid or derivative thereof.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid. Among these, phosphonic acid is particularly desirable.

Examples of phosphorous oxo acid derivatives include esters in which a hydrogen atom within the above-mentioned phosphorous oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenyl phosphonate, diphenyl phosphonate and dibenzyl phosphonate.

Examples of phosphinic acid derivatives include phosphinic acid esters and phenylphosphinic acid.

When the component (G) includes a component (G2), as the component (G2), one type of compound may be used, or two or more types may be used in combination. Among these, as the component (G2), at least one member selected from the group consisting of sulfonylimide, bis(alkylsulfonyl)imide, tris(alkylsulfonyl)methide and any of these compounds having a fluorine atom is preferable, and it is particularly preferable to use at least one of these compounds having a fluorine atom.

Further, when the resist composition contains the component (G2), the amount of the component (G2) relative to 100 parts by weight of the component (A) is preferably within a range from 0.5 to 20 parts by weight, more preferably from 1 to 15 parts by weight, and still more preferably from 1 to 10 parts by weight. When the amount of the component (G2) is at least as large as the lower limit of the above-mentioned range, the solubility of the resist film in an alkali developing solution is likely to be increased. On the other hand, when the amount of the component (G2) is no more than the upper limit of the above-mentioned range, an excellent sensitivity can be obtained.

[Acid Generator Component (B)]

The resist composition of the present invention may further include an acid generator component that is decomposed by heat or light, so as to function as acid (hereafter, frequently referred to as “component (B)”), in addition to the component (A).

Differing from the component (G), the component (13) generates acid upon exposure in step (2) described later and upon baking (PEB) in step (3). The component (B) itself does not need to exhibit acidity.

By using the component (A) and the component (B) in combination, the formation of a resist pattern in the dual-tone developing process (see Japanese Unexamined Patent Application, First Publication No. 2011-102974) can be conducted. In the dual-tone developing process, a component (B) having a high generation efficiency of acid is used. By conducting exposure, firstly, acid is generated from a component (B), and during baking (PEB), deprotection reaction proceeds to form a positive pattern.

By increasing the exposure dose, the generation of acid from the component (B) is reduced, and when the amount of the base generated from a component (A) (and the other base such as a component (D2) described later) exceeds the amount of the acid, deactivation of the acid occurs to suppress the deprotection reaction during PEB, thereby forming a negative pattern. Therefore, by conducting development, a resist pattern containing both a positive pattern and a negative pattern can be obtained.

As the component (B), there is no particular limitation, and any of the known acid generators used in conventional chemically amplified resist compositions can be used. Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators.

As an onium salt acid generator, for example, a compound consisting of an anion moiety of the aforementioned component (G1) and a sulfonium cation or iodonium cation can be used. By virtue of containing the sulfonium cation or the iodonium cation, in the dual-tone developing process, the generation efficiency of acid generated from the component (B) can be more enhanced than the generation efficiency of base generated from the component (A) with ease.

(Anion Moiety)

As the anion moiety of the onium salt acid generator, the anion moieties exemplified as anion moieties of the component (G 1) are preferable, and an anion represented by the aforementioned formula “R⁴″SO₃⁻” (in particular, an anion in which R⁴″ is “X³-Q′-Y³-”, and specific examples thereof include any one of anions represented by the aforementioned formulae (b1) to (b9)) or an anion represented by the aforementioned formula (G1a-3) is particularly preferable.

(Cation Moiety)

As the cation moiety for the onium salt-based acid generator, a sulfonium cation or an iodonium cation is preferable, and cation moieties represented by general formulas (ca-1) to (ca-4) are particularly preferable.

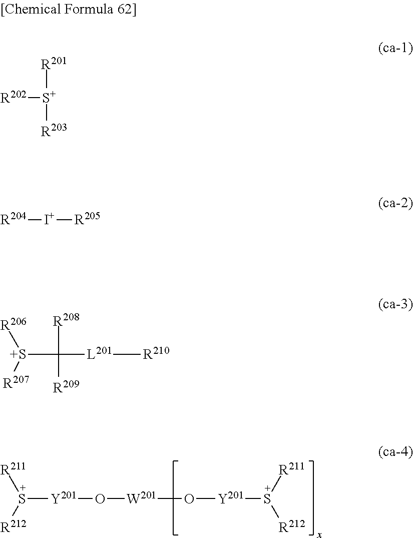

In the formulas, R²⁰¹ to R²⁰⁷ and R²¹⁰ to R²¹² each independently represents an aryl group, alkyl group or alkenyl group which may have a substituent; R²⁰¹ to R²⁰³, R²⁰⁶ and R²⁰⁷, and R²¹¹ and R²¹² may be mutually bonded to form a ring with the sulfur atom; R²⁰⁸ and R²⁰⁹ each independently represents a hydrogen atom or an alkyl group of 1 to 5 carbon atoms; L²⁰¹ represents —C(═O)— or —C(═O)O—; Y²⁰¹ each represents an arylene group, an alkylene group or an alkenylene group; x represents 1 or 2; and W²⁰¹ represents a linking group having a valency of (x+1).

In the formulas, as the aryl group for R²⁰¹ to R²⁰⁷, and R²¹⁰ to R²¹², unsubstituted aryl group of 6 to 20 carbon atoms can be mentioned, and a phenyl group or a naphthyl group is preferable.

As the alkyl group for R²⁰¹ to R²⁰⁷, and R²¹⁰ to R²¹², a linear, branched or cyclic alkyl group of 1 to 30 carbon atoms is preferable.

As the alkenyl group for R²⁰¹ to R²⁰⁷, and R²¹⁰ to R²¹², an alkenyl group of 2 to 10 carbon atoms is preferable.

As the substituent which R²⁰¹ to R²⁰⁷, and R²¹⁰ to R²¹² may have, for example, an alkyl group, a halogen atom, a halogenated alkyl group, an oxo group (═O), a cyano group, an amino group, an aryl group and substituents represented by formulas (ca1-r-1) to (ca-r-7) can be mentioned.

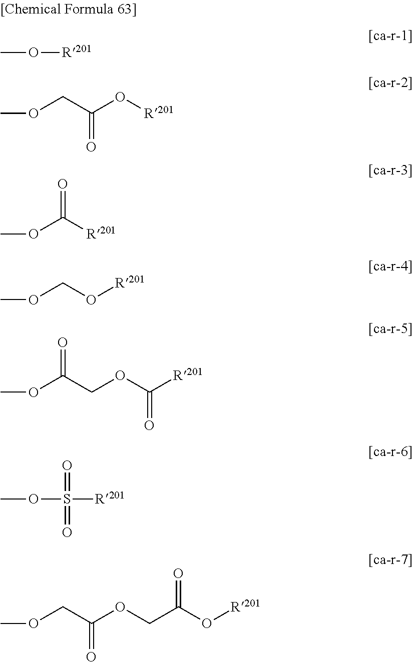

In the formulas, R′²⁰¹ each independently represents a hydrogen atom, a cyclic hydrocarbon group, a linear or branched alkyl group, or a linear or branched alkenyl group which may have a substituent.

In the formulas, a cyclic hydrocarbon group (e.g., cyclic aliphatic hydrocarbon group or an aromatic hydrocarbon group), a linear or branched alkyl group, or a linear or branched alkenyl group (e.g., linear or branched monovalent unsubstituted hydrocarbon group) for R′²⁰¹ which may have a substituent are the same groups as those described above for the hydrocarbon groups for R² which may have a substituent in the formula (a0-m).

As the aromatic hydrocarbon group for R′²⁰¹, a phenyl group or a naphthyl group is preferable.

As the cyclic aliphatic hydrocarbon group for R′²⁰¹, an adamantyl group or a norbornyl group is preferable.

The cyclic hydrocarbon group for R′²⁰¹ may contain a hetero atom like as a heterocycle, and examples thereof include a lactone-containing cyclic group represented by the aforementioned general formulas (a1-r-1) to (a2-r-7), an —SO₂— containing cyclic group represented by the aforementioned general formulas (a1-r-1) to (a5-r-4), and heterocycles shown below. In the formula, ★ represents a valence bond.

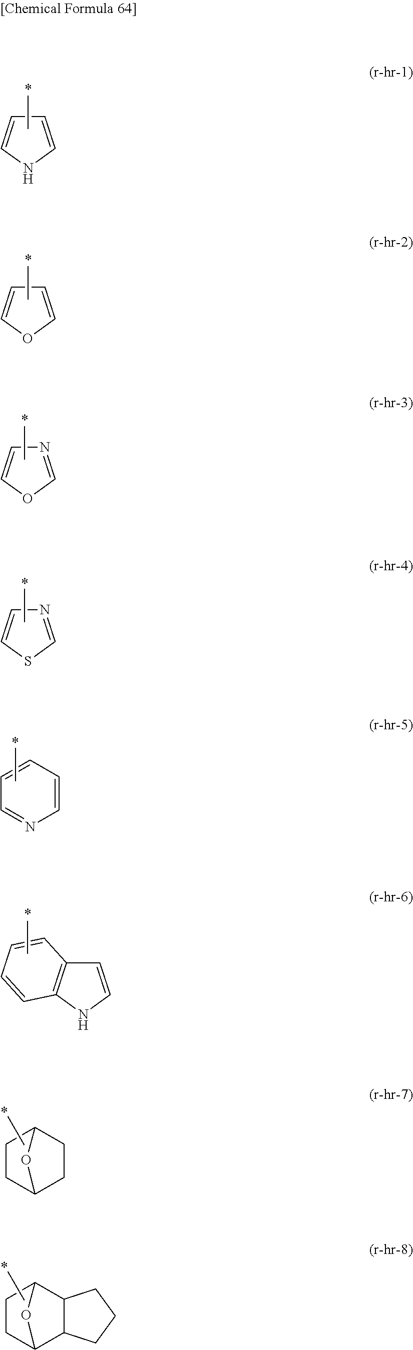

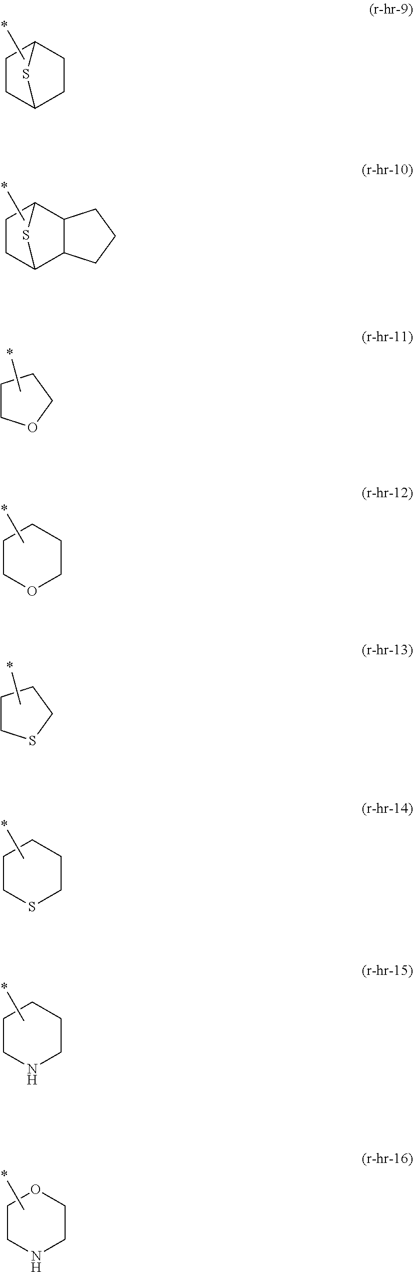

When R²⁰¹ to R²⁰⁶ and R²⁰⁷, R²¹¹ and R²¹² are mutually bonded to form a ring with the sulfur atom, these groups may be mutually bonded via a hetero atom such as a sulfur atom, an oxygen atom and a nitrogen atom, or a functional group such as a carbonyl group, —SO—, —SO₂—, —SO₃—, —COO—, —CONH— and —N(R_{N})— (in the formula, R_{N} represents an alkyl group of 1 to 5 carbon atoms).

The ring to be formed containing the sulfur atom in the skeleton thereof is preferably a 3 to 10-membered ring, and particularly preferably a 5 to 7-membered ring.

Specific examples of the ring to be formed include a thiophene ring, a thiazole ring, a benzothiophene ring, a thianthrene ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydropyranium ring.

The plurality of Y²⁰¹ each independently represents an arylene group, an alkylene group or alkenylene group, and examples thereof include groups in which one hydrogen atom has been removed from the aryl group, the alkyl group and the alkenyl group exemplified as a hydrocarbon group for R² in the formula (a0-m).

x represents 1 or 2.

W²⁰¹ represents a linking group having a valency of (x+1), that is, a divalent or trivalent linking group.

Examples of the divalent linking group for W²⁰¹ include the same divalent linking groups as those described above for Y² in the formula (a0-m). The divalent linking group may be linear, branched or cyclic, but is preferably cyclic. Among these, an arylene group having two carbonyl groups, each bonded to the terminal thereof is preferable. Specific examples thereof include a phenylene group and a naphthylene group. Of these, a phenylene group is particularly desirable.

Examples of the trivalent linking group for W²⁰¹ include a group in which one hydrogen atom has been removed from a divalent linking group, and a group in which a divalent linking group has been bonded to another divalent linking group. Examples of the divalent linking group include the same divalent linking groups as those described above for Y² in the aforementioned formula (a0-m). The trivalent linking group for W²⁰¹ is preferably an arylene group combined with three carbonyl groups.

As preferable examples of the cation moiety represented by general formula (ca-1), those represented by formulas (ca-1-1) to (ca-1-58) shown below can be given.

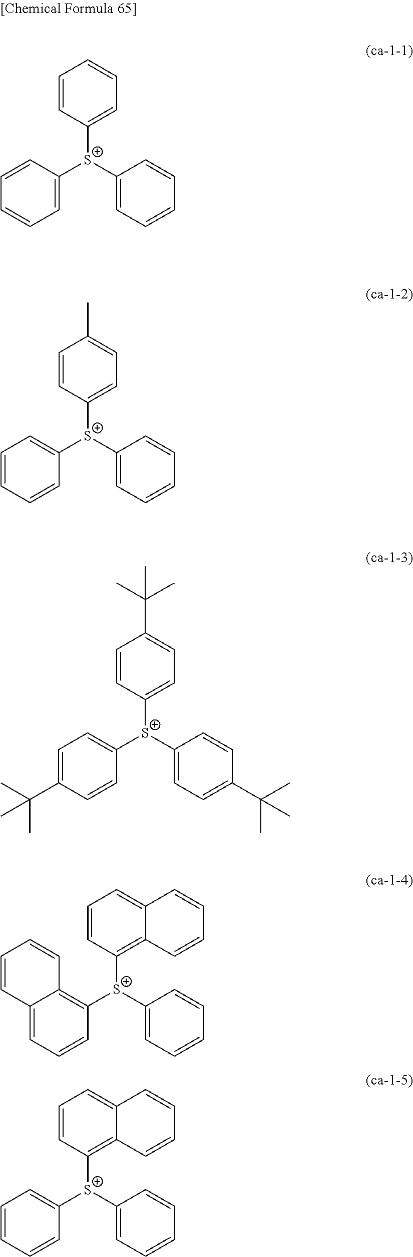

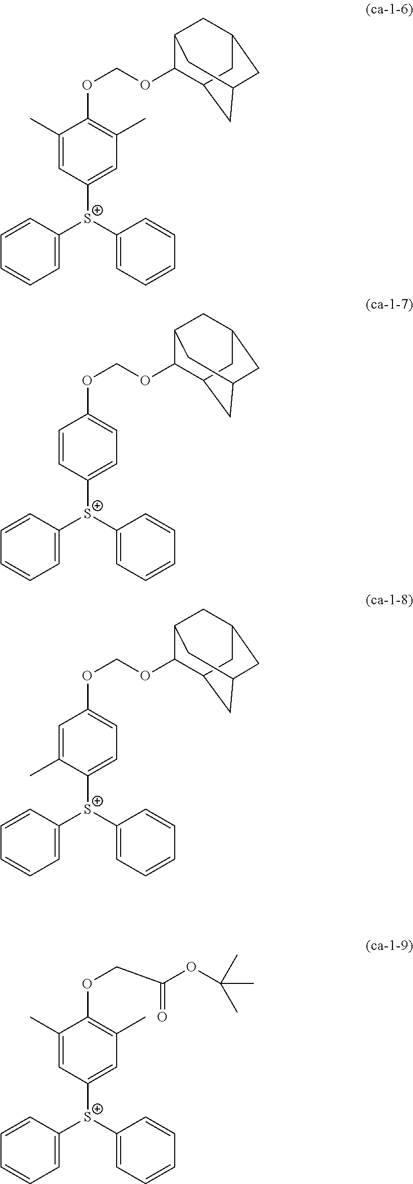

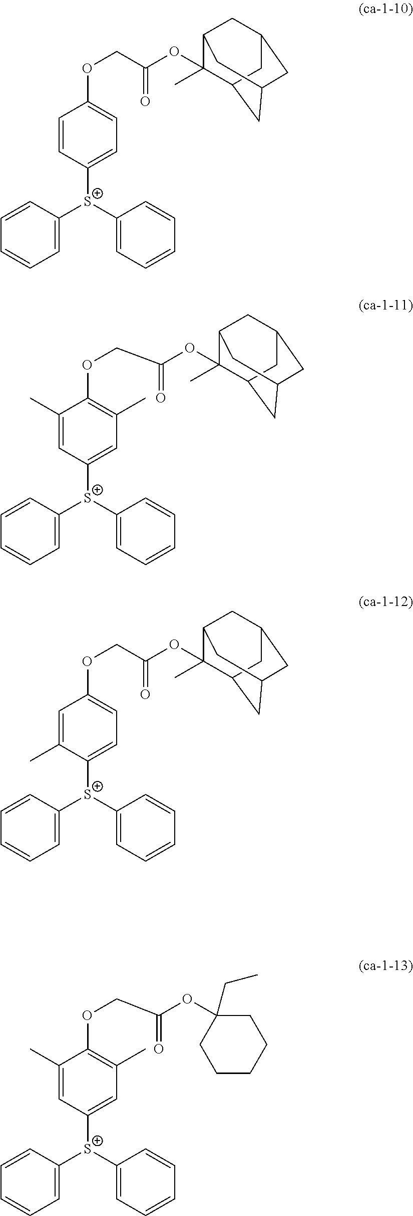

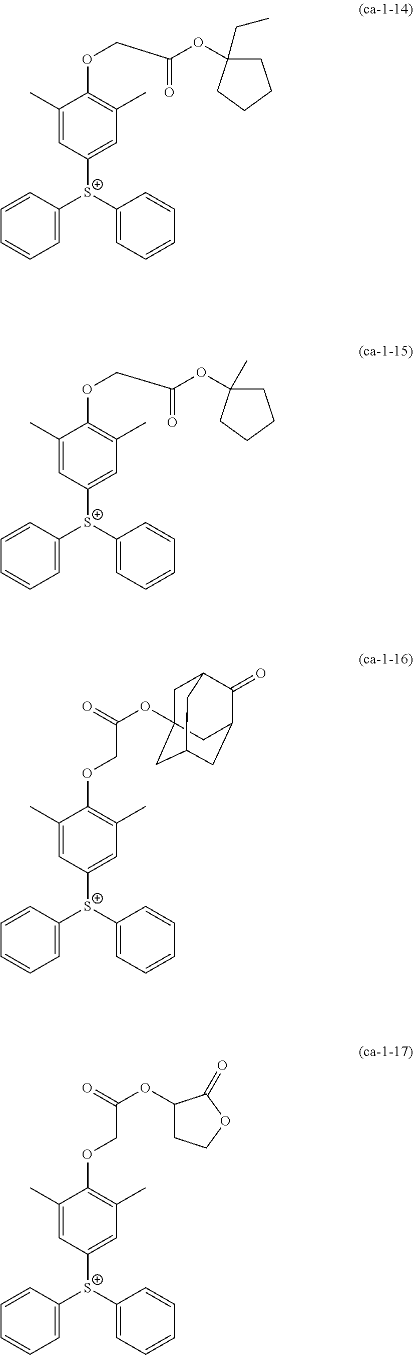

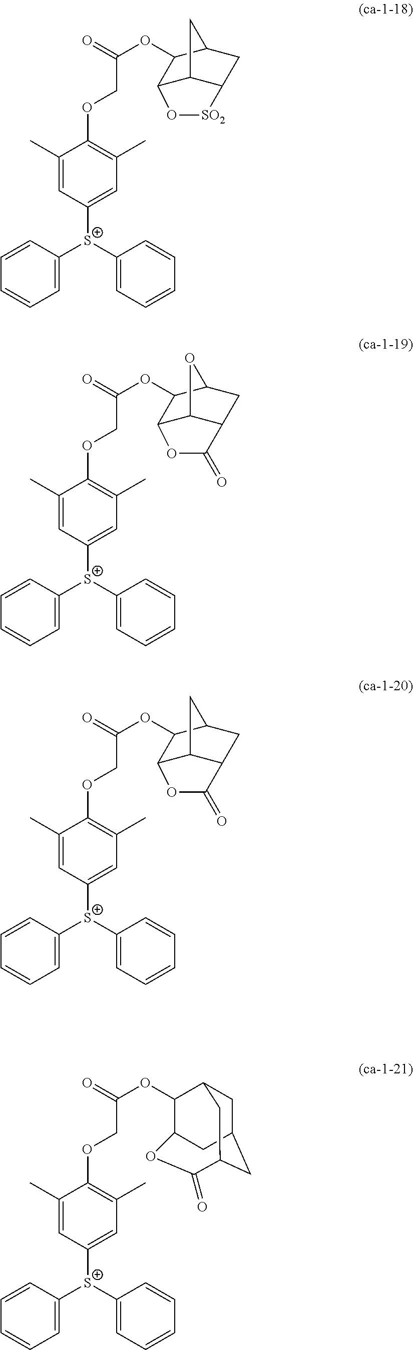

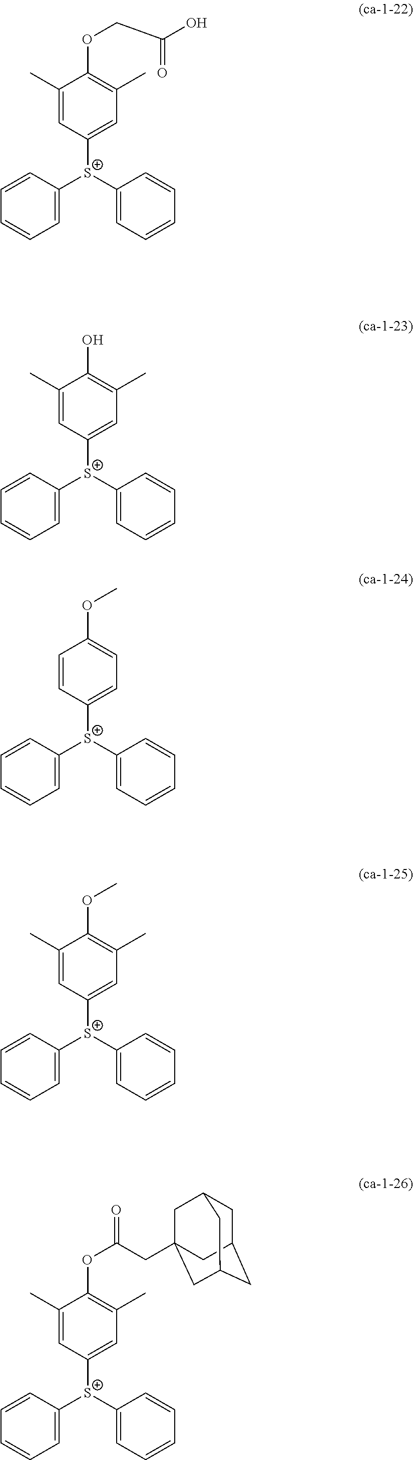

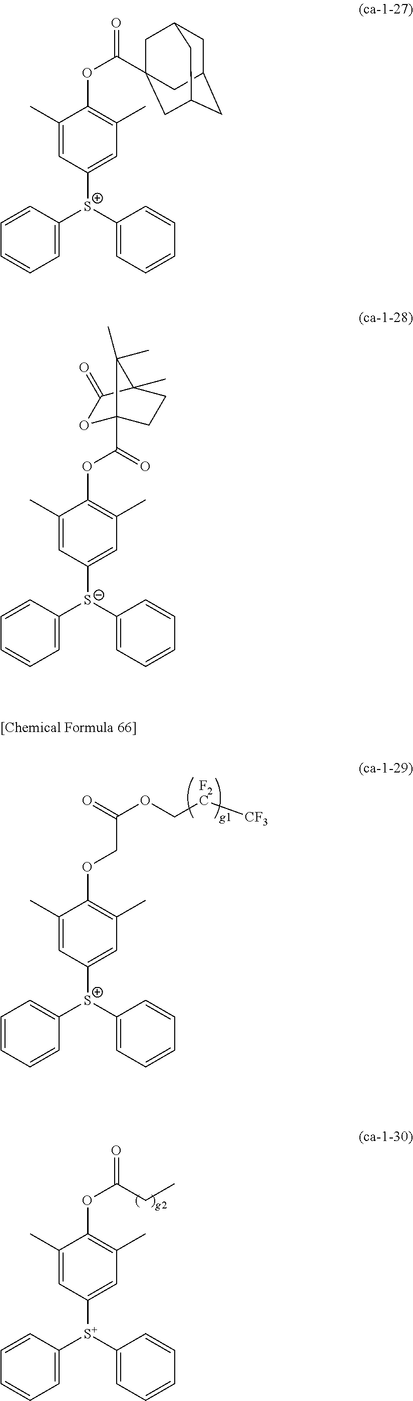

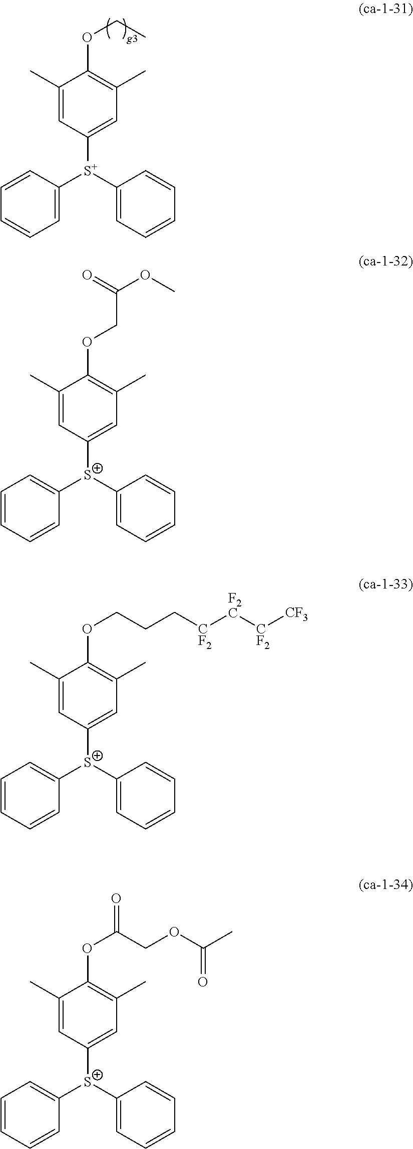

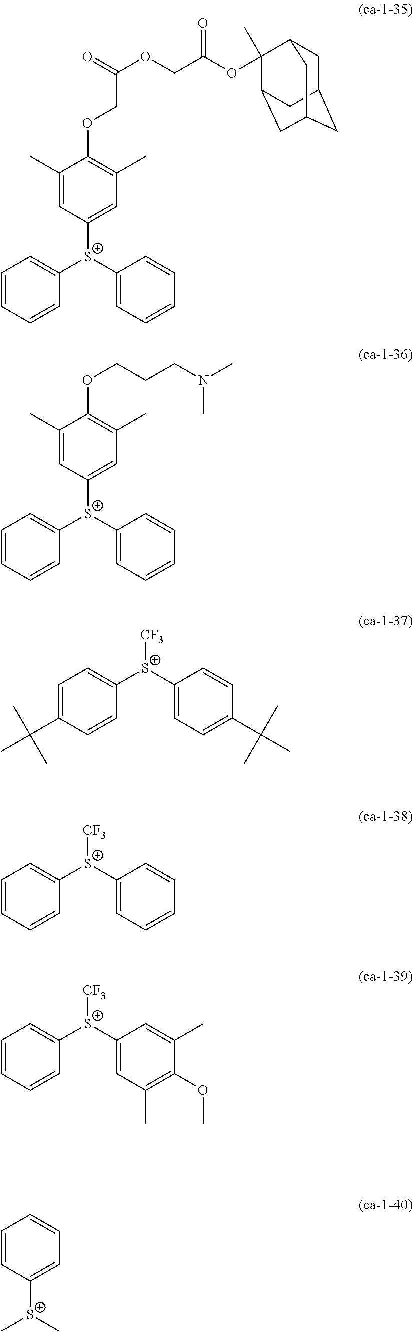

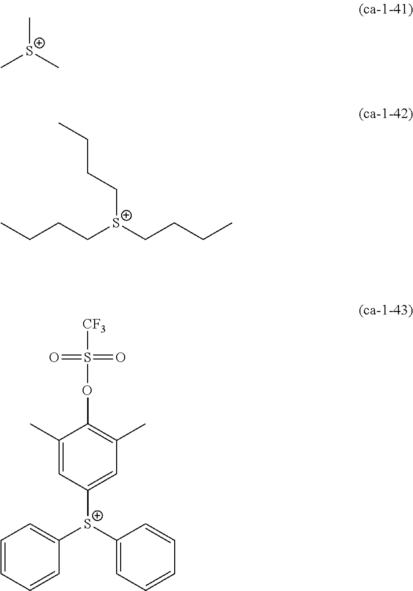

In the formulas, g1, g2 and g3 represent recurring numbers, wherein g1 represents an integer of 1 to 5, g2 is an integer of 0 to 20, and g3 is an integer of 0 to 20.

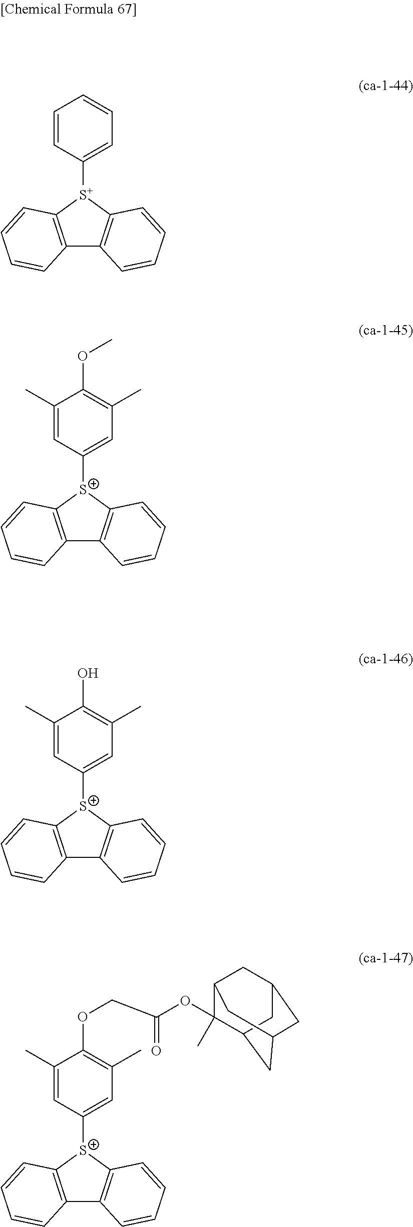

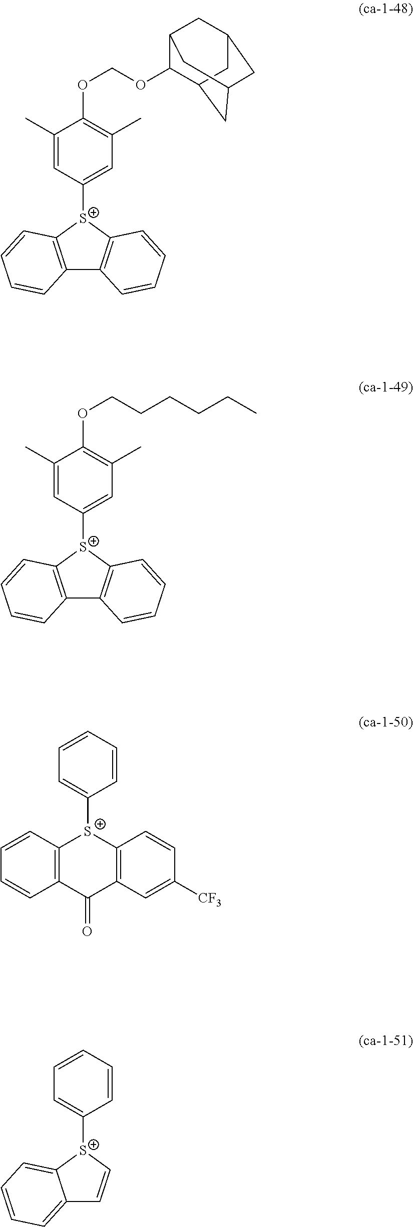

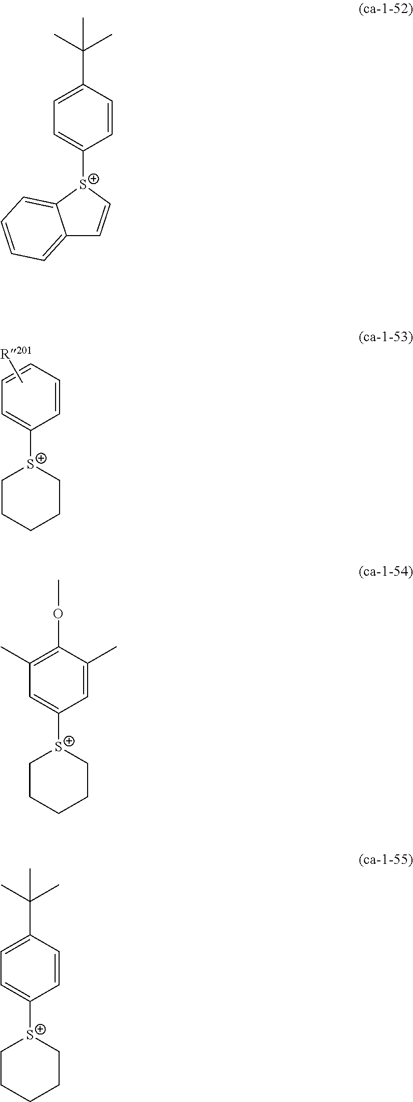

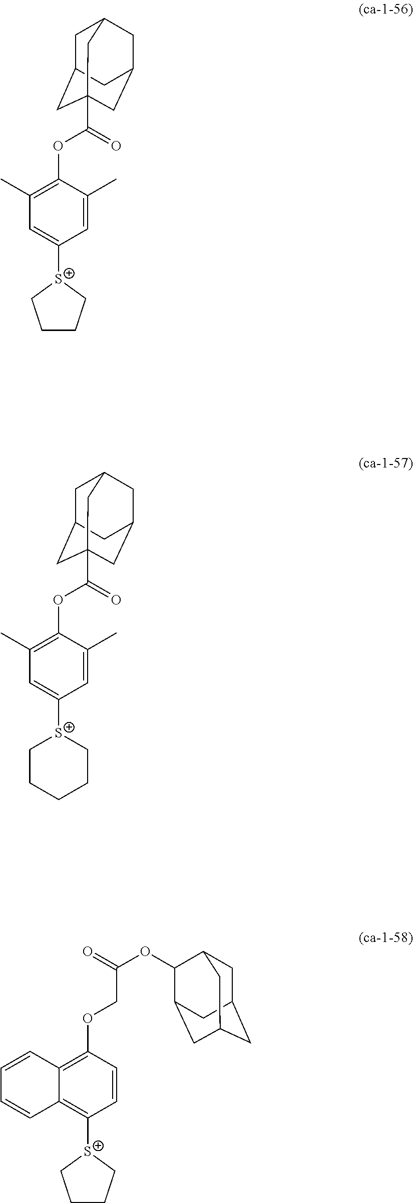

In the formulas, R″²⁰¹ represents a hydrogen atom or a substituent, and the substituent is the same groups as those which R²⁰¹ to R²⁰⁷, and R²¹⁰ to R²¹² may have.

As preferable examples of the cation moiety represented by general formula (ca-3), those represented by formulas (ca-3-1) to (ca-3-2) shown below can be given.

As preferable examples of the cation moiety represented by general formula (ca-4), those represented by formulas (ca-4-1) to (ca-4-2) shown below can be given.

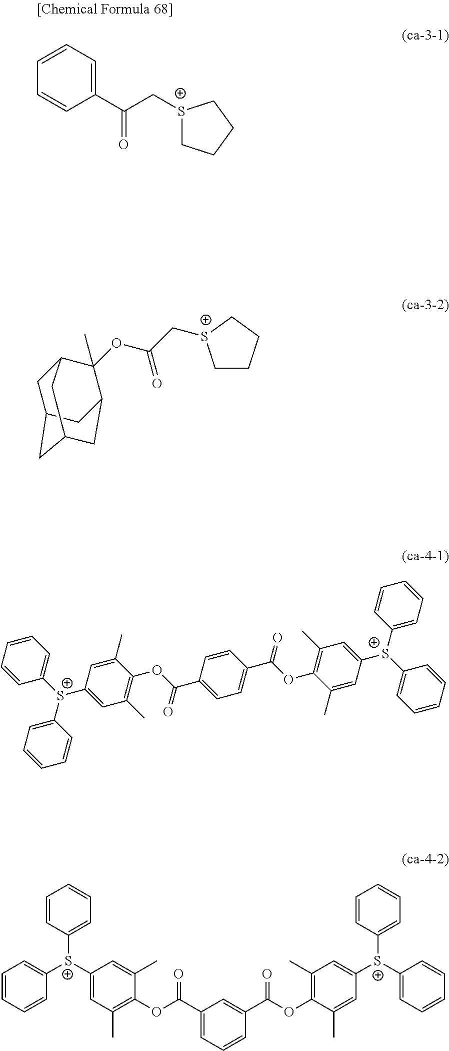

As the component (B), one type of these acid generators may be used alone, or two or more types may be used in combination.

When the resist composition of the present invention contains the component (B), the amount of the component (B) relative to 100 parts by weight of the component (A) is preferably within a range from 0.5 to 60 parts by weight, more preferably from 1 to 50 parts by weight, and still more preferably from 1 to 40 parts by weight. When the amount of the component (B) is within the above-mentioned range, formation of a resist pattern can be satisfactorily performed. Further, by virtue of the above-mentioned range, when each of the components of the resist composition are dissolved in an organic solvent, a uniform solution can be obtained and the storage stability becomes satisfactory.

[Photobase Generator Component (C)]

The resist composition of the present invention may further include a photobase generator component (hereafter, frequently referred to as “component (C)”), in addition to the component (A).

The component (C) may be any compound capable of being decomposed by irradiation of radiation (i.e., exposure) to generate a base, and examples thereof include a compound containing a carbamate group (a urethane bond), a compound containing an acyloxyimino group, an ionic compound (an anion-cation complex), and a compound containing a carbamoyloxyimino group. Among these, a compound containing a carbamate group (a urethane bond), a compound containing an acyloxyimino group, and an ionic compound (an anion-cation complex) are preferable.

Further, compounds having a ring structure within a molecule thereof are preferable, and examples thereof include compounds having a ring skeleton such as benzene, naphthalene, anthracene, xanthone, thioxanthone, anthraquinone or fluorene.

Among these, as the component (C), in terms of photodegradability, a compound represented by general formula (C1) shown below (hereafter, referred to as “component (C1)”) is particularly desirable. When the compound is irradiated by radiation (i.e., exposure), at least the bond between the nitrogen atom in the formula (C1) and the carbon atom of the carbonyl group adjacent to the nitrogen atom is cleaved, thereby generating an amine or ammonia and carbon dioxide. After the decomposition, it is preferable that the product containing —N(R⁰¹)(R⁰²) has a high boiling point. Further, in terms of suppressing diffusion during PEB, it is preferable that the product containing —N(R⁰¹)(R⁰²) has a large molecular weight or a highly bulky skeleton.

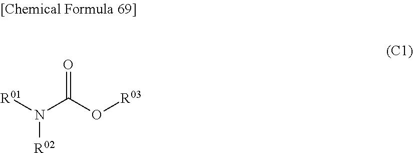

In the formula, R⁰¹ and R⁰² each independently represents a hydrogen atom or a monovalent hydrocarbon group which may contain a hetero atom, provided that R⁰¹ and R⁰² may be mutually bonded to form a cyclic group with the adjacent nitrogen atom; and R⁰³ represents a monovalent photo reactive group.

In formula (C1), the hetero atom which may be contained in the hydrocarbon group for R⁰¹ and R⁰² is an atom other than hydrogen atom and carbon atom, and examples thereof include an oxygen atom, a nitrogen atom, a sulfur atom and a halogen atom. Examples of the halogen atom include a fluorine atom, a chlorine atom, a bromine atom and an iodine atom.

The hydrocarbon group may be either an aromatic hydrocarbon group or an aliphatic hydrocarbon group, and is preferably an aliphatic hydrocarbon group.

In the formula (C1), the aromatic hydrocarbon group for R⁰¹ and R⁰² is a hydrocarbon group having an aromatic ring, and the same aromatic hydrocarbon groups as those described above for X³ in formula X³-Q′- exemplified as a substituent for R⁴″ can be mentioned.

As the aliphatic hydrocarbon groups for R⁰¹ and R⁰², the same aliphatic hydrocarbon groups as those described above for X³ in formula X³-Q′- exemplified as a substituent for R⁴″ can be mentioned.

In the aforementioned general formula (C1), R⁰¹ and R⁰² may be mutually bonded to form a cyclic group with the adjacent nitrogen atom.

The cyclic group may be either an aromatic cyclic group or an aliphatic cyclic group. When the cyclic group is an aliphatic cyclic group, it may be either saturated or unsaturated. In general, the aliphatic cyclic group is preferably saturated.

The cyclic group may have a nitrogen atom other than the nitrogen atom having R⁰¹ and R⁰² bonded thereto within the ring skeleton thereof. Further, the cyclic group may have a carbon atom or a hetero atom other than a nitrogen atom (e.g., an oxygen atom, a sulfur atom or the like) within the ring skeleton thereof.

The cyclic group may be either a monocyclic group or a polycyclic group.

When the cyclic group is monocyclic, the number of atoms constituting the skeleton of the cyclic group is preferably from 4 to 7, and more preferably 5 or 6. That is, the cyclic group is preferably a 4- to 7-membered ring, and more preferably a 5- or 6-membered ring. Specific examples of monocyclic groups include groups in which the hydrogen atom of —NH— has been removed from a heteromonocyclic group containing —NH— in the ring structure thereof, such as piperidine, pyrrolidine, morpholine, pyrrole, imidazole, pyrazole, 1,2,3-triazole, 1,2,4-triazole, tetrazole or piperazine.

When the cyclic group is polycyclic, the cyclic group is preferably bicyclic, tricyclic or tetracyclic. Further, the number of atoms constituting the skeleton of the cyclic group is preferably from 7 to 12, and more preferably from 7 to 10. Specific examples of polycyclic nitrogen-containing heterocyclic groups include groups in which the hydrogen atom of —NH— has been removed from a heteropolycyclic group containing —NH— in the ring structure thereof, such as indole, isoindole, carbazole, benzimidazole, indazole or benzotriazole.

The cyclic group may have a substituent. Examples of the substituent include the same groups as those described above for the substituent group which substitutes a hydrogen atom bonded to the aromatic ring contained in the aforementioned aromatic hydrocarbon group.

As a cyclic group formed by R⁰¹ and R⁰² mutually bonded with the adjacent nitrogen atom, a group represented by general formula (II) shown below is particularly desirable.

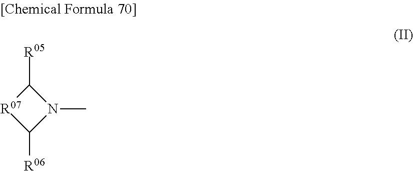

In the formula, R⁰⁵ and R⁰⁶ each independently represents a hydrogen atom or an alkyl group; R⁰⁷ represents a linear alkylene group of 1 to 3 carbon atoms which may have a carbon atom substituted with an oxygen atom or a nitrogen atom and may have a hydrogen atom substituted with a substituent.

In formula (II), as the alkyl group for R⁰⁵ and R⁰⁶, the same alkyl groups as those described above as the aliphatic hydrocarbon group for R⁰¹ and R⁰² can be mentioned, a linear or branched alkyl group is preferable, and a methyl group is particularly desirable.

Examples of the alkylene group for R⁰⁷ which may have a carbon atom substituted with an oxygen atom or a nitrogen atom include —CH₂—, —CH₂—O—, —CH₂—NH—, —CH₂—CH₂—, —CH₂—O—CH₂—, —CH₂—NH—CH₂—, —CH₂—CH₂—CH₂—, —CH₂—CH₂—O—CH₂—, and —CH₂—CH₂—NH—CH₂—.

As the substituent which substitutes a hydrogen atom in the alkylene group, the same groups as those described above for the substituent group which substitutes a hydrogen atom bonded to the aromatic ring contained in the aforementioned aromatic hydrocarbon group can be mentioned. The hydrogen atom to be substituted with a substituent may be a hydrogen atom bonded to a carbon atom, or a hydrogen atom bonded to a nitrogen atom.

In formula (C1), R⁰³ represents a monovalent photoactive group.

The term “photoactive group” refers to a group which absorbs the exposure energy of the exposure conducted in step (2) described later.

As the photoactive group, a ring-containing group is preferable, and may be either a hydrocarbon ring or a hetero ring. Preferable examples thereof include groups having a ring structure described above for R⁰¹ and R⁰², and groups having an aromatic ring. Specific examples of preferable ring skeletons for the ring-containing group include benzene, biphenyl, indene, naphthalene, fluorene, anthracene, phenanthrene, xanthone, thioxanthone and anthraquinone.

Further, these ring skeletons may have a substituent. In terms of efficiency in the generation of a base, as the substituent, a nitro group is particularly desirable.

As the component (C1), a compound represented by general formula (C1-11) or (C1-12) shown below is particularly desirable.

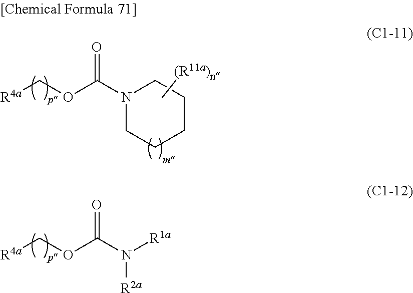

In the formulae, R^{4a} and R^{4b} each independently represents a ring skeleton selected from benzene, biphenyl, indene, naphthalene, fluorene, anthracene, phenanthrene, xanthone, thioxanthone and anthraquinone which may have a substituent; R^{1a} and R^{2a} each independently represents an alkyl group of 1 to 15 carbon atoms or a cycloalkyl group; R^{11a} represents an alkyl group of 1 to 5 carbon atoms; m″ represents 0 or 1; n″ represents 0 to 3; and each p″ independently represents 0 to 3.

In formulae (C1-11) and (C1-12), in terms of efficiency in generation of a base, it is preferable that R^{4a} and R^{4b} has a nitro group as a substituent, and it is particularly desirable that the ortho position is substituted.

In terms of suppressing the diffusion length of the generated base, it is preferable that each of R^{1a} and R^{2a} is a cycloalkyl group of 5 to 10 carbon atoms.

m″ is preferably 1. n″ is preferably 0 to 2. p″ is preferably 0 or 1.

Specific examples of the component (C1) are shown below.

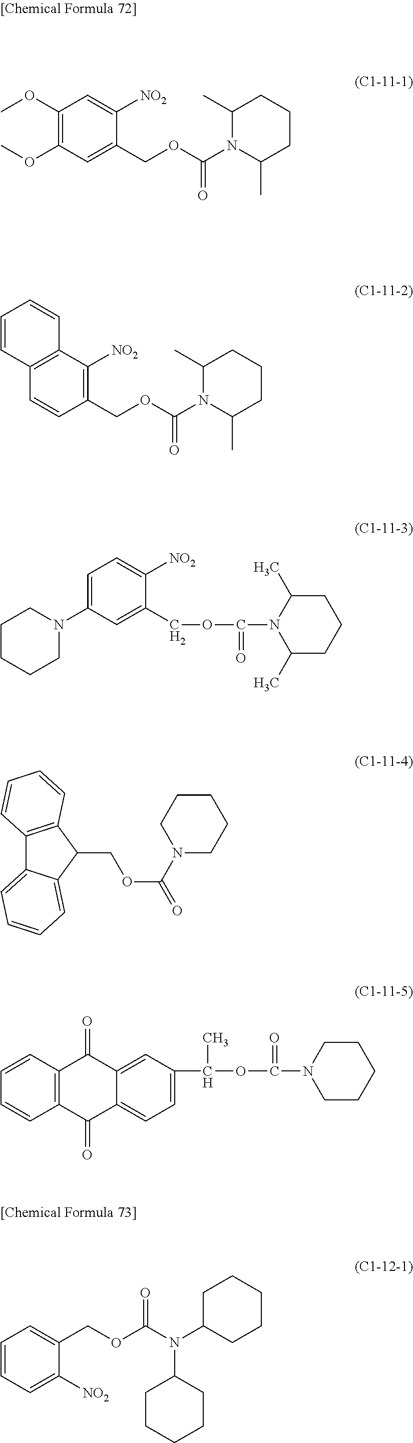 [SMILES: COc1cc(COC(=O)N2C(C)CCCC2C)c([N+](=O)[O-])cc1OC ; CC1CCCC(C)N1C(=O)OCc1ccc2ccccc2c1[N+](=O)[O-] ; CC1CCCC(C)N1C(=O)OCc1cc(N2CCCCC2)ccc1[N+](=O)[O-] ; O=C(OCC1c2ccccc2-c2ccccc21)N1CCCCC1 ; CC(OC(=O)N1CCCCC1)c1ccc2c(c1)C(=O)c1ccccc1C2=O ; O=C(OCc1ccccc1[N+](=O)[O-])N(C1CCCCC1)C1CCCCC1]

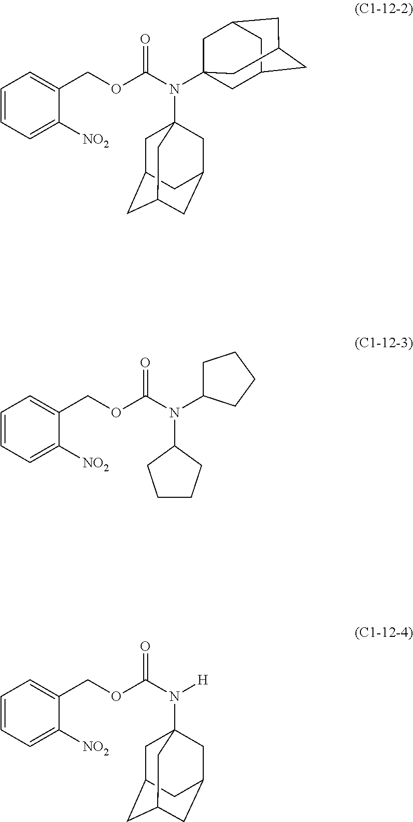 [SMILES: O=C(OCc1ccccc1[N+](=O)[O-])N(C12CC3CC(CC(C3)C1)C2)C12CC3CC(CC(C3)C1)C2 ; O=C(OCc1ccccc1[N+](=O)[O-])N(C1CCCC1)C1CCCC1 ; O=C(NC12CC3CC(CC(C3)C1)C2)OCc1ccccc1[N+](=O)[O-]]

Further, as a preferable example of the component (C), a compound represented by general formula (C2) shown below (hereafter, referred to as “component (C2)”) can also be mentioned.

After absorbing the exposure energy by the exposure conducted in step (2) described later, the component (C2) has the (—CH═CH—C(═O)—) portion isomerized to a cis isomer, and is further cyclized by heating, thereby generating a base (NHR⁰¹R⁰²).

The component (C2) is preferable in that, not only a base can be generated, but also the effect of rendering the resist composition hardly soluble in an alkali developing solution in step (4) described later can be obtained.

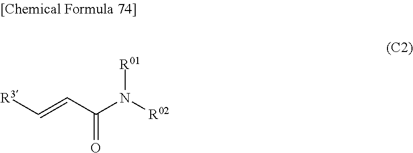

In formula (C2), R⁰¹ and R⁰² are respectively the same as defined for R⁰¹ and R⁰² in the aforementioned formula (C1); and R³′ represents an aromatic cyclic group having a hydroxy group on the ortho position.

In the aforementioned formula (C2), it is preferable that R⁰¹ and R⁰² are mutually bonded together with the adjacent nitrogen atom to form a cyclic group represented by the aforementioned formula (II). Further, R⁰¹ and R⁰² are preferably the same as defined for R^{1a} and R^{2a} in the aforementioned formula (C1-12).

As the aromatic cyclic group for R³′, the same groups having an aromatic ring as those described above for R⁰³ in the aforementioned formula (C1) can be mentioned. As the ring skeleton, benzene, biphenyl, indene, naphthalene, fluorene, anthracene and phenanthrene are preferable, and a benzene ring is more preferable.

The aromatic cyclic group for R³′ may have a substituent other than the hydroxy group on the ortho position. Examples of the substituent include a halogen atom, a hydroxy group, a mercapto group, a sulfide group, a silyl group, a silanol group, a nitro group, a nitroso group, a sulfino group, a sulfo group, a sulfonate group, a phosphino group, a phosphinyl group, a phosphono group, a phosphonate group, an amino group, an ammonio group, and a monovalent organic group such as an alkyl group.

Specific examples of the component (C2) are shown below.

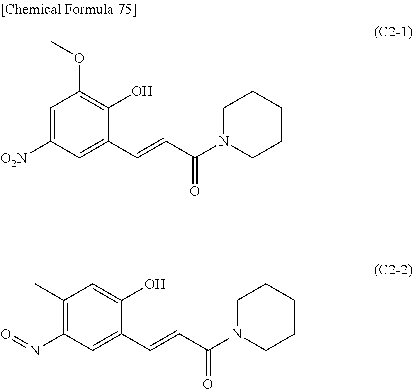 [SMILES: COc1cc([N+](=O)[O-])cc(/C=C/C(=O)N2CCCCC2)c1O ; Cc1cc(O)c(/C=C/C(=O)N2CCCCC2)cc1N=O]

Further, as a preferable example of the component (C), a compound represented by general formula (C3) shown below (hereafter, referred to as “component (C3)”) can also be mentioned.

After absorbing the exposure energy by the exposure conducted in step (2) described later, the component (C3) undergoes decarboxylation, and then reacts with water to generate amine (base).

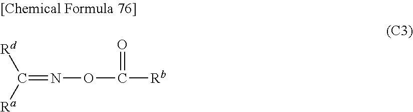

In the formula, R^{a} and R^{d} each independently represents a hydrogen atom or a hydrocarbon group of 1 to 30 carbon atoms which may have a substituent (provided that, when both R^{a} and R^{d} represent a hydrocarbon group of 1 to 30 carbon atoms which may have a substituent, R^{a} and R^{d} are mutually bonded to form a ring); and R^{b} represents an aryl group which may have a substituent or an aliphatic cyclic group which may have a substituent.

In the aforementioned formula (C3), R^{a} represents a hydrogen atom or a hydrocarbon group of 1 to 30 carbon atoms which may have a substituent.

The hydrocarbon group of 1 to 30 carbon atoms for R^{a} which may have a substituent may be either an aromatic hydrocarbon group or an aliphatic hydrocarbon group.

As the aromatic hydrocarbon groups for R^{a}, the same aromatic hydrocarbon groups as those described above for X³ in formula X³-Q′- exemplified as a substituent for R⁴″ can be mentioned.

As the aliphatic hydrocarbon groups for R^{a}, the same aliphatic hydrocarbon groups as those described above for X³ in formula X³-Q′- exemplified as a substituent for R⁴″ can be mentioned.

When R^{a} in the aforementioned formula (C3) represents a hydrocarbon group of 1 to 30 carbon atoms which may have a substituent, R^{a} may form a ring with the adjacent carbon atom. The formed ring may be either monocyclic or polycyclic. The number of carbon atoms (including the carbon atom bonded thereto) is preferably 5 to 30, and more preferably 5 to 20. Specifically, among the cyclic aliphatic hydrocarbon groups (aliphatic cyclic groups) for R^{a} described above, aliphatic cyclic groups of 5 to 30 carbon atoms can be given as examples (provided that the carbon atom bonded thereto is regarded as part of the ring).

It is preferable that R^{a} in the aforementioned formula (C3) is a hydrogen atom or a cyclic group which may have a substituent. The cyclic group may be either an aromatic hydrocarbon group which may have a substituent, or an aliphatic cyclic group which may have a substituent.

As the aliphatic cyclic group which may have a substituent, an aliphatic polycyclic group which may have a substituent is preferable. As the aliphatic polycyclic group, the aforementioned group in which one or more hydrogen atoms have been removed from a polycycloalkane, and groups represented by formulas (L2) to (L6), (S3) and (S4) are preferable.

As the aromatic hydrocarbon group which may have a substituent, a naphthyl group which may have a substituent, or a phenyl group which may have a substituent is preferable.

Examples of the aryl group for R^{b} in the aforementioned formula (C3) include the aromatic hydrocarbon groups described above for R^{a}, excluding arylalkyl groups. As the aryl group for R^{b}, a phenyl group is more preferable.

The aliphatic cyclic group for R^{b} in the aforementioned formula (C3) is the same as defined for the aliphatic cyclic group for R^{a} in the aforementioned formula (C3). The aliphatic cyclic group for R^{b} is preferably an aliphatic polycyclic group, more preferably a group in which one or more hydrogen atoms have been removed from a polycycloalkane, and most preferably a group in which one or more hydrogen atoms have been removed from adamantane.

As the substituent which the aromatic hydrocarbon group or the aliphatic cyclic group for R^{b} may have, the same substituents as those described above for R^{a} in the aforementioned formula (C3) can be mentioned.

R^{d} in the aforementioned formula (C3) is the same as defined for R^{a} in the aforementioned formula (C3).

It is preferable that R^{d} in the aforementioned formula (C3) is a cyclic group which may have a substituent.

The cyclic group may be either an aromatic hydrocarbon group which may have a substituent, or an aliphatic cyclic group which may have a substituent, and an aromatic cyclic group which may have a substituent is preferable.

As the aliphatic cyclic group which may have a substituent, an aliphatic polycyclic group which may have a substituent is preferable. As the aliphatic polycyclic group, the aforementioned group in which one or more hydrogen atoms have been removed from a polycycloalkane, and groups represented by formulas (L2) to (L6), (S3) and (S4) are preferable.

R^{d} in the aforementioned formula (C3) is more preferably a naphthyl group which may have a substituent, or a phenyl group which may have a substituent, and most preferably a phenyl group which may have a substituent.

When both R^{a} and R^{d} represent a hydrocarbon group of 1 to 30 carbon atoms which may have a substituent, R^{a} and R^{d} are mutually bonded to form a ring. The formed ring may be either monocyclic or polycyclic. The number of carbon atoms including the carbon atom having R^{a} and R^{d} bonded thereto in the aforementioned formula (C3) is preferably 5 to 30, and more preferably 5 to 20.

Specifically, among the cyclic aliphatic hydrocarbon groups (aliphatic cyclic groups) for R^{a} described above, aliphatic cyclic groups of 5 to 30 carbon atoms can be given as examples, provided that the carbon atom having R^{a} and R^{d} bonded thereto in the aforementioned formula (C3) is regarded as part of the ring.

Specific examples of the component (C3) are shown below.

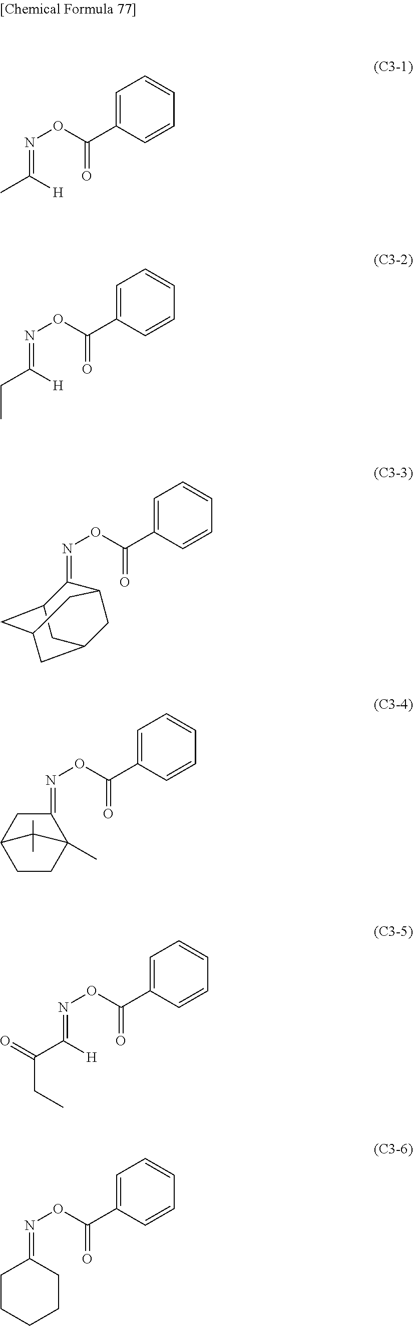 [SMILES: C/C=N/OC(=O)c1ccccc1 ; CC/C=N/OC(=O)c1ccccc1 ; O=C(ON=C1C2CC3CC(C2)CC1C3)c1ccccc1 ; CC12CCC(C/C1=N/OC(=O)c1ccccc1)C2(C)C ; CCC(=O)/C=N/OC(=O)c1ccccc1 ; O=C(ON=C1CCCCC1)c1ccccc1]

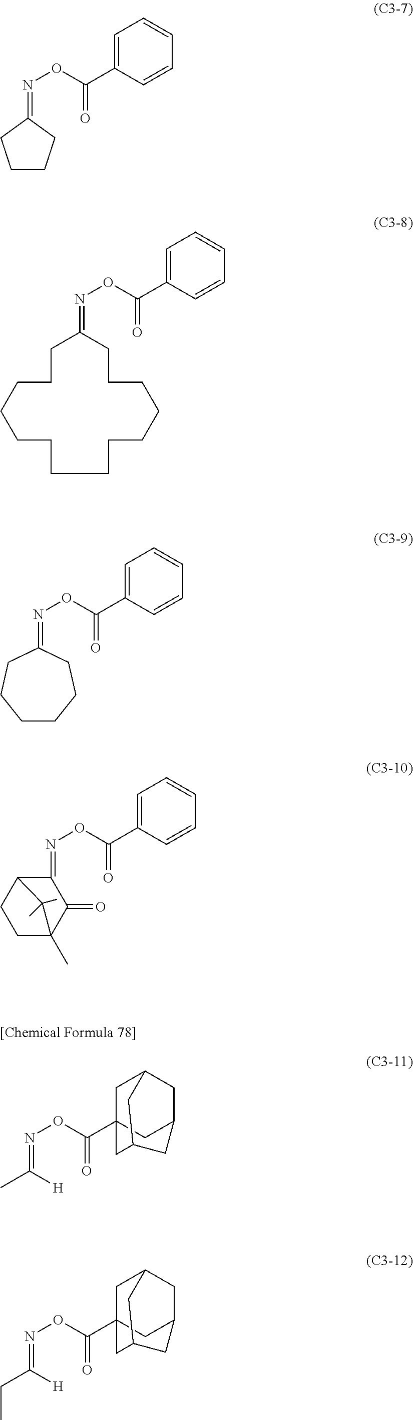 [SMILES: O=C(ON=C1CCCC1)c1ccccc1 ; O=C(ON=C1CCCCCCCCCCCCCC1)c1ccccc1 ; O=C(ON=C1CCCCCC1)c1ccccc1 ; CC12CCC(/C(=N/OC(=O)c3ccccc3)C1=O)C2(C)C ; C/C=N/OC(=O)C12CC3CC(CC(C3)C1)C2 ; CC/C=N/OC(=O)C12CC3CC(CC(C3)C1)C2]

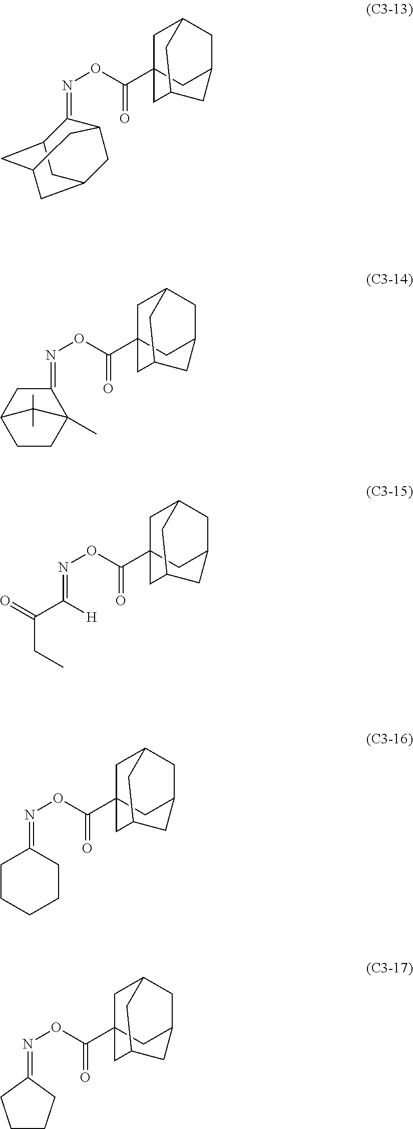 [SMILES: O=C(ON=C1C2CC3CC(C2)CC1C3)C12CC3CC(CC(C3)C1)C2 ; CC12CCC(C/C1=N/OC(=O)C13CC4CC(CC(C4)C1)C3)C2(C)C ; CCC(=O)/C=N/OC(=O)C12CC3CC(CC(C3)C1)C2 ; O=C(ON=C1CCCCC1)C12CC3CC(CC(C3)C1)C2 ; O=C(ON=C1CCCC1)C12CC3CC(CC(C3)C1)C2]

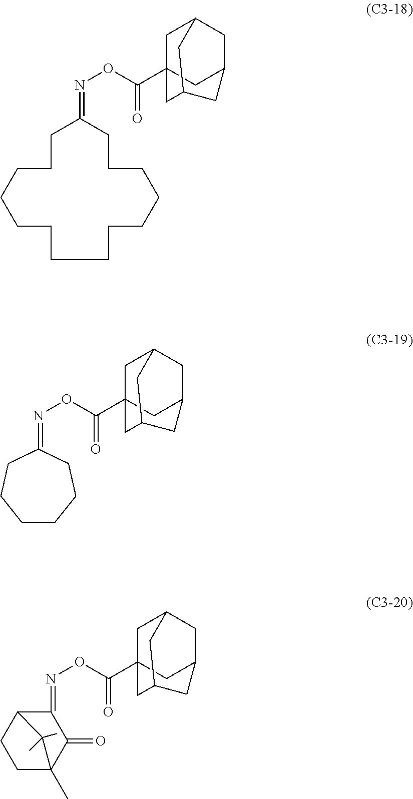 [SMILES: O=C(ON=C1CCCCCCCCCCCCCC1)C12CC3CC(CC(C3)C1)C2 ; O=C(ON=C1CCCCCC1)C12CC3CC(CC(C3)C1)C2 ; CC12CCC(/C(=N/OC(=O)C34CC5CC(CC(C5)C3)C4)C1=O)C2(C)C]

Further, as a preferable example of the component (C), the following compounds (C4) containing an acyloxyimino group can also be mentioned.

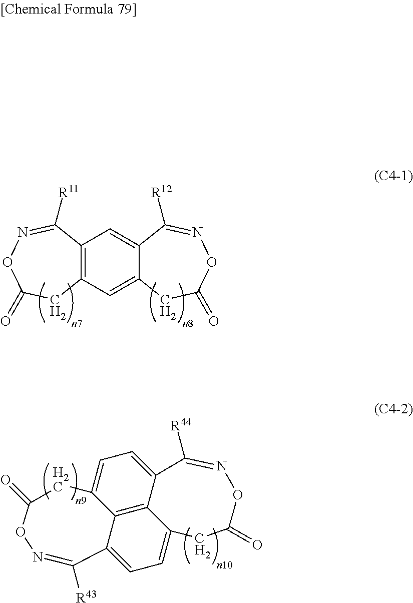

In the formulae, R¹¹, R¹², R⁴³ and R⁴⁴ each independently represents a hydrogen atom or an alkyl group of 1 to 5 carbon atoms; and n7 to n10 each independently represents 0 to 3.

Furthermore, as the component (C), other than the above examples, any of the known photo-base generators used in conventional chemically amplified resist compositions can be used.

Examples of such photo-base generators include ion-type photo-base generators (anion-cation complexes); triphenylsulfonium compounds; triphenylmethanol; photoactive carbamates, such as benzylcarbamate and benzoin carbamate; amides, such as o-carbamoylhydroxylamide, o-carbamoyloxime, aromatic sulfoneamide, alphalactum and N-(2-allylethynyl)amide; oximeesters; α-aminoacetophenone; cobalt complexes; and those exemplified in Japanese Unexamined Patent Application, First Publication No. 2007-279493.

As the component (C), one type of organic compound may be used alone, or two or more types may be used in combination.

Among the above examples, as the component (C), a component (C1) is preferable, at least one member selected from the group consisting of compounds represented by the aforementioned general formula (C1-11) or (C1-12) is more preferable, and a compound represented by general formula (C1-12) is particularly preferable.

When the resist composition of the present invention contains the component (C), the amount of the component (C) relative to 100 parts by weight of the component (A) is preferably within a range from 0.05 to 50 parts by weight, more preferably from 1 to 30 parts by weight, and particularly preferably from 5 to 20 parts by weight.

When the amount of the component (C) is at least as large as the lower limit of the above-mentioned range, the film retentiveness of the resist film at exposed portions becomes excellent, and the resolution of the formed resist pattern is further improved. On the other hand, when the amount of the component (C) is no more than the upper limit of the above-mentioned range, the transparency of the resist film can be maintained.

[Acidic Amplifier Component (H)]

The resist composition of the present invention may further include an acidic amplifier component (hereafter, frequently referred to as “component (H)”), in addition to the component (A).

The component (H) is decomposed by an acid to generate a free acid, and the free acid further decomposes the component (H) to further generate free acid. In this manner, by the action of acid, the component (H) is serially decomposed, and generates many free acid molecules.

The component (H) is not particularly limited, as long as it is decomposable by the action of an acid, and is capable of further generating acid to self-catalytically amplify acid. Preferable examples of the component (H) include compounds having a bridged-carbon ring skeleton structure.

Here, the term “compound having a bridged-carbon ring skeleton structure” refers to a compound which has a structure (hereafter, frequently referred to as “bridged carbon ring”) of a bridging bond formed by a plurality of carbon rings in a molecule thereof.

By virtue of the compound having a bridged-carbon ring skeleton structure having a bridging bond, the molecule becomes rigid, and the thermal stability of the compound is improved.

The number of carbon rings is preferably from 2 to 6, and more preferably 2 or 3.

The bridged carbon ring may have part or all of the hydrogen atoms substituted with an alkyl group, an alkoxy group or the like. The alkyl group preferably has 1 to 6 carbon atoms, more preferably 1 to 3, and specific examples of the alkyl group include a methyl group, an ethyl group and a propyl group. The alkoxy group preferably has 1 to 6 carbon atoms, more preferably 1 to 3, and specific examples of the alkoxy group include a methoxy group and an ethoxy group. The bridged carbon ring may have an unsaturated bond such as a double bond.

In the present invention, it is most preferable that the bridged carbon ring has, on the ring thereof, a hydroxy group and a sulfonate group represented by general formula (Hs) shown below bonded to the carbon atom adjacent to the carbon atom having the hydroxy group bonded thereto.

[Chemical Formula 80]

—OSO₂—R⁰ (Hs)

In the formula, R⁰ represents an aliphatic group, an aromatic group or a heterocyclic group.

In the aforementioned formula (Hs), R⁰ represents an aliphatic group, an aromatic group or a heterocyclic group.

Examples of the aliphatic group for R⁰ include a chain-like or cyclic alkyl group or an alkenyl group, and preferably has 1 to 12 carbon atoms, more preferably 1 to 10 carbon atoms.

The aromatic group may be either a monocyclic group or a polycyclic group, and specific examples thereof include aryl groups.

The heterocyclic group may be a monocyclic group or a polycyclic group, and specific examples thereof include groups which are derived from various conventional heterocyclic compounds.

The aforementioned aliphatic group, aromatic group and heterocyclic group may have a substituent, and examples of the substituent include a halogen atom, an alkyl group, an alkoxy group, an amino group, a substituted amino group and an oxygen atom (═O).

Specific examples of the aforementioned aliphatic group and the aromatic group include a methyl group, an ethyl group, a propyl group, a butyl group, an acyl group, a hexyl group, a vinyl group, a propylene group, an allyl group, a cyclohexyl group, a cyclooctyl group, a bicyclohydrocarbon group, a tricyclohydrocarbon group, a phenyl group, a tolyl group, a benzyl group, a phenethyl group, a naphthyl group, a naphthylmethyl group, and substitution products thereof.

Examples of the heterocyclic group include groups derived from various heterocyclic groups, such as a 5-membered ring compound containing one hetero atom or a condensed ring compound thereof (e.g., furan, thiophene, pyrrole, benzofuran, thionaphthene, indole or carbazole); a 5-membered ring compound containing two hetero atoms or a condensed ring compound thereof (e.g., oxazole, thiazole or pyrazole); a 6-membered ring compound containing one hetero atom or a condensed ring compound thereof (e.g., pyran, pyrone, coumarin, pyridine, quinoline, isoquinoline or acridine); and a 6-membered ring compound containing two hetero atoms or a condensed ring compound thereof (e.g., pyridazine, pyrimidine, pyrazine or phthalazine).

In the present invention, when the component (H) has, on the bridged carbon ring, a hydroxy group and a sulfonate group represented by the aforementioned general formula (Hs), such a component (H) is decomposed by the action of an acid to generate a new acid (R⁰SO₃H).

In this manner, one acid increases in one reaction, and the reaction is accelerated as the reaction proceeds, thereby serially decomposing the component (H).

In such a case, the strength of the generated acid in terms of the acid dissociation constant (pKa) is preferably 3 or less, and particularly preferably 2 or less. When the pKa is 3 or less, the generated acid itself is likely to induce the self-decomposition. On the other hand, when the generated acid has a weaker strength, it becomes difficult to induce the self-decomposition.

Examples of the free acid (R⁰SO₃H) generated by the above reaction include methanesulfonic acid, ethanesulfonic acid, propanesulfonic acid, butanesulfonic acid, pentanesulfonic acid, hexanesulfonic acid, heptanesulfonic acid, octanesulfonic acid, cyclohexanesulfonic acid, camphorsulfonic acid, trifluoromethanesulfonic acid, 2,2,2-trifluoroethanesulfonic acid, benzenesulfonic acid, p-toluenesulfonic acid, p-bromobenzenesulfonic acid, p-nitrobenzenesulfonic acid, 2-thiophenesulfonic acid, 1-naphthalenesulfonic acid and 2-naphthalenesulfonic acid.

Specific examples of the component (H) include compounds represented by general formulae (H1) to (H4) shown below (hereafter, the compounds corresponding to general formulae are respectively referred to as “compounds (H1) to (H4)”).

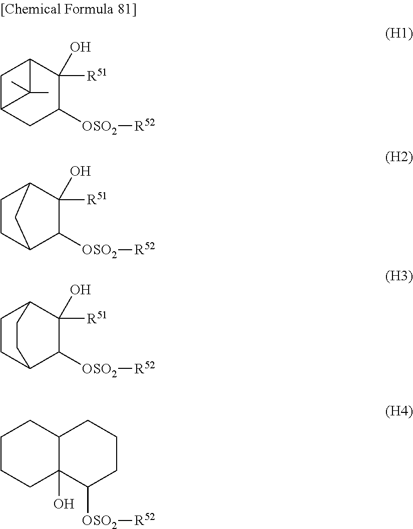

In the formulae, R⁵¹ represents a hydrogen atom, an aliphatic group or an aromatic group; and R⁵² represents an aliphatic group, an aromatic group or a heterocyclic group.

In the aforementioned general formulae (H1) to (H3), R⁵¹ represents a hydrogen atom, an aliphatic group or an aromatic group. The aliphatic group and the aromatic group for R⁵¹ is the same as defined for the aliphatic group and the aromatic group for the aforementioned R⁰. As R⁵¹, an aliphatic group or an aromatic group is preferable, an aliphatic group is more preferable, a lower alkyl group is particularly preferable, and a methyl group is most preferable.

In the aforementioned general formulae (H1) to (H4), R⁵² represents an aliphatic group, an aromatic group or a heterocyclic group, and is the same as defined for R⁰. As R⁵², an aliphatic group or an aromatic group is preferable, and an aliphatic group is more preferable.

With respect to the compounds (H1) to (H4), the compound (H1) has a bridge bond on the 1st and 3rd positions of the bicyclo compound, the compounds (H2) and (H3) has a bridge bond on the 1st and 4th positions of the bicyclo compound, and the compound (H4) has a bridge bond on the 1st and 6th positions of the bicyclo compound (decarine).

Therefore, in the compounds (H1) to (H4), the conformation change of the cyclohexane ring is greatly suppressed, and hence, the ring structure exhibits rigidity.

As the component (H), for example, a compound in which the bridged carbon has, on the ring thereof, a hydroxy group and a sulfonate group represented by general formula (Hs) bonded to the carbon atom adjacent to the carbon atom having the hydroxy group bonded thereto (such as the compounds (H1) to (H4)) can be readily synthesized by reacting a diol compound with a halide of the sulfonic acid. The diol compound has two isomers, namely, cis-isomer and trans-isomer, but the cis-isomer is thermally stable, and is therefore preferably used. Further, such a compound can be stably stored as long as an acid does not coexist.

Specific examples of preferable component (H) are shown below.

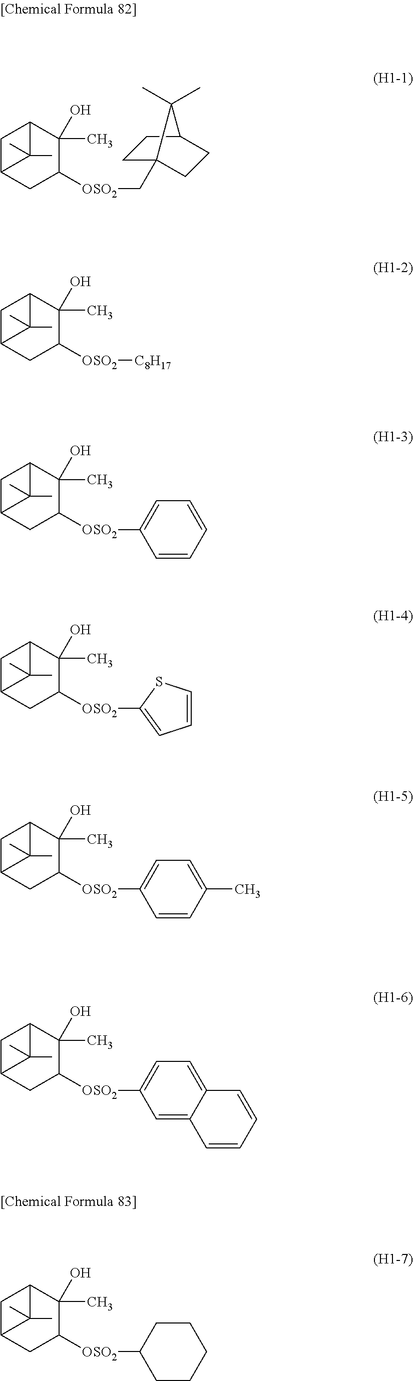

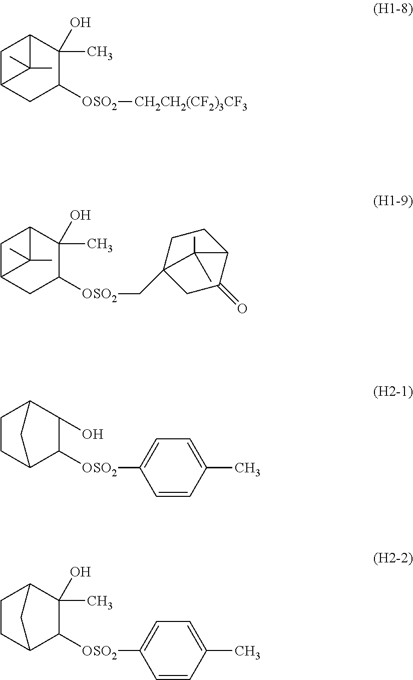

Among the above examples, as the component (H), in terms of the effects of the present invention, the compound (H1) or the compound (H2) is preferable, and the compound (H1) is more preferable. More specifically, it is preferable to use at least one member selected from the group consisting of compounds represented by chemical formulae (H1-1) to (H1-9), and it is most preferable to use a compound represented by chemical formula (H1-9).

As the component (H), one type of compound may be used, or two or more types may be used in combination.

When the resist composition of the present invention contains the component (H), the amount of the component (H) relative to 100 parts by weight of the component (A) is preferably within a range from 0.1 to 30 parts by weight, and more preferably from 1 to 20 parts by weight. When the amount of the component (H) is at least as large as the lower limit of the above-mentioned range, the resolution is improved. On the other hand, when the amount of the component (H) is no more than the upper limit of the above-mentioned range, the sensitivity is improved.

When the component (H) is used, the mixing ratio of the component (H) to the component (J) in terms of molar ratio is preferably from 9:1 to 1:9, more preferably from 9:1 to 5:5, and particularly preferably from 9:1 to 6:4.

When the ratio of the component (H) is at least as large as the lower limit of the above-mentioned range, the resolution is improved. On the other hand, when the ratio of the component (H) is no more than the upper limit of the above-mentioned range, the sensitivity is improved.

[Fluorine Additive; Component (F)]

The resist composition of the present invention may include a fluorine additive (hereafter, referred to as “component (F)”) may be blended for imparting water repellency to the resist film, in addition to the component (A).

As the component (F), for example, a fluorine-containing polymeric compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, and Japanese Unexamined Patent Application, First Publication No. 2011-128226 can be used.

Specific examples of the component (F) include polymers having a structural unit (f1) represented by general formula (f1-1) shown below. As such polymer, a polymer (homopolymer) consisting of a structural unit (f1); a copolymer of a structural unit represented by formula (f1-1) shown below and the aforementioned structural unit (a1); and a copolymer of a structural unit represented by the formula (f1-1) shown below, a structural unit derived from acrylic acid or methacrylic acid and the aforementioned structural unit (a1) are preferable.

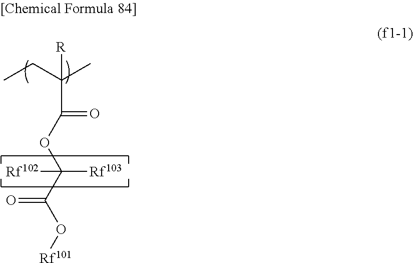

In the formula, R represents the same as defined above; Rf¹⁰² and Rf¹⁰³ each independently represents a hydrogen atom, a halogen atom, an alkyl group of 1 to 5 carbon atoms or a halogenated alkyl group of 1 to 5 carbon atoms; nf¹ an integer of 1 to 5 carbon atoms, provided that, when nf¹ are 2 or more, the plurality of Rf¹⁰⁵ and Rf¹⁰³ may be the same or different from each other; and Rf¹⁰¹ represents an organic group containing a fluorine atom.

In formula (f1-1), R is the same as defined above. As R, a hydrogen atom or a methyl group is preferable.

In formula (f1-1), examples of the halogen atom for Rf¹⁰² and Rf¹⁰³ include a fluorine atom, a chlorine atom, a bromine atom and an iodine atom, and a fluorine atom is particularly desirable. Examples of the alkyl group of 1 to 5 carbon atoms for Rf¹⁰² and Rf¹⁰³ include the same alkyl group of 1 to 5 carbon atoms for R defined above, and a methyl group or an ethyl group is preferable. Specific examples of the halogenated alkyl group of 1 to 5 carbon atoms represented by Rf¹⁰² and Rf¹⁰³ include groups in which part or all of the hydrogen atoms of the aforementioned alkyl groups of 1 to 5 carbon atoms have been substituted with halogen atoms. Examples of the halogen atom include a fluorine atom, a chlorine atom, a bromine atom and an iodine atom, and a fluorine atom is particularly desirable. Among these, as Rf¹⁰² and Rf¹⁰³, a hydrogen atom, a fluorine atom or an alkyl group of 1 to 5 carbon atoms is preferable, and a hydrogen atom, a fluorine atom, a methyl group or an ethyl group is more preferable.

In formula (f1-1), nf¹ represents an integer of 1 to 5, preferably an integer of 1 to 3, and more preferably 1 or 2.

In formula (f1-1), Rf¹⁰¹ represents an organic group containing a fluorine atom, and is preferably a hydrocarbon group containing a fluorine atom.

The hydrocarbon group containing a fluorine atom may be linear, branched or cyclic, and preferably has 1 to 20 carbon atoms, more preferably 1 to 15 carbon atoms, and particularly preferably 1 to 10 carbon atoms.

It is preferable that the hydrocarbon group having a fluorine atom has 25% or more of the hydrogen atoms within the hydrocarbon group fluorinated, more preferably 50% or more, and most preferably 60% or more, as the hydrophobicity of the resist film during immersion exposure is enhanced.

Among these as for Rf¹⁰¹, a fluorinated hydrocarbon group of 1 to 5 carbon atoms is particularly preferable, and a methyl group, —CH₂—CF₃, —CH₂—CF₂—CF₃, —CH(CF₃)₂, —CH₂—CH₂—CF₃, and —CH₂—CH₂—CF₂—CF₂—CF₂—CF₃ are most preferable.

The weight average molecular weight (Mw) (the polystyrene equivalent value determined by gel permeation chromatography) of the component (F) is preferably 1,000 to 50,000, more preferably 5,000 to 40,000, and most preferably 10,000 to 30,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (F) is preferably 1.0 to 5.0, more preferably 1.0 to 3.0, and most preferably 1.2 to 2.5.

As the component (F), one type may be used alone, or two or more types may be used in combination.

When the resist composition of the present invention contains the component (F), the amount of the component (F) relative to 100 parts by weight of the component (A) is preferably within a range from 0.5 to 10 parts by weight.

[Basic Compound Component (D)]

The resist composition of the present invention may further include a basic compound component (hereafter, frequently referred to as “component (D)”), in addition to the component (A).

The component (D) functions as an acid diffusion control agent, i.e., a quencher which traps the acid generated from the component (13) upon exposure or the component (G). In the present invention, a “basic compound” refers to a compound which is basic relative to the component (G) or component (B).

In the present invention, the component (D) may be a basic compound (D1) (hereafter, referred to as “component (D1)”) which has a cation moiety and an anion moiety, or a basic compound (D2) (hereafter, referred to as “component (D2)”) which does not fall under the definition of component (D1).

(Component (D1))

In the case where the resist composition of the present invention contains a component (B) in addition to the component (A), by virtue of the resist composition further containing a component (D1), when a resist pattern is formed by the aforementioned dual-tone developing process, the contrast of the positive region (the portion which exhibits increased solubility in an alkali developing solution) can be improved.

The component (D1) is not particularly limited, as long as it is basic relative to the components (G) and (B). As the component (D1), at least one member selected from the group consisting of a compound (d1-1) represented by general formula (d1-1) shown below (hereafter, referred to as “component (d1-1)”), a compound (d1-2) represented by general formula (d1-2) shown below (hereafter, referred to as “component (d1-2)”) and a compound (d1-3) represented by general formula (d1-3) shown below (hereafter, referred to as “component (d1-3)”) are preferable.

The components (d1-1) to (d1-3) do not function as a quencher at exposed portions, but functions as a quencher at unexposed portions.

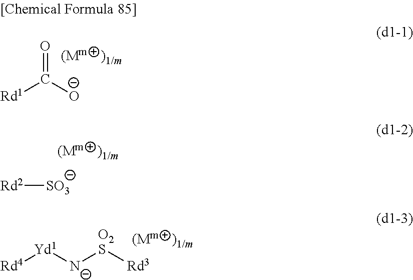

In the formulas, Rd¹ and Rd² represents a hydrocarbon group which may have a substituent; provided that in Rd² in the formula (d1-2), the carbon adjacent to the S atom has no fluorine atom as a substituent; Rd³ represents a hydrocarbon group containing a fluorine atom; Rd⁴ represents an alkyl group, an alkoxy group, —O—C(═O)—C(Rd⁴²)═CH₂ (wherein Rd⁴² represents a hydrogen atom, an alkyl group of 1 to 5 carbon atoms or a halogenated alkyl group of 1 to 5 carbon atoms) or —O—C(═O)—Rd⁴³ (wherein Rd⁴³ represents a hydrocarbon group); Yd¹ represents an alkylene group or an arylene group; and M^{m+} each independently represents an organic cation having a valency of m.

{Component (d1-1)}

Anion Moiety

In formula (d1-1), Rd represents a hydrocarbon group which may have a substituent.

As the hydrocarbon group for Rd¹ which may have a substituent, the same groups as those described above for the hydrocarbon group which may have a substituent for R² in the aforementioned formula (a0-m) can be mentioned.

Among these, as for Rd¹, an aromatic hydrocarbon group which may have a substituent or an aliphatic cyclic group which may have a substituent is preferable, and a phenyl group or a naphthyl group which may have a substituent, or a group in which one or more hydrogen atoms have been removed from a polycycloalkane such as adamantane, norbornane, isobornane, tricyclodecane or tetracyclododecane is more preferable.

As the hydrocarbon group for Rd¹ which may have a substituent, a linear. branched or alicyclic alkyl group or a fluorinated alkyl group is also preferable.

The linear, branched or alicyclic alkyl group for Rd¹ preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl or a decyl group; a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group or a 4-methylpentyl group; and an alicyclic alkyl group such as a norbornyl group and an adamantyl group.

The fluorinated alkyl group for Rd¹ may be either chain-like or cyclic, but is preferably linear or branched.

The fluorinated alkyl group preferably has 1 to 11 carbon atoms, more preferably 1 to 8, and still more preferably 1 to 4. Specific examples include a group in which part or all of the hydrogen atoms constituting a linear alkyl group (such as a methyl group, an ethyl group, a propyl group, a butyl group, a pentyl group, a hexyl group, a heptyl group, an octyl group, a nonyl group or a decyl group) have been substituted with fluorine atom(s), and a group in which part or all of the hydrogen atoms constituting a branched alkyl group (such as a 1-methylethyl group, a 1-methylpropyl group, a 2-methylpropyl group, a 1-methylbutyl group, a 2-methylbutyl group or a 3-methylbutyl group) have been substituted with fluorine atom(s).

The fluorinated alkyl group for Rd¹ may contain an atom other than fluorine. Examples of the atom other than fluorine include an oxygen atom, a carbon atom, a hydrogen atom, a sulfur atom and a nitrogen atom.

Among these, as the fluorinated alkyl group for Rd¹, a group in which part or all of the hydrogen atoms constituting a linear alkyl group have been substituted with fluorine atom(s) is preferable, and a group in which all of the hydrogen atoms constituting a linear alkyl group have been substituted with fluorine atoms (i.e., a perfluoroalkyl group) is more preferable.

Specific examples of preferable anion moieties for the component (d1-1) are shown below.

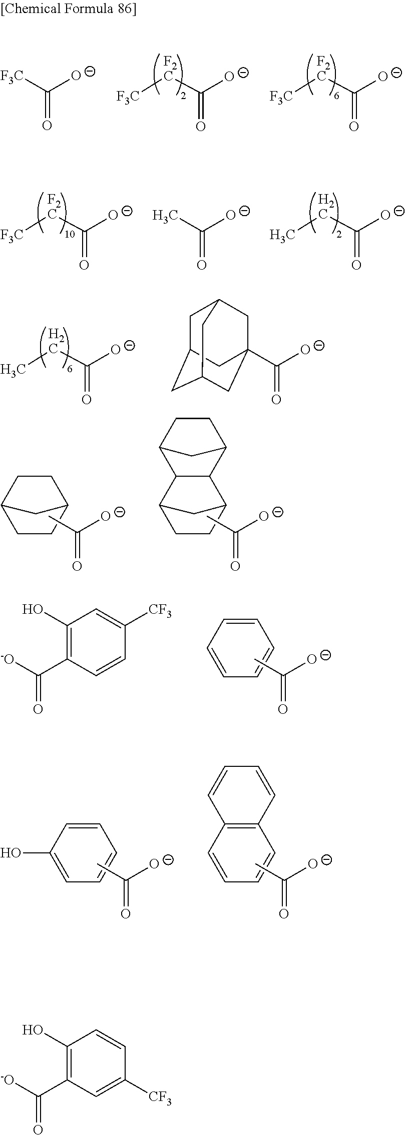

Cation Moiety

In formula (d1-1), M^{m+} represents an organic cation having a valency of m. The organic cation for M^{m+} is not particularly limited, and examples thereof include the same cation moieties as those represented by the aforementioned formulas (ca-1) to (ca-4), and preferably the cation moieties represented by the aforementioned formulas (ca-1-1) to (ca-1-58).

As the component (d1-1), one type of compound may be used, or two or more types of compounds may be used in combination.

{Component (d1-2)}

Anion Moiety

In formula (d1-2), Rd² represents a hydrocarbon group which may have a substituent.

As the hydrocarbon group for Rd² which may have a substituent, the same groups as those described above for the hydrocarbon group which may have a substituent for R² in the aforementioned formula (a0-m) can be mentioned.

Among these, as for Rd², an aliphatic cyclic group which may have a substituent is preferable, and a group in which one or more hydrogen atoms have been removed from adamantane, norbornane, isobornane, tricyclodecane or tetracyclododecane (which may have a substituent); and a group in which one or more hydrogen atom have been removed from camphor are more preferable.

The hydrocarbon group for Rd² may have a substituent, and as the substituents, the same substituent as those described above for the hydrocarbon group (aromatic hydrocarbon group or aliphatic hydrocarbon group) for R² in the aforementioned formula (a0-m) can be mentioned.

Provided that in Rd² in the formula (d1-2), the carbon adjacent to the S atom has no fluorine atom as a substituent (i.e, the hydrogen atom bonded to the carbon atom adjacent to the S atom is not substituted by a fluorine atom). As a result, the anion of the component (d1-2) becomes an appropriately weak acid anion, thereby improving the quenching ability of the component (D).

Specific examples of preferable anion moieties for the component (d1-2) are shown below.

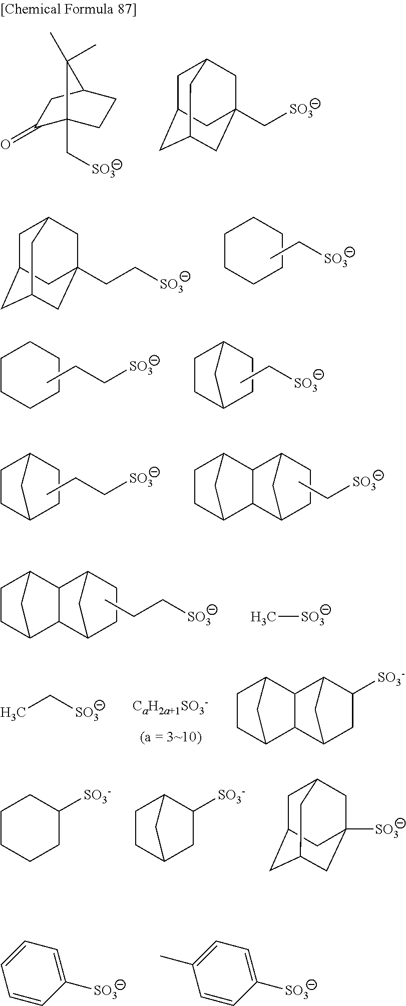

Cation Moiety

In formula (d1-2), M^{m+} is an organic cation having a valency of m, and is the same as defined for M^{m+} in the aforementioned formula (d1-1).

As the component (d1-2), one type of compound may be used, or two or more types of compounds may be used in combination.

{Component (d1-3)}

Anion Moiety

In formula (d1-3), Rd³ represents a hydrocarbon group containing a fluorine atom.

The hydrocarbon group containing a fluorine atom for Rd³ is preferably a fluorinated alkyl group, and more preferably the same fluorinated alkyl groups as those described above for Rd¹.

In formula (d1-3), Rd⁴ represents an alkyl group, an alkoxy group, —O—C(═O)—C(Rd⁴²)═CH₂ (wherein Rd⁴² represents a hydrogen atom, an alkyl group of 1 to 5 carbon atoms or a halogenated alkyl group of 1 to 5) or —O—C(═O)—Rd⁴³ (wherein Rd⁴³ represents a hydrocarbon group).

The alkyl group for Rd⁴ is preferably a linear or branched alkyl group of 1 to 5 carbon atoms, and specific examples include a methyl group, an ethyl group, a propyl group, an isopropyl group, an n-butyl group, an isobutyl group, a tert-butyl group, a pentyl group, an isopentyl group, and a neopentyl group. Part of the hydrogen atoms within the alkyl group for Rd⁴ may be substituted with a hydroxy group, a cyano group or the like.

The alkoxy group for Rd⁴ is preferably an alkoxy group of 1 to 5 carbon atoms, and specific examples thereof include a methoxy group, an ethoxy group, an n-propoxy group, an iso-propoxy group, an n-butoxy group and a tert-butoxy group. Among these, a methoxy group or an ethoxy group is preferable.

When Rd⁴ is —O—C(═O)—C(Rd⁴²)═CH₂, Rd⁴² represents a hydrogen atom, an alkyl group of 1 to 5 carbon atoms or a halogenated alkyl group of 1 to 5 carbon atoms.

As the alkyl group of 1 to 5 carbon atoms for Rd⁴², a linear or branched alkyl group of 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group and a neopentyl group.

The halogenated alkyl group for Rd⁴² is a group in which part or all of the hydrogen atoms of the aforementioned alkyl group of 1 to 5 carbon atoms has been substituted with halogen atoms. Examples of the halogen atom include a fluorine atom, a chlorine atom, a bromine atom and an iodine atom, and a fluorine atom is particularly desirable.

As Rd⁴², a hydrogen atom, an alkyl group of 1 to 3 carbon atoms or a fluorinated alkyl group of 1 to 3 carbon atoms is preferable, and a hydrogen atom or a methyl group is particularly desirable in terms of industrial availability.

When Rd⁴ is —O—C(═O)-Rd⁴³, Rd⁴³ represents a hydrocarbon group.

The hydrocarbon group for Rd⁴³ may be either an aromatic hydrocarbon group or an aliphatic hydrocarbon group. Specific examples of the hydrocarbon group for Rd⁴³ include the same groups as those described above for the hydrocarbon group which may have a substituent for R² in the aforementioned formula (a0-m).

Among these, as the hydrocarbon group for Rd⁴³, an aliphatic cyclic group (e.g., a group in which one or more hydrogen atoms have been removed from a cycloalkane such as cyclopentane, cyclohexane, adamantane, norbornane, isobornane, tricyclodecane or tetracyclododecane) or an aromatic group (e.g., a phenyl group or a naphthyl group) is preferable. When Rd⁴³ is an aliphatic cyclic group, the resist composition can be satisfactorily dissolved in an organic solvent, thereby improving the lithography properties. Alternatively, when Rd⁴³ is an aromatic group, the resist composition exhibits an excellent photoabsorption efficiency in a lithography process using EUV or the like as the exposure source, thereby resulting in the improvement of the sensitivity and the lithography properties.

Among these, as Rd⁴², —O—C(═O)—C(Rd⁴²′)═CH₂ (Rd⁴²′ represents a hydrogen atom or a methyl group) or —O—C(═O)—Rd⁴³′ (Rd⁴³′ represents an aliphatic cyclic group).

In formula (d1-3), Yd¹ represents an alkylene group or an arylene group.

As the alkylene group or arylene group for Yd¹, the same groups as those described above for the hydrocarbon group (aliphatic hydrocarbon group or aromatic hydrocarbon group) for Y¹ in the aforementioned formula (a0-m) can be mentioned.

Among these, as Yd¹, an alkylene group is preferable, a linear or branched alkylene group is more preferable, and a methylene group or an ethylene group is still more preferable.

Specific examples of preferable anion moieties for the component (d1-3) are shown below.

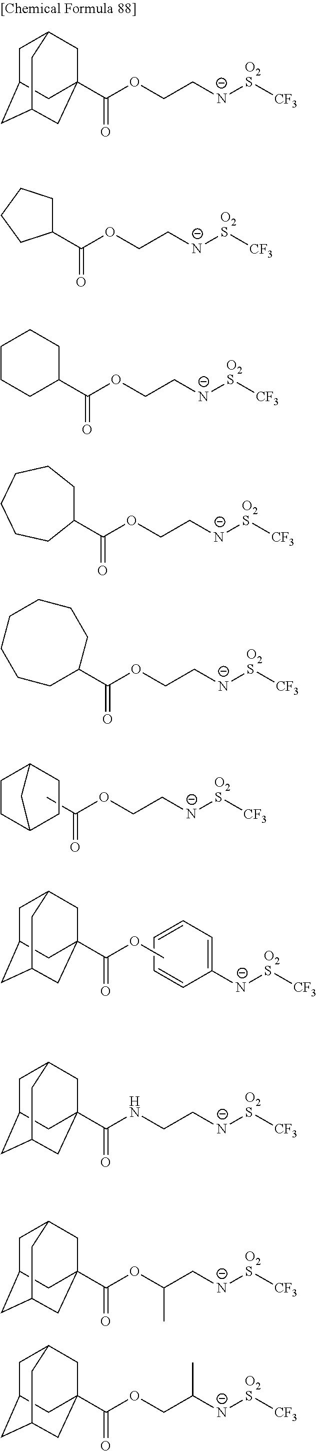

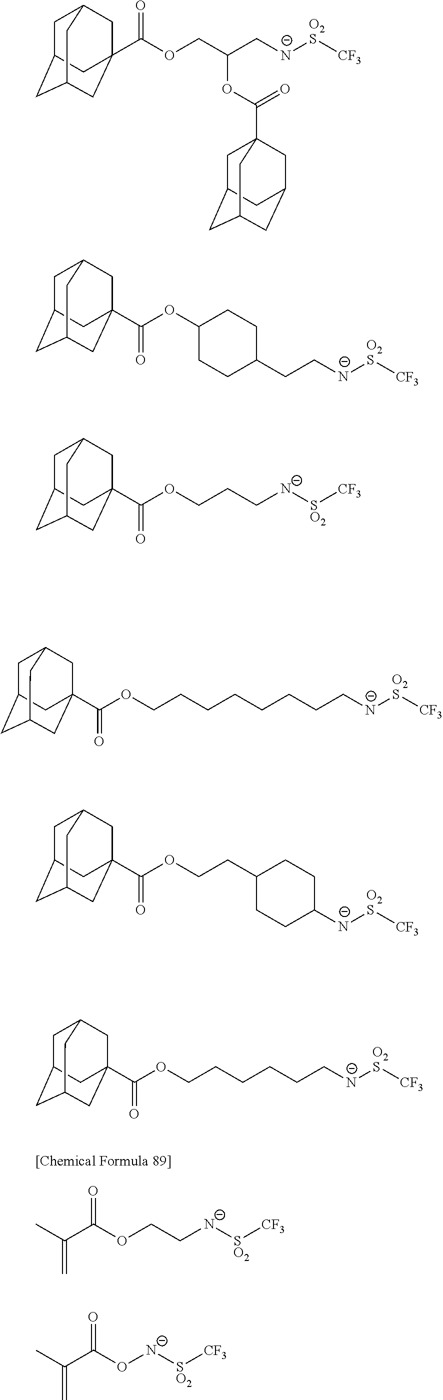

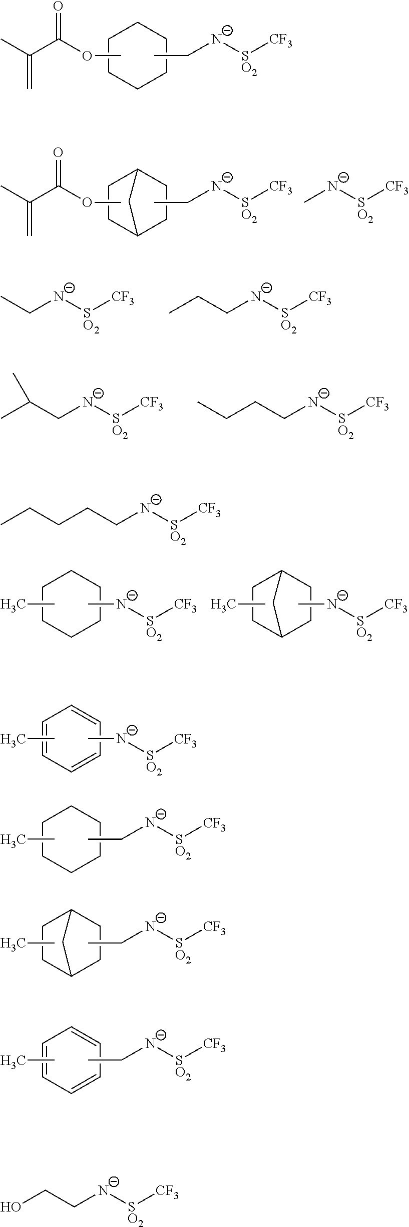

Cation Moiety

In formula (d1-3), M^{m+} is an organic cation having a valency of m, and is the same as defined for M^{m+} in the aforementioned formula (d1-1).

As the component (d1-3), one type of compound may be used, or two or more types of compounds may be used in combination.

The component (D1) may contain one of the aforementioned components (d1-1) to (d1-3), or at least two of the aforementioned components (d1-1) to (d1-3).

The amount of the component (D1) relative to 100 parts by weight of the component (A) is preferably within a range from 0.5 to 10 parts by weight, more preferably from 0.5 to 8 parts by weight, and still more preferably from 1 to 8 parts by weight.

When the amount of the component (D1) is at least as large as the lower limit of the above-mentioned range, excellent lithography properties and excellent resist pattern shape can be obtained. On the other hand, when the amount of the component (D1) is no more than the upper limit of the above-mentioned range, sensitivity can be maintained at a satisfactory level, and through-put becomes excellent.

{Production Method of Component (D1)}

The production methods of the aforementioned components (d1-1) and (d1-2) are not particularly limited, and the components (d1-1) and (d1-2) can be produced by conventional methods.

The production method of the component (d1-3) is not particularly limited. For example, in the case where Rd⁴ in formula (d1-3) is a group having an oxygen atom on the terminal thereof which is bonded to Yd¹, the compound (d1-3) represented by general formula (d1-3) can be produced by reacting a compound (i-1) represented by general formula (i-1) shown below with a compound (i-2) represented by general formula (i-2) shown below to obtain a compound (i-3) represented by general formula (i-3) shown below, and reacting the compound (i-3) with a compound Z⁻(M^{m+})^{1/m} (i-4) having the desired cation M^{m+}, thereby obtaining the compound (d1-3).

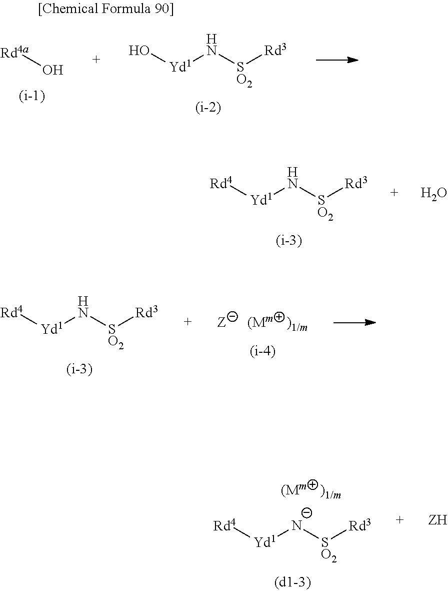

In the formulae, Rd⁴, Yd¹, Rd³ and M^{m+} are respectively the same as defined for Rd⁴, Yd¹, Rd³ and M^{m+} in the aforementioned general formula (d1-3); Rd^{4a}. represents a group in which the terminal oxygen atom has been removed from the Rd⁴ group; and Z⁻ represents a counteranion.

Firstly, the compound (i-1) is reacted with the compound (i-2), thereby obtain the compound (i-3).

In formula (i-1), Rd^{4a} represents a group in which the terminal oxygen atom has been removed from Rd⁴. In formula (i-2), Yd¹ and Rd³ are the same as defined above.

As the compound (i-1) and the compound (i-2), commercially available compounds may be used, or the compounds may be synthesized.

The method for reacting the compound (i-1) with the compound (i-2) to obtain the compound (i-3) is not particularly limited, but can be performed, for example, by reacting the compound (i-1) with the compound (i-2) in an organic solvent in the presence of an appropriate acidic catalyst, followed by washing and recovering the reaction mixture.

The acidic catalyst used in the above reaction is not particularly limited, and examples thereof include toluenesulfonic acid and the like. The amount of the acidic catalyst is preferably 0.05 to 5 moles, per 1 mole of the compound (i-2).

As the organic solvent used in the above reaction, any organic solvent which is capable of dissolving the raw materials, i.e., the compound (i-1) and the compound (i-2) can be used, and specific examples thereof include toluene and the like. The amount of the organic solvent is preferably 0.5 to 100 parts by weight, more preferably 0.5 to 20 parts by weight, relative to the amount of the compound (i-1). As the solvent, one type may be used alone, or two or more types may be used in combination.

In general, the amount of the compound (i-2) used in the above reaction is preferably 0.5 to 5 moles per 1 mole of the compound (i-1), and more preferably 0.8 to 4 moles per 1 mole of the compound (i-1).

The reaction time depends on the reactivity of the compounds (i-1) and (i-2), the reaction temperature or the like. However, in general, the reaction time is preferably 1 to 80 hours, and more preferably 3 to 60 hours.

The reaction temperature in the above reaction is preferably 20 to 200° C., and more preferably 20 to 150° C.

Next, the obtained compound (i-3) is reacted with the compound (i-4), thereby obtaining the compound (d1-3).

In formula (i-4), M^{m+} is the same as defined above, and T represents a counteranion.

The method for reacting the compound (i-3) with the compound (i-4) to obtain the compound (d1-3) is not particularly limited, but can be performed, for example, by dissolving the compound (i-3) in an organic solvent and water in the presence of an appropriate alkali metal hydroxide, followed by addition of the compound (i-4) and stirring.

The alkali metal hydroxide used in the above reaction is not particularly limited, and examples thereof include sodium hydroxide, potassium hydroxide and the like. The amount of the alkali metal hydroxide is preferably 0.3 to 3 moles, per 1 mole of the compound (i-3).

Examples of the organic solvent used in the above reaction include dichloromethane, chloroform, ethyl acetate and the like. The amount of the organic solvent is preferably 0.5 to 100 parts by weight, and more preferably 0.5 to 20 parts by weight, relative to the weight of the compound (i-3). As the solvent, one type may be used alone, or two or more types may be used in combination.

In general, the amount of the compound (i-4) used in the above reaction is preferably 0.5 to 5 moles per 1 mole of the compound (i-3), and more preferably 0.8 to 4 moles per 1 mole of the compound (i-3).

The reaction time depends on the reactivity of the compounds (i-3) and (i-4), the reaction temperature or the like. However, in general, the reaction time is preferably 1 to 80 hours, and more preferably 3 to 60 hours.

The reaction temperature in the above reaction is preferably 20 to 200° C., and more preferably 20 to 150° C.

After the reaction, the compound (d1-3) contained in the reaction mixture may be separated and purified. The separation and purification can be conducted by a conventional method. For example, any one of concentration, solvent extraction, distillation, crystallization, recrystallization and chromatography can be used alone, or two or more of these methods may be used in combination.

The structure of the compound (d1-3) obtained in the above-described manner can be confirmed by a general organic analysis method such as ¹H-nuclear magnetic resonance (NMR) spectrometry, ¹³C-NMR spectrometry, ¹⁹F-NMR spectrometry, infrared absorption (IR) spectrometry, mass spectrometry (MS), elementary analysis and X-ray diffraction analysis.

(Component (D2))

The component (D2) is not particularly limited, as long as it is a compound which is basic relative to the components (G) and (B), so as to functions as an acid diffusion inhibitor, and does not fall under the definition of the component (D1). As the component (D2), any of the conventionally known compounds may be selected for use. Examples thereof include an aliphatic amine, an aromatic amine, and an amine compound in which one proton “H⁺” has been removed from the cation moieties represented by the aforementioned formulas (J1c-11) to (J1c-14).

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine. Among these, trialkylamines of 5 to 10 carbon atoms are preferable, and tri-n-pentylamine and tri-n-octylamine are particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris {2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris {2-(1-ethoxypropoxy)ethyl}amine, tris[2-{2-(2-hydroxyethoxy)ethoxy}ethyl]amine and triethanolamine triacetate, and triethanolamine triacetate is preferable.

Further, as the component (D2), an aromatic amine may be used.

Examples of aromatic amines include aniline, pyridine, 4-dimethylaminopyridine, pyrrole, indole, pyrazole, imidazole and derivatives thereof, diphenylamine, triphenylamine, tribenzylamine, 2,6-diisopropylaniline and N-tert-butoxycarbonylpyrrolidine.

In the case of the resist composition containing a component (J) and/or a component (G) in addition to the component (A), it is preferable that a pKa of the conjugate acid of the component (D2) is smaller than a pKa of the cation moiety of each component. Specific examples of the component (D2) include aliphatic amine compounds which have a fluorinated alkyl group, such as trifluoroethylamine (2,2,2-trifluoroethylamine), pentafluoropropylamine (2,2,3,3,3-pentafluoropropylamine), heptafluorobutylamine (1H,1H-heptafluorobutylamine), nonafluoropentylamine (1H,1H-nonafluoropentylamine), undecafluorohexylamine (1H,1H-undecafluorohexylamine), bis(2,2,2-trifluoroethyl)amine, bis(2,2,3,3,3-pentafluoropropyl)amine and 1-(2,2,2-trifluoroethyl)pyrrolidine; pyridine compounds, such as pyridine and pentafluoropyridine; and oxazole compounds, such as oxazole and isooxyazole.

As the component (D2), one type of compound may be used alone, or two or more types may be used in combination.

The component (D2) is typically used in an amount within a range from 0.01 to 5.0 parts by weight, relative to 100 parts by weight of the component (A). When the amount of the component (D2) is within the above-mentioned range, the shape of the resist pattern and the post exposure stability of the latent image formed by the pattern-wise exposure of the resist layer are improved.

As the component (D), one type of compound may be used, or two or more types may be used in combination.

When the resist composition of the present invention contains the component (D), the amount of the component (D) relative to 100 parts by weight of the component (A) is preferably within a range from 0.1 to 15 parts by weight, more preferably from 0.3 to 12 parts by weight, and still more preferably from 0.5 to 10 parts by weight.

When the amount of the component (D) is at least as large as the lower limit of the above-mentioned range, various lithography properties of the resist composition are improved, such as roughness and dimension uniformity. Further, a resist pattern having an excellent shape can be obtained. On the other hand, when the amount of the component (D) is no more than the upper limit of the above-mentioned range, sensitivity can be maintained at a satisfactory level, and through-put becomes excellent.

If desired, other miscible additives can also be added to the resist composition of the present invention. Examples of such miscible additives include additive resins for improving the performance of the resist film, surfactants for improving the applicability, dissolution inhibitors, plasticizers, stabilizers, colorants, halation prevention agents, dyes, sensitizers and base amplifiers.

As the sensitizer, conventional sensitizers can be used, and specific examples thereof include benzophenone-type sensitizers, such as benzophenone and p,p′-tetramethyldiaminobenzophenone; carbazole-type sensitizers; acetophen-type sensitizers; naphthalene-type sensitizers; phenol-type sensitizers; anthracene-type sensitizers, such as 9-ethoxyanthracene; biacetyl; eosin; rose bengal; pyrene; phenothiazine; and anthrone. In the resist composition, the amount of the sensitizer, relative to 100 parts by weight of the component (A) is preferably from 0.5 to 20 parts by weight.

A base amplifier is decomposed by the action of a base in a chain reaction, and is capable of generating a large amount of base using a small amount of base. Therefore, by blending a base amplifier, the sensitivity of the resist composition can be improved. As the base amplifier, for example, those described in Japanese Unexamined Patent Application, First Publication No. 2000-330270 and Japanese Unexamined Patent Application, First Publication No. 2008-174515 can be used.

[Organic Solvent Component (S)]

The resist composition used in the present invention can be prepared by dissolving the resist materials for the resist composition in an organic solvent (hereafter, referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene.

These solvents can be used individually, or in combination as a mixed solvent.

Among the aforementioned examples, PGMEA, PGME, cyclohexanone and EL are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2. For example, when EL or cyclohexanone is mixed as the polar solvent, the PGMEA:EL weight ratio or the PGMEA:cyclohexanone weight ratio is preferably from 1:9 to 9:1, and more preferably from 2:8 to 8:2. Alternatively, when PGME is mixed as the polar solvent, the PGMEA:PGME is preferably from 1:9 to 9:1, more preferably from 2:8 to 8:2, and still more preferably 3:7 to 7:3. Alternatively, when PGME and cyclohexanone is mixed as the polar solvent, the PGMEA:(PGME+cyclohexanone) weight ratio is preferably from 1:9 to 9:1, more preferably from 2:8 to 8:2, and still more preferably 3:7 to 7:3.

Further, as the component (S), a mixed solvent of γ-butyrolactone with PGMEA, EL or the aforementioned mixed solvent of PGMEA with a polar solvent, is also preferable. The mixing ratio (former:latter) of such a mixed solvent is preferably from 70:30 to 95:5.

The amount of the component (S) is not particularly limited, and is appropriately adjusted to a concentration which enables coating of a coating solution to a substrate, depending on the thickness of the coating film. In general, the organic solvent is used in an amount such that the solid content of the resist composition becomes within the range from 1 to 20% by weight, and preferably from 2 to 15% by weight.

The resist composition of the present invention described above can be preferably used in the formation of a resist pattern by an alkali developing process.

The base component (A) used in the resist composition of the present invention generates base upon exposure, in addition to exhibiting changed solubility in a developing solution by the action of acid. Further, the component (A) includes a polymeric compound (A1) containing a structural unit (a0) derived from a compound represented by general formula (a0-m). By using the component (A1), at unexposed portions of a resist film, the solubility of the component (A) in an alkali developing solution is increased. On the other hand, at exposed portions of a resist film, base is generated from a structural unit (A) upon exposure, and by the interaction between the base and acid, the solubility of the component (A) in an alkali developing solution is either unchanged or only slightly changed. The component (A1) has —O—O—Y¹— in the structure thereof, and hence, the polymerizable group (R¹) is distantly positioned from the amine part (—N(R²)—Y²—). As a result, the glass-transition temperature of the component (A1) is reduced, thereby enhancing the diffusion property of base generated upon exposure in the resist film. Further, at exposed portions of the resist film, by enhancing the interaction between the base and acid, the film retentiveness of the resist film at exposed portions becomes excellent, and the dimension uniformity of the formed resist pattern is further improved.

Furthermore, the resist composition of the present invention is preferably used in step (1) of the method of forming a resist pattern including steps (1) to (4) described below.

<<Method of Forming a Resist Pattern>>

The method of forming a resist pattern according to the second aspect of the present invention includes: forming a resist film on a substrate using a resist composition of the present invention; conducting exposure of the resist film; and developing the resist film to form a resist pattern.

As an embodiment of the method of forming a resist pattern, a method of forming a negative resist pattern, including: a step (1) in which a resist film is formed on a substrate using a resist composition containing a base component (A) and an acid component (G); a step (2) in which the resist film is subjected to exposure; a step (3) in which baking is conducted after the step (2), so as to increase the solubility of the base component (A) in an alkali developing solution by the action of the acid component (G) at an unexposed portion of the resist film; and a step (4) in which the resist film is subjected to an alkali development.

According to this embodiment, exposed portions of the resist film are not removed and dissolved by alkali development due to neutralization between the base generated from the base component (A) and the acid component (G), but unexposed portions of the resist film are removed and dissolved by alkali development.

Hereinbelow, the method of forming a resist pattern according to the aforementioned embodiment will be described, with reference to the drawings. However, the present invention is not limited to these embodiments.

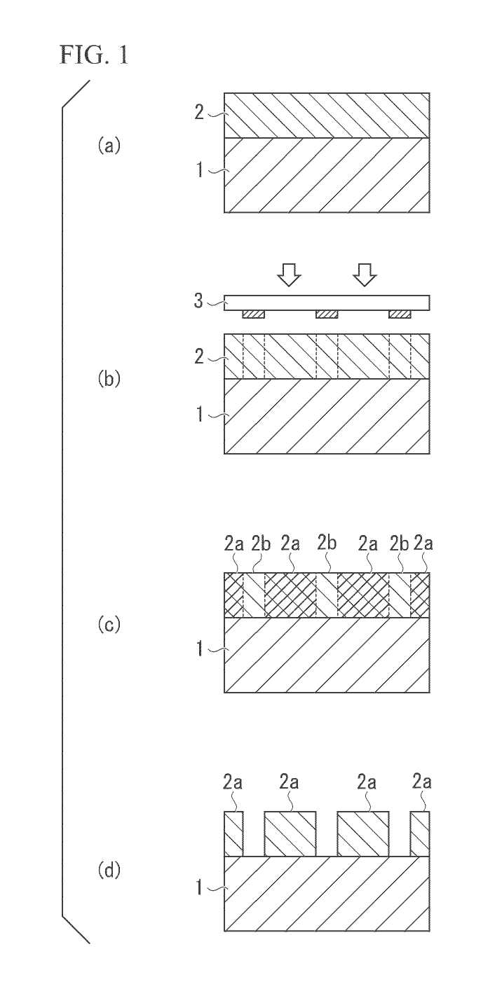

FIG. 1 shows an example of one embodiment of the method of forming a resist pattern according to the present invention.

In this embodiment, a resist composition contains a base component (A) which generates base upon exposure and exhibits changed solubility in a developing solution under action of acid (i.e., component (A)), and an acid component (i.e., component (G)).

Firstly, as shown in FIG. 1(a), the resist composition is applied to a substrate 1 to form a resist film 2 (step (1); FIG. 1(a)).

Next, as shown in FIG. 1(b), the resist film 2 formed in the step (1) is subjected to exposure through a photomask 3 having a predetermined pattern formed thereon. As a result, in the exposed region (exposed portions) of the resist film 2, a base is generated from the component (A) upon exposure (step (2); FIG. 1(b)).

After exposure, baking (post exposure bake (PEB)) is conducted. By this baking, at the unexposed portions 2b of the resist film 2, the solubility of the component (A) in an alkali developing solution can be increased by the action of the acid (component (G)) provided to the resist film 2 by adding the component (G) to the resist composition. On the other hand, at exposed portions 2a, a neutralization reaction between the base generated from the component (A) upon exposure and the acid provided to the resist film 2 proceeds, so that the solubility of the component (A) in an alkali developing solution is either unchanged or only slightly changed. As a result, a difference in the dissolution rate in an alkali developing solution (dissolution contrast) occurs between the exposed portions 2a and the unexposed portions 2b (step (3); FIG. 1(c)). Thereafter, developing is conducted using an alkali developing solution. By conducting development, the exposed portions 2a of the resist film 2 remain, and the unexposed portions 2b of the resist film 2 are dissolved and removed. As a result, as shown in FIG. 1(d), a resist pattern including a plurality of resist patterns arranged at intervals is formed on the substrate 1 (step (4); FIG. 1(d)).

[Step (1)]

In this embodiment, a resist composition including components (A) and (G) is applied to a substrate 1, thereby forming a resist film 2.

The substrate 1 is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate 1, any one of the above-mentioned substrates provided with an inorganic and/or organic film on the surface thereof may be used, and a substrate provided with an organic film is preferable. As the inorganic film, an inorganic antireflection film (inorganic BARC) can be used. As the organic film, an organic antireflection film (organic BARC) and an organic film such as a lower-layer organic film used in a multilayer resist method can be used. It is particularly desirable that an organic film is provided because a pattern can be reliably formed on the substrate with a high aspect ratio which is useful in the production of semiconductors.

Here, a “multilayer resist method” is method in which at least one layer of an organic film (lower-layer film) and at least one layer of a resist film are provided on a substrate, and a resist pattern formed on the upper resist film is used as a mask to conduct patterning of the lower-layer film. This method is considered as being capable of forming a pattern with a high aspect ratio. The multilayer resist method is broadly classified into a method in which a double-layer structure consisting of an upper-layer resist film and a lower-layer film is formed, and a method in which a multilayer structure having at least three layers composed of an upper-layer resist film, a lower-layer film and at least one intermediate layer (thin metal film or the like) provided between the upper-layer resist film and the lower-layer film. In the multilayer resist method, a desired thickness can be ensured by the lower-layer film, and as a result, the thickness of the resist film can be reduced, and an extremely fine pattern with a high aspect ratio can be formed.

An inorganic film can be formed, for example, by coating an in organic anti-reflection film composition such as a silicon-based material on a substrate, followed by baking.

An organic film can be formed, for example, by dissolving a resin component and the like for forming the film in an organic solvent to obtain an organic film-forming material, coating the organic film-forming material on a substrate using a spinner or the like, and baking under heating conditions preferably in the range of 200 to 300° C. for 30 to 300 seconds, more preferably for 60 to 180 seconds. The organic film-forming material does not need to have susceptibility to light or electron beam like a resist film, and the organic film-forming material may or may not have such susceptibility. More specifically, a resist or a resin generally used in the production of a semiconductor device or a liquid crystal display device can be used.

Further, it is preferable that the organic film-forming material can be subjected to etching, particularly dry etching, so that, by etching the organic film using a resist pattern, the resist pattern can be transferred to the organic film, and an organic film pattern can be formed. It is particularly desirable to use an organic film-forming material which can be subjected to oxygen plasma etching or the like. As such an organic film-forming material, a material conventionally used for forming an organic film such as an organic BARC can be used. Examples of such an organic film-forming material include the ARC series manufactured by Brewer Science Ltd., the AR series manufactured by Rohm and Haas Company, and the SWK series manufactured by Tokyo Ohka Kogyo Co., Ltd.

In this embodiment, the component (G) contained in the resist composition neutralizes the base generated from the component (A) upon exposure at exposed portions 2a in steps (2) and (3) described later. Thus, the solubility of the component (A) in an alkali developing is either unchanged or only slightly changed. In step (3) described later, the component (G) acts on the component (A) as an acid upon baking (PEB), thereby increasing the solubility of the component (A) at unexposed portions 2b in an alkali developing solution.

The explanation of the resist composition is the same as the explanation of the resist composition of the present invention.

The method of applying the resist composition to the substrate 1 to form a resist film 2 is not particularly limited, and the resist film 2 can be formed by a conventional method.

For example, the resist composition can be applied to the substrate 1 by a conventional method such as a spin-coating method using a spinner, a bar-coating method using a bar coater, or the like, followed by drying at room temperature on a cooling plate or the like, or prebaking (PAB), thereby forming a resist film 2.

In the present invention, “prebake” refers to a heat treatment of 70° C. or higher that is conducted after applying the resist composition to the substrate and before conducting exposure using a hot plate or the like.

When a prebaking treatment is conducted, the temperature conditions is preferably from 80 to 150° C., and more preferably from 80 to 100° C. The prebaking time is preferably from 40 to 120 seconds, and more preferably from 60 to 90 seconds. By conducting prebaking, the organic solvent can be volatilized even when the resist film has a large film thickness.

By drying the resist composition at room temperature and not conducting prebaking, the number of steps in the formation of a resist pattern can be reduced, and the resolution of the resist pattern can be enhanced.

Whether or not a prebaking is conducted can be suitably determined depending on the advantages in view of the materials used for the resist composition, and target of the pattern to be formed.

The film thickness of the resist film 2 formed in step (1) is preferably within the range from 50 to 500 nm, and more preferably from 50 to 450 nm. By ensuring that the thickness of the resist film satisfies the above-mentioned range, a resist pattern with a high level of resolution can be formed, and a satisfactory level of etching resistance can be achieved.

Further, in the case where a prebaking is not conducted, the film thickness of the resist film 2 formed in step (1) is preferably 300 nm or less, more preferably 200 nm or less, and particularly preferably from 50 to 150 nm. When the film thickness of the resist film 2 is no more than the upper limit of the preferable range, by a coating method such as a spin-coating method at room temperature without prebaking, the organic solvent is less likely to remain in the resist film, and the resist film can be more reliably dried, thereby improving the uniformity of the film thickness of the resist film 2 (i.e., the in-plane uniformity of the substrate 1). The effects of not conducting a prebaking become more significant as the film thickness of the resist film becomes smaller.

[Step (2)]

In the present embodiment, the resist film 2 formed in the step (1) is selectively exposed through a photomask 3. As a result, at exposed portions 2a, a base is generated from the component (A) upon exposure, and a neutralization reaction between the base and the acid (component (G)) within the resist film 2 is started.

In the present invention, by using a component (A) containing a component (A1), base generated from the structural unit (A) upon exposure easily diffuses into the entire exposed portions 2a of the resist film 2. Therefore, the base is neutralized by satisfactory amount of acid in exposed portions 2a.

With respect to the exposure dose, an amount capable of generating a base from the component (A) in an amount necessary to neutralize the acid which presents in the exposed portions 2a is sufficient.

The wavelength to be used for exposure is not particularly limited and the exposure can be conducted using radiation such as KrF excimer laser, ArF excimer laser, F₂ excimer laser, extreme ultraviolet rays (EUV), vacuum ultraviolet rays (VUV), electron beam (EB), X-rays, and soft X-rays. In terms of forming a fine resist pattern, ArF excimer laser, EUV or EB is preferable, and ArF excimer laser is particularly desirable.

The photomask 3 is not particularly limited, and a conventional mask can be used. For example, a binary mask in which the transmittance of the light shielding portion is 0% or a halftone-phase shift mask (HT-mask) in which the transmittance of the light shielding portion is 6% can be used. The unexposed portions can be selectively formed by using a halftone-phase shift mask.

As a binary mask, those in which a chromium film, a chromium oxide film, or the like is formed as a light shielding portion on a quartz glass substrate are generally used.

A phase shift mask is a photomask provided with a portion (shifter) which changes the phase of light. Thus, by using a phase shift mask, incidence of light to unexposed portions can be suppressed, and the dissolution contrast to an alkali developing solution can be improved between unexposed portions and exposed portions. As a phase shift mask other than a halftone-phase shift mask, a Levenson-phase shift mask can be mentioned. As any of these phase shift masks, commercially available masks can be used.

Specific examples of the half-tone type phase shift masks include those in which an MoSi (molybdenum silicide) film, a chromium film, a chromium oxide film, an silicon oxynitride film, or the like is formed as a light shielding portion (shifter) exhibiting a transmittance of about several % to 10% (generally 6%) on a substrate generally made of quartz glass.

In the present embodiment, exposure is conducted through a photomask 3, but the present invention is not limited to this embodiment. For example, the exposure may be conducted without using a photomask 3, e.g., selective exposure by drawing with electron beam (EB) or the like.

The exposure of the resist film 2 can be either a general exposure (dry exposure) conducted in air or an inert gas such as nitrogen, or immersion exposure (immersion lithography) through an immersion medium. In step (2), in terms of forming a resist pattern with a high resolution, it is preferable to conduct exposure through an immersion medium.

In immersion lithography, exposure (immersion exposure) is conducted in a state where the region between the lens and the resist film 2 formed on the substrate 1 (which was conventionally filled with air or an inert gas such as nitrogen) is filled with a solvent (a immersion medium) that has a larger refractive index than the refractive index of air.

More specifically, in immersion lithography, the region between the resist film 2 formed in the above-described manner and lens at the lowermost portion of the exposure apparatus is filled with a solvent (an immersion medium) that has a larger refractive index than the refractive index of air, and in this state, the resist film 2 is subjected to exposure (immersion exposure) through a predetermined photomask 3.

The immersion medium preferably exhibits a refractive index larger than the refractive index of air but smaller than the refractive index of the resist film 2 to be subjected to immersion exposure. The refractive index of the immersion medium is not particularly limited as long at it satisfies the above-mentioned requirements.

Examples of this immersion medium which exhibits a refractive index that is larger than the refractive index of air but smaller than the refractive index of the resist film 2 include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the immersion medium after the exposure can be removed by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

[Step (3)]

In the present embodiment, after the step (2), baking (post exposure bake (PEB)) is conducted.

In the baking, the temperature conditions is preferably from 50 to 200° C., more preferably from 80 to 150° C., and still more preferably from 90 to 130° C. The baking time is preferably from 10 to 300 seconds, more preferably from 40 to 120 seconds, and still more preferably from 60 to 90 seconds.

In this manner, by conducting baking of the resist film 2 after exposure, in the entire resist film 2, the component (G) blended within the resist composition acts as acid, and at unexposed portions 2b, by the action of the acid (component (G)), the solubility of the component (A) in an alkali developing solution is increased. On the other hand, at exposed portions 2a, a neutralization reaction between the base generated from the component (A) upon exposure and the acid (component (G)) proceeds, so that the amount of acid which would act on the component (A) decreases. As a result, the solubility of the component (A) in an alkali developing is either unchanged or only slightly changed. As such, a difference in the dissolution rate in an alkali developing solution (dissolution contrast) occurs between the exposed portions 2a and the unexposed portions 2b. Further, in the present invention, since base generated from the structural unit (a0) upon exposure is neutralized by satisfactorily acid in exposed portions 2a, the film retentiveness of the resist film at exposed portions 2a becomes excellent, and the dimension uniformity of the formed resist pattern is further improved.

The baking in this step (3) does not necessarily control the start of the neutralization reaction.

[Step (4)]

In the present embodiment, after the step (3), by conducting alkali developing, the unexposed portions 2b of the resist film 2 are dissolved and removed, and the exposed portions 2a are retained, thereby forming a negative resist pattern.

Specific examples of the alkali developing solution include inorganic alkalis, such as sodium hydroxide, potassium hydroxide, sodium carbonate, sodium silicate, sodium metasilicate and aqueous ammonia; primary amines, such as ethylamine and n-propyl amine; secondary amines, such as diethylamine and di-n-butylamine; tertiary amines, such as triethylamine and methyldiethylamine; alcoholamines, such as dimethylethanolamine and triethanolamine; quaternary ammonium salts, such as tetramethylammonium hydroxide and tetraethylammonium hydroxide; and cyclic amines, such as pyrrole and piperidine.

Among these examples, as the alkali developing solution, an aqueous alkali solution containing at least one member selected from the group consisting of primary amines, secondary amines, tertiary amines and quaternary ammonium salts is preferable, and an aqueous solution of tetramethylammonium hydroxide (TMAH) is particularly desirable.

Further, the aforementioned aqueous alkali solution having alcohols, surfactants added thereto in an appropriate amount may be used.

In general, the alkali concentration within the alkali developing solution (i.e., concentration of inorganic alkalis, quaternary ammonium salts or amine compounds, based on the total weight of the alkali developing solution) is from 0.01 to 20% by weight.

The alkali developing treatment can be performed by a conventional method.

After the alkali development, a rinse treatment using pure water or the like may be conducted.

In addition, after the alkali development, a further baking (post bake) may be conducted. Post bake (which is performed in order to remove water content after the alkali developing and rinsing) is generally conducted at about 100° C. preferably for 30 to 90 seconds.

In the first embodiment described above, a resist composition containing a component (G) is used. However, a resist composition containing an acid generator component (B) instead of the component (G) or together with the component (G) may be used. When the component (B) is used instead of the component (G), the aforementioned dual-tone developing process can be preferably conducted. Further, an acid amplifier component (H) may be used in combination with at least one of the component (G) and the component (B), since the acid concentration can be enhanced by a bake treatment such as PEB. Further, a resist composition containing a component (J) instead of the component (G) or together with the component (G) may be used. When the component (J) is used instead of the component (G), since neutralization reaction proceeds upon exposure, a negative pattern can be obtained.

In the method of forming a resist pattern of the present invention, a resist composition containing a component (J) in addition to a component (A) is preferably used. By using the resist composition containing a component (J), a resist pattern with excellent lithography properties such as dimension uniformity and resolution can be formed.

As the method of forming a resist pattern of the present invention, an embodiment other than aforementioned embodiment may be applied. For example, an embodiment in which between steps (2) and (3), a step is conducted in which an organic film-forming composition containing a component (G) is coated on the resist film, can be mentioned. In this embodiment, by baking (PEB) in the step (3), an organic film is formed, and a component (G) in the organic film is diffused to the resist film, thereby providing acid to the resist film. At the exposed portions of the resist film, the base generated from the component (A) upon exposure and the acid provided from the organic film are neutralized. Thus, the solubility of the component (A) in an alkali developing is either unchanged or only slightly changed. On the other hand, at unexposed portions, the solubility of the component (A) in an alkali developing solution is increased by the action of the acid provided from the organic film. As a result, a difference in the dissolution rate in an alkali developing solution (dissolution contrast) occurs between the exposed portions and the unexposed portions, and a negative resist pattern can be formed by alkali development. The organic film-forming composition may contain, for example, a conventional resin, an organic solvent and the like, in addition to the component (G).

Alternatively, instead of using an organic film-forming composition containing a component (G), an embodiment in which an acidic, activated rinse is applied to the resist film can be used. As the acidic, activated rinse, an aqueous solution containing a component (G2) described above can be used.

In the method of forming a resist pattern according to the present invention, after forming a negative resist pattern in the manner as described above, etching of the substrate 1 may be conducted using the negative resist pattern as a mask. By conducting such etching to transfer the resist pattern to the substrate 1, a semiconductor device or the like can be produced.

The etching can be conducted by a conventional method. For example, when the substrate 1 has an organic film formed thereon, the etching of the organic film is preferably conducted by dry etching. Among dry etching, especially in terms of production efficiency, oxygen-plasma etching or etching using a CF₄ gas or a CHF₃ gas is preferable, and oxygen-plasma etching is more preferable.

Etching of the substrate is preferably performed using a halogen gas, more preferably using a fluorinated carbon-based gas, and most preferably using a F₄ gas or a CHF₃ gas.

According to the method of forming a resist pattern of the present invention, a negative-tone resist pattern can be formed with an excellent lithography properties such as dimension uniformity by a developing process in which a chemically amplified resist composition conventionally known as a positive type is used in combination with an alkali developing solution. Further, the method of forming a resist pattern of the present invention can be used in the dual-tone developing process (see Japanese Unexamined Patent Application, First Publication No. 2011-102974).

Further, according to the method of forming a resist pattern of the present invention, the resolution becomes excellent in a resist pattern (such as an isolated trench pattern, an extremely small, dense contact hole pattern, or the like) having a region where the optical strength becomes weak (region where irradiation by exposure is not satisfactorily reached) is likely to be generated in a film thickness direction.

Further, by the method of forming a resist pattern according to the present invention, it is possible to form a highly densed resist pattern. For example, it becomes possible to form a contact hole pattern in which each of the holes are close to each other with excellent shapes, e.g., the distance between the holes is about 30 to 50 nm.

Furthermore, the method of forming a resist pattern according to the present invention can be performed by existing exposure apparatuses and existing facilities.

Moreover, by using a double exposure method in the method of forming a resist pattern according to the present invention, the number of steps can be reduced as compared to a double patterning in which each of a lithography step and a patterning step are performed at least twice.

<<Compound>>

The compound according to the third aspect of the present invention is a compound represented by general formula (a0-m) shown below.

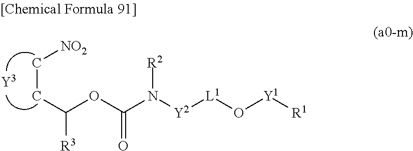

In the formula, R¹ represents a polymerizable group; Y¹ represents a hydrocarbon group of 1 to 30 carbon atoms which may have a substituent; L¹ represents a single bond or a carbonyl group; Y² represents a divalent linking group, and R² represents a hydrogen atom or a hydrocarbon group which may have a substituent, provided that Y² and R² may be mutually bonded to form a ring with the nitrogen atom having Y² and R² bonded thereto; R³ represents a hydrogen atom or a hydrocarbon group which may have a substituent; and Y³ represents a group which forms an aromatic ring together with the two carbon atoms having Y³ bonded thereto, provided that the aromatic ring may have a nitro group or a substituent other than the nitro group bonded to the aromatic ring.

The explanation of the compound of the present invention is the same as the explanation of the compound which derives the structural unit (a0) in the component (A1) contained in the resist composition of the present invention described above and which represented by the general formula (a0-m).

The compound of the present invention is a new compound useful as a raw material (monomer) for a polymeric compound of the present invention described later.

<<Polymeric Compound>>

A fourth aspect of the present invention is a polymeric compound having a structural unit (i.e., structural unit (a0)) derived from the aforementioned compound of the present invention.

It is preferable that the polymeric compound of the present invention further includes, in addition to the structural unit (a0), a structural unit (a1) containing an acid decomposable group that exhibits increased polarity by the action of acid. Further, it is preferable that the polymeric compound of the present invention include a structural unit containing a lactone-containing cyclic group (i.e., structural unit (a2)), as well as the structural units (a0) and (a1).

The polymeric compound of the present invention is the same as the component (A 1) contained in the resist composition of the present invention described above, and the type of each structural unit, the ratio of each structural unit, the weight average molecular weight (Mw), the dispersity (Mw/Mn) and the synthesis method are the same as defined above for the component (A1).

The polymeric compound of the present invention is a novel polymeric compound useful as a base resin for a resist composition, and can be blended within a resist composition as a base component capable of forming a film.

By adding the polymeric compound as a base component to a resist composition, a resist pattern with an excellent dimension uniformity can be formed by the method of forming a resist pattern of the present invention.

### EXAMPLES

As follows is a description of examples of the present invention, although the scope of the present invention is by no way limited by these examples.

In the following examples, a compound represented by a chemical formula (1) is designated as “compound (1)”, and the same applies for compounds represented by other chemical formulae.

In the NMR analysis, the internal standard for and ¹³C-NMR was tetramethylsilane (TMS). The internal standard for ¹⁹F-NMR was hexafluorobenzene (provided that the peak of hexafluorobenzene was regarded as −160 ppm).

<Production of Resist Composition>

### Examples 1 and 2, Comparative Examples 1 and 2

The components shown in Table 1 were mixed together and dissolved to obtain resist compositions.

TABLE 1

| Resist | Component | Component | Component | Component | Component | Component | Component |
|---|---|---|---|---|---|---|---|
| Composition | (A) | (A′) | (Z) | (J) | (D) | (F) | (S) |
| Comparative | (A)-1 | (A′)-1 | (G)-1 | — | (D)-1 | (F)-1 | (S)-1 |
| Example 1 | [50] | [50] | [10.0] | | [4.0] | [2.0] | [3700] |
| Comparative | (A)-1 | (A′)-1 | (G)-1 | (J)-1 | (D)-1 | (F)-1 | (S)-1 |
| Example 2 | [50] | [50] | [10.0] | [6.0] | [4.0] | [2.0] | [3700] |
| Example 1 | (A)-2 | (A′)-1 | (G)-1 | — | (D)-1 | (F)-1 | (S)-1 |
| | [50] | [50] | [10.0] | | [4.0] | [2.0] | [3700] |
| Example 2 | (A)-2 | (A′)-1 | (G)-1 | (J)-1 | (D)-1 | (F)-1 | (S)-1 |
| | [50] | [50] | [10.0] | [6.0] | [4.0] | [2.0] | [3700] |

In Table 1, the values in brackets [ ] indicate the amount (in terms of parts by weight) of the component added, and the reference characters indicate the following. With respect to each polymeric compound, the copolymer compositional ratio (molar ratio) as determined by carbon 13 nuclear magnetic resonance spectrometry (600 MHz ¹³C-NMR) and the weight average molecular weight (Mw) and the dispersity (Mw/Mn) determined by the polystyrene equivalent value as measured by gel permeation chromatography (GPC) are shown in Table 1.

(A)-1: a polymeric compound (1) represented by chemical formula (A)-1 shown below (Mw=7000, Mw/Mn=1.73). In the chemical formula, the subscript numerals shown on the bottom right of the parentheses ( ) indicate the proportion (copolymer compositional ratio; molar ratio) of the respective structural units, and 1/m/n=45/45/10.

(A)-2: a polymeric compound (2) represented by chemical formula (A)-2 shown below (Mw=7000, Mw/Mn=1.72). In the chemical formula, the subscript numerals shown on the bottom right of the parentheses ( ) indicate the proportion (molar ratio) of the respective structural units, and l/m/n=45/45/10.

(A′)-1: a polymeric compound (3) represented by chemical formula (A′)-1 shown below (Mw=7000, Mw/Mn=1.70). In the chemical formula, the subscript numerals shown on the bottom right of the parentheses ( ) indicate the proportion (molar ratio) of the respective structural units, and l/m=50/50.

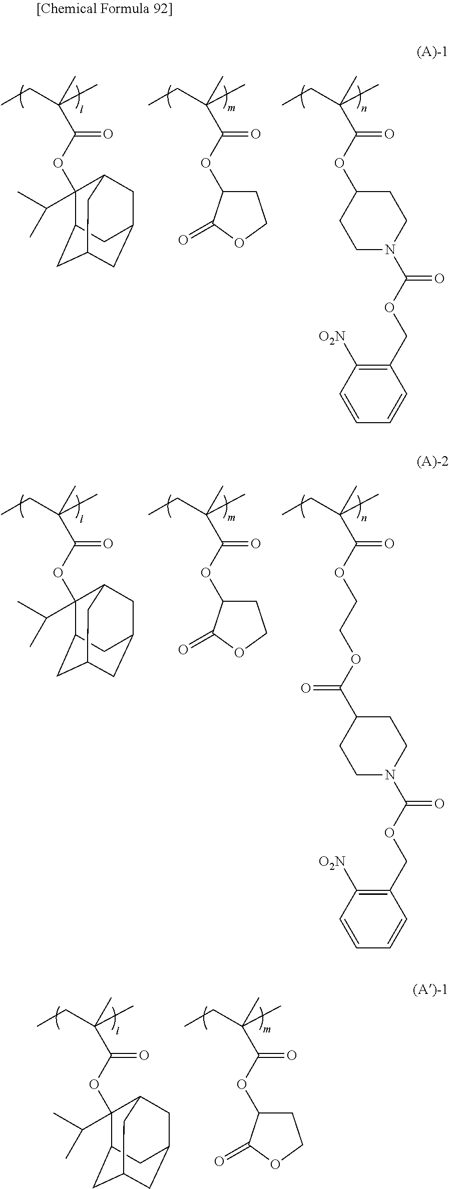

(G)-1: a compound represented by chemical formula (G)-1 shown below.

(J)-1: a compound represented by chemical formula (J)-1 shown below.

(D)-1: 1H,1H-heptafluorobutylamine [pKa=5.89]

(F)-1: a polymer represented by chemical formula (F)-1 shown below (Mw=24000, Mw/Mn=1.38). In the chemical formula, the subscript numerals shown on the bottom right of the parentheses ( ) indicate the proportion (molar ratio) of the respective structural units.

(S)-1: a mixed solvent of propylene glycol monomethyl ether acetate/propylene glycol monomethyl ether=8/2 (weight ratio).

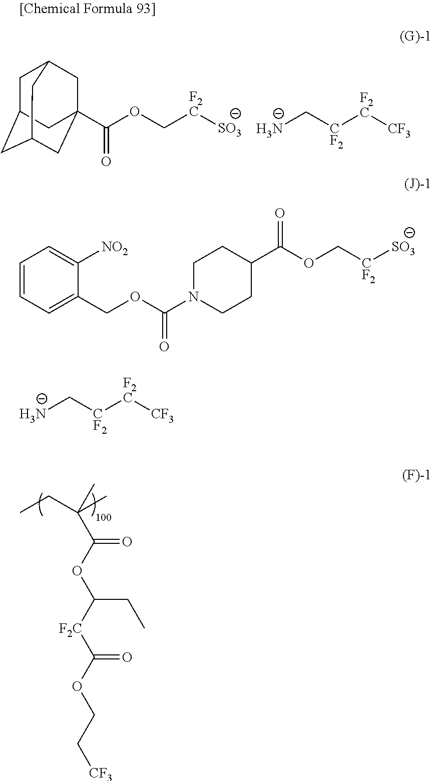

<Formation of Resist Pattern>

Step (1)

An organic anti-reflection film composition (product name: ARC95, manufactured by Brewer Science Ltd.) was applied to an 12-inch silicon wafer using a spinner, and the composition was then baked and dried at 205° C. for 60 seconds on a hotplate, thereby forming an organic anti-reflection film having a film thickness of 90 nm.

Each resist composition was then applied to the organic anti-reflection film using a spinner, and then allowed to stand on a cooling plate for 60 seconds at 23° C., thereby forming a resist film having a film thickness of 100 nm.

Step (2)

Subsequently, the resist film was selectively irradiated with an ArF excimer laser (193 nm) through a photomask (6% halftone), using an immersion lithography ArF exposure apparatus NSR-S609B (manufactured by Nikon Corporation; NA (numerical aperture)=1.07; Crosspole (in/out=0.78/0.97); immersion medium: water).

Step (3)

Further, PEB treatment was conducted at 90° C. for 60 seconds.

Step (4)

Thereafter, an alkali development was conducted for 20 seconds at 23° C. in a 2.38% by weight aqueous solution of tetramethylammonium hydroxide (TMAH) (product name: NMD-3; manufactured by Tokyo Ohka Kogyo Co., Ltd.). Then, the resist was washed for 30 seconds with pure water, followed by drying by shaking.

As a result, in each of the examples, a contact hole pattern in which holes having a diameter of 60 nm were equally spaced at a pitch of 120 nm was formed (hereafter, this contact hole pattern is referred to as “CH pattern”).

[Evaluation of In-Plane Uniformity (CDU) of Pattern Size]

With respect to each CH pattern having the above target size obtained above, 100 holes in the CH pattern were observed from the upper side thereof using a measuring scanning electron microscope (SEM) (product name: S-9380, manufactured by Hitachi High-Technologies Corporation; acceleration voltage: 500V), and the hole diameter (nm) of each hole was measured. From the results, the value of 3 times the standard deviation σ (i.e., 3σ) was determined. The results are indicated “CDU” in Table 2.

The smaller the thus determined 36 value is, the higher the level of the dimension uniformity (CD uniformity) of the plurality of holes formed in the resist film.

TABLE 2

| | CDU (nm) |
|---|---|
| Comparative | 12.7 |
| Example 1 | |
| Comparative | 11.5 |
| Example 2 | |
| Example 1 | 9.82 |
| Example 2 | 9.11 |

From the results shown in Table 2, the resist compositions of the Examples 1 and 2 according to the present invention exhibited high dimension uniformity and excellent lithography properties, as compared to the resist compositions of the Comparative Examples 1 and 2.

From the evaluation results, it was found that with respect to the component (A), when a polymerizable group had been distantly positioned from the amine part, the dimension uniformity (CD uniformity) of holes was enhanced.

Further, it was found that by virtue of including a component (J), the dimension uniformity (CD uniformity) of holes was enhanced.

<Synthesis Example of Compound (Monomer)>

### Example 3

25.6 g of a compound (01-0) and 250 g of dichloromethane was added to a three-necked flask and cooled at 10° C. or lower, and 2.0 g of 4-dimethylaminopyridine was added thereto, followed by stirring. Next, 11.9 g of hydroxyethyl methacrylate was dissolved in 105 g of dichloromethane to obtain a solution, and the solution was added to the three-necked flask in a dropwise manner while maintaining a temperature of 10° C. or lower. Thereafter, 18.6 g of 1-(3-dimethylaminopropyl)-3-ethylcarbodiimide hydrochloride was added thereto and stirred for 10 minutes, and then, stirred for 30 hours at 23° C. After the reaction, the reaction solution was washed with 350 g of pure water three times, and subjected to distillation under reduced pressure to remove the solvent, thereby obtaining 27 g of the compound (01) in the form of a viscous liquid.

The obtained compound (01) was analyzed by NMR, and the structure thereof was identified by the following results.

¹H-NMR (400 MHz, dmso-d6): δ(ppm)=8.08 (d, 1H, ArH), 7.79 (m, 1H, ArH), 7.64 (m, 2H, ArH), 6.03 (s, 1H, HC═C), 5.69 (s, 1H, HC═C), 5.37 (s, 2H, OCOCH₂Ar), 4.32 (m, 4H, COOCH₂CH₂OCO), 3.90 (m, 2H, piperidine), 2.85-3.10 (m, 2H, piperidine), 2.58-2.64 (m, 1H, piperidine), 1.82-1.94 (m, 5H, piperidine+C═CCH₃), 1.47-1.49 (m, 2H, piperidine)

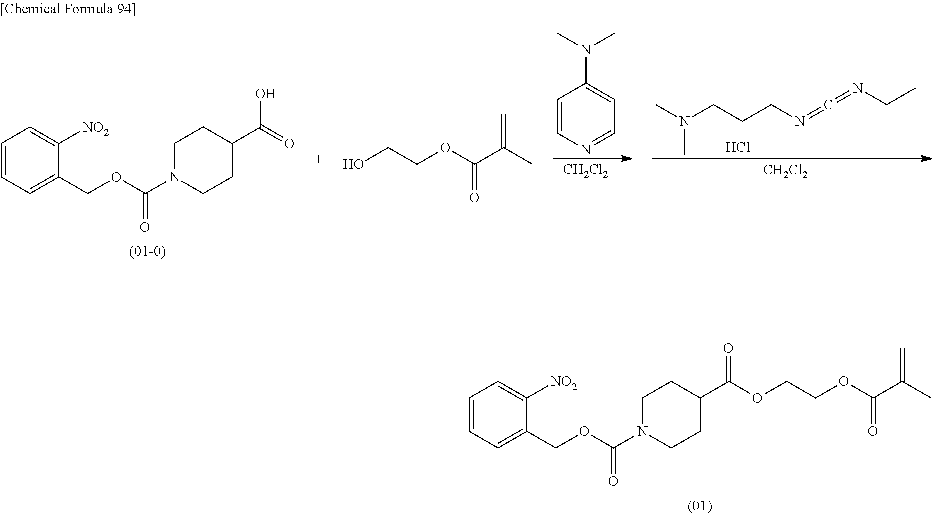

<Synthesis Example of Polymeric Compound>

### Example 4

In a separable flask equipped with a thermometer, a reflux tube and a nitrogen feeding pipe, 21.43 g (81.66 mmol) of a compound (11) was dissolved in 29.03 g of propylene glycol monomethyl ether acetate, and heated to 80° C. To the resulting solution, a solution obtained by dissolving 13.00 g (76.40 mmol) of a compound (21) and 7.22 g (17.17 mmol) of a compound (01) and 26.28 mmol of dimethyl 2,2′-azobis(isobutyrate) (V-601) as a polymerization initiator in 53.51 g of propylene glycol monomethyl ether acetate was added in a dropwise manner over 4 hours in a nitrogen atmosphere.

After dropwise, the resulting reaction solution was heated while stirring for 1 hour, and then cooled to room temperature. The obtained reaction polymer solution was dropwise added to an excess amount of n-heptane, and an operation to precipitate a polymer was conducted. Thereafter, the precipitated white powder was separated by filtration, followed by washing with methanol and drying, thereby obtaining 27.3 g of a polymeric compound (2) as an objective compound.

With respect to the polymeric compound (2), the weight average molecular weight (Mw) and the dispersity (Mw/Mn) were determined by the polystyrene equivalent value as measured by gel permeation chromatography (GPC). As a result, it was found that the weight average molecular weight was 7,600, and the dispersity was 1.72. Further, as a result of an analysis by carbon 13 nuclear magnetic resonance spectroscopy (600 MHz, ¹³C-NMR), it was found that the copolymer compositional ratio (ratio (molar ratio) of the respective structural units within the structural formula) was l/m/n=45.1/44.0/10.9.

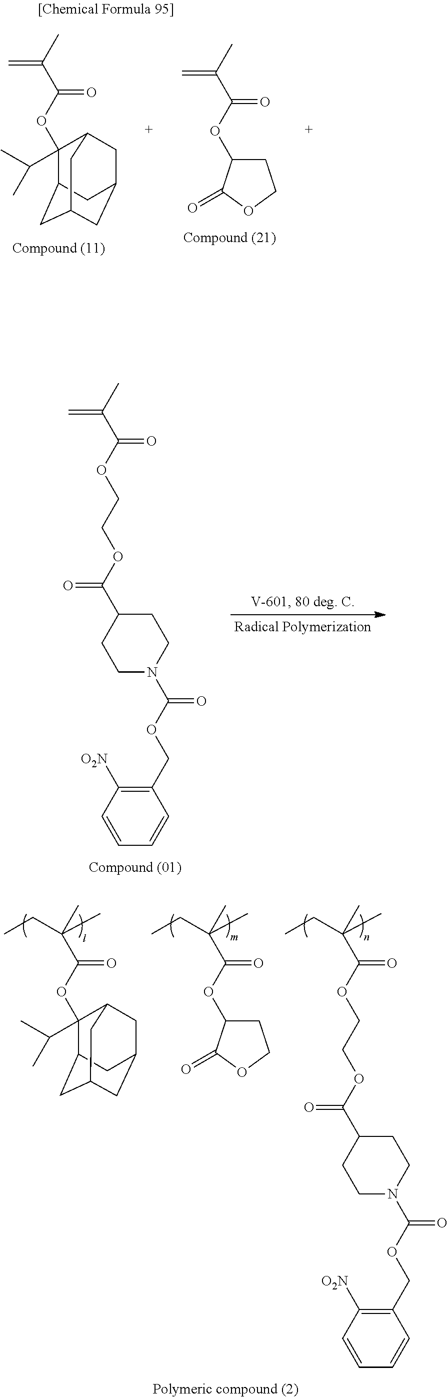

<Synthesis Example of Compound Represented by General Formula (J)-1)>

In a nitrogen atmosphere, 30.8 g of (j)-1, 20.3 g of (j)-2 and 250 g of pyridine were added thereto. Then, 16.41 g of diisopropylcarbodiimide was gradually added in a dropwise manner. Thereafter, the resultant was stirred at room temperature for 24 hours, and 500 g of pure water was added to finish the reaction. Diisopropylurea precipitated in the reaction mixture was removed by filtration, and 26 g of 1H,1H-heptafluorobutylaminechloride was added to the filtrate, followed by stirring at room temperature for 1 hour. Then, the precipitate was collected by filtration. The obtained powder was dried under reduced pressure, thereby obtaining 52.7 g of a compound (J)-1 in the form of light brown crystals.

The obtained compound (J)-1 was analyzed by NMR, and the structure thereof was identified by the following results.

¹H-NMR (400 MHz, DMSO-d6): δ(ppm)=8.79 (3H, NH₃), 8.09 (1H, ArF), 7.81 (1H, ArH), 7.65 (2H, ArH), 5.41 (2H, CH₂Ar), 4.61 (2H, CH₂CF₂), 4.02 (2H, CH₂NH₃), 3.91 (2H, Piperidine), 3.01 (2H. Piperidine), 2.71 (1H, Piperidine), 1.89 (2H, Piperidine), 1.53 (2H, Piperidine).

¹⁹F-NMR (376 MHz, DMSO-d6): δ (ppm)=−77.5, −111.4, −114.3, −124.6.

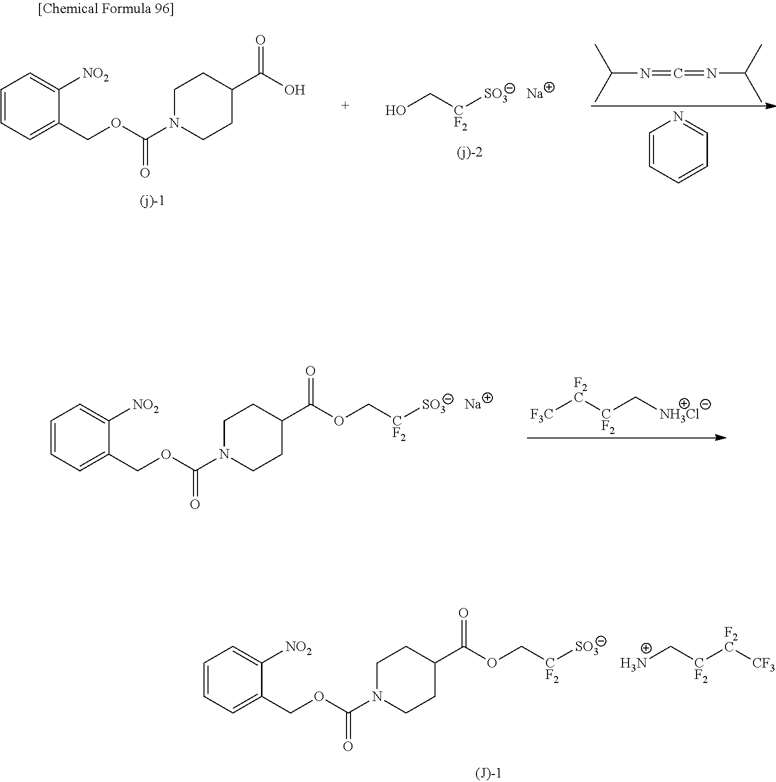

### DESCRIPTION OF REFERENCE NUMERALS AND CHARACTERS

1: substrate; 2: resist film; 2a: exposed portion; 2b: unexposed portion; 3: photomask

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A resist composition comprising a base component (A) which generates base upon exposure and exhibits changed solubility in a developing solution under action of acid, wherein
the base component (A) comprises a polymeric compound (A1) comprising a structural unit derived from a compound represented by general formula (a0-m) shown below: 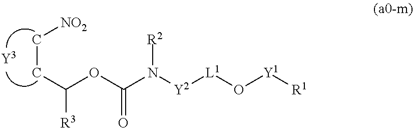
wherein R¹ represents a polymerizable group; Y¹ represents a hydrocarbon group of 1 to 30 carbon atoms which may have a substituent; L¹ represents a single bond or a carbonyl group; Y² represents a divalent linking group, and R² represents a hydrogen atom or a hydrocarbon group which may have a substituent, provided that Y² and R² may be mutually bonded to form a ring with the nitrogen atom having Y² and R² bonded thereto; R³ represents a hydrogen atom or a hydrocarbon group which may have a substituent; Y³ represents a group which forms an aromatic ring together with the two carbon atoms having Y³ bonded thereto, provided that the aromatic ring may have a nitro group or a substituent other than the nitro group bonded to the aromatic ring.

2. The resist composition according to claim 1, wherein the polymeric compound (A1) comprises a structural unit (a1) containing an acid decomposable group that exhibits increased polarity by the action of acid.

3. The resist composition according to claim 2, wherein the polymeric compound (A1) further comprises a structural unit (a2) containing a lactone-containing cyclic group.

4. The resist composition according to claim 1, further comprising a compound represented by general formula (J1) shown below: 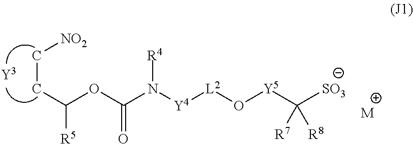
wherein Y⁴ represents a divalent linking group, and R⁴ represents a hydrogen atom or a hydrocarbon group which may have a substituent, provided that Y⁴ and R⁴ may be mutually bonded to form a ring with the nitrogen atom having Y⁴ and R⁴ bonded thereto; R⁵ represents a hydrogen atom or a hydrocarbon group which may have a substituent; L² represents a single bond or a carbonyl group; Y⁵ represents an alkylene group of 1 to 6 carbon atoms, provided that part of the methylene group constituting the alkylene group may be replaced with an oxygen atom or a carbonyl group, part or all of the hydrogen atoms constituting the alkylene group may be substituted with an aliphatic hydrocarbon group of 1 to 6 carbon atoms which may have a fluorine atom, and -L²-O—Y⁵— does not represent —C(═O)—O—C(═O)—; Y⁶ represents a group which forms an aromatic ring together with the two carbon atoms having Y⁶ bonded thereto, provided that the aromatic ring may have a nitro group or a substituent other than the nitro group bonded to the aromatic ring; R⁷ and R⁸ each independently represents a fluorine atom or a linear or branched fluorinated alkyl group of 1 to 6 carbon atoms; and M⁺ represents a primary, secondary or tertiary ammonium coutercation which exhibits a pKa smaller than a pKa of H₂N⁺(R⁴)—Y⁴-L²-O—Y⁵—C(R⁷)(R⁸)—SO₃⁻ generated by decomposition upon exposure.

5. A method of forming a resist pattern, comprising: forming a resist film on a substrate using a resist composition of claim 1; conducting exposure of the resist film;
and developing the resist film to form a resist pattern.

6. The method of forming a resist pattern according to claim 5, comprising:
a step (1) in which a resist film is formed on a substrate using a resist composition comprising the base component (A) and an acid component (G);
a step (2) in which the resist film is subjected to exposure;
a step (3) in which baking is conducted after the step (2), so as to increase the solubility of the base component (A) in an alkali developing solution by the action of the acid component (G) at an unexposed portion of the resist film; and
a step (4) in which the resist film is subjected to an alkali development, thereby forming a negative-tone resist pattern, wherein
an exposed portion of the resist film is not removed and dissolved by a neutralization between base generated from the base component (A) and the acid component (G), and the unexposed portion of the resist film is removed and dissolved by the neutralization.

7. A compound represented by general formula (a0-m) shown below: 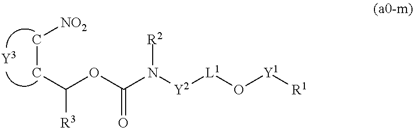
wherein R¹ represents a polymerizable group; Y¹ represents a hydrocarbon group of 1 to 30 carbon atoms which may have a substituent; L¹ represents a single bond or a carbonyl group; Y² represents a divalent linking group, and R² represents a hydrogen atom or a hydrocarbon group which may have a substituent, provided that Y² and R² may be mutually bonded to form a ring with the nitrogen atom having Y² and R² bonded thereto; R³ represents a hydrogen atom or a hydrocarbon group which may have a substituent; and Y³ represents a group which forms an aromatic ring together with the two carbon atoms having Y³ bonded thereto, provided that the aromatic ring may have a nitro group or a substituent other than the nitro group bonded to the aromatic ring.

8. A polymeric compound comprising a structural unit derived from the compound of claim 7.

9. The polymeric compound according to claim 8, comprising a structural unit (a1) containing an acid decomposable group that exhibits increased polarity by the action of acid.

10. The polymeric compound according to claim 9, further comprising a structural unit (a2) containing a lactone-containing cyclic group.
